(19) United States
(12) Patent Application Publication
(10) Pub. No.: US 2003/0138720 A1
(43) Pub. Date: Jul. 24, 2003

(54) Multicolor heat-sensitive recording material

(75) Inventor: Mitsuyuki Tsurumi, Kanagawa (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/207,771

(22) Filed: Jul. 31, 2002

(30) Foreign Application Priority Data
Aug. 2, 2001 (JP) 2001-235373

(51) Int. Cl. G03F 7/021

(52) U.S. Cl. 430/138; 430/157; 430/163; 430/171

(57) ABSTRACT

A multicolor heat-sensitive recording material includes a support having disposed thereon at least a heat-sensitive recording layer that develops yellow, a heat-sensitive recording layer that develops cyan, and a heat-sensitive recording layer that develops magenta, wherein water content of the multicolor heat-sensitive recording material is 5.5% or less.

### BACKGROUND OF THE INVENTION

1. Field of the Invention

The invention relates to a multicolor heat-sensitive recording material, and more specifically to a multicolor heat-sensitive recording material having at least three heat-sensitive recording layers on a support.

2. Description of the Related Art

In recent years, there have been developments in heat-sensitive recording because recording devices therefore are simple, highly reliable and require no maintenance. Conventional examples of materials for the recording include widely known materials using a reaction between an electron-donating colorless dye and an electron-accepting compound that causes the dye to color, and materials using a reaction of a diazo compound or a diazonium salt (may be referred to simply as “diazo compound or the like” below) and a coupler that causes to color.

In recent years, the development of multicolor heat-sensitive recording materials has been remarkable. Such multicolor heat-sensitive recording materials have a structure in which layers that respectively color to yellow, magenta and cyan are laminated. The respective layers color by being heated, whereby a full color image is formed.

In such multicolor heat-sensitive recording materials, generally color-developing layers (heat-sensitive recording layers) comprising both an electron-donating colorless dye and an electron-accepting compound are combined with a color-developing layer comprising a diazo compound or the like and a coupler, with the layers being laminated in the order of yellow, magenta and cyan from the uppermost layer.

In the above-mentioned multicolor heat-sensitive recording material, the higher the density of an image to be formed is, the thicker the color developing layer is. The thicker the color-developing layer becomes, the more difficult it is to control curls, whereby it becomes difficult for the recording material easily pass through a printer. Moreover, there are many cases in which the wet coat amount of the solution before being dried must be increased in order to thicken the color-developing layer. When the recording material is produced using a coater, there are problems in that the productivity of the recording material drops and the recording material cannot be sufficiently dried, whereby the water content in the recording material increases. Furthermore, if the water content in the heat-sensitive recording material itself becomes large, shelf life of the recording material deteriorates.

### SUMMARY OF THE INVENTION

In light of the above-mentioned problems, an object of the invention is to provide a multicolor heat-sensitive recording material which has good color balance and superior shelf life.

The object is achieved by the following aspects of the invention.

A first aspect of the invention provides a multicolor heat-sensitive recording material comprising a support having disposed thereon at least a heat-sensitive recording layer that develops yellow, a heat-sensitive recording layer that develops cyan, and a heat-sensitive recording layer that develops magenta, wherein water content by percentage of the multicolor heat-sensitive recording material including the support is 5.5% or less.

A second aspect of the invention provides a multicolor heat-sensitive recording material, according to the first aspect, wherein the wet coated amount of all layers formed on the side of the support disposed with the heat-sensitive recording layers is 250 g/m² or less.

A third aspect of the invention provides a multicolor heat-sensitive recording material, according to the first aspect, wherein the solid content coated amount of all layers formed on the side of the support disposed with the heat-sensitive recording layers is 40 g/m² or less.

A fourth aspect of the invention provides a multicolor heat-sensitive recording material, according to the first aspect, wherein the heat-sensitive recording layers are successively disposed on the support in the order of the heat-sensitive recording layer that develops yellow, the heat-sensitive recording layer that develops cyan, and the heat-sensitive recording layer that develops magenta.

A fifth aspect of the invention provides a multicolor heat-sensitive recording material, according to the first aspect, wherein the heat-sensitive recording layer that develops cyan and the heat-sensitive recording layer that develops magenta are light-fixing, heat-sensitive recording layers.

A sixth aspect of the invention provides a multicolor heat-sensitive recording material, according to the first aspect, further comprising a light-transmittance adjusting layer, an intermediate layer and a protective layer.

A seventh aspect of the invention provides a multicolor heat-sensitive recording material, according to the first aspect, wherein each of the heat-sensitive recording layers comprises: at least one of a diazo compound and at least one of a diazonium salt; and a coupler compound that reacts with the diazo compound and the diazonium salt to develop the corresponding color.

An eighth aspect of the invention provides a multicolor heat-sensitive recording material, according to the seventh aspect, wherein the heat-sensitive layers further comprise a basic material and a sensitizer.

A ninth aspect of the invention provides a multicolor heat-sensitive recording material, according to the seventh aspect, wherein the maximum absorbency wavelength of at least one of the diazo compound and the diazonium salt in the heat-sensitive recording layer that develops yellow is 350 nm or less, the maximum absorbency wavelength of at least one of the diazo compound and the diazonium salt in the heat-sensitive recording layer that develops cyan is 370±30 nm, and the maximum absorbency wavelength of at least one of the diazo compound and the diazonium salt in the heat-sensitive recording layer that develops magenta is 430±30 nm.

A tenth aspect of the invention provides a multicolor heat-sensitive recording material, according to the seventh aspect, wherein at least one of the diazo compound and the diazonium salt is encapsulated in microcapsules.

### DESCRIPTION OF THE PREFERRED EMBODIMENTS

A multicolor heat-sensitive recording material of the invention comprises a support having disposed thereon at least a heat-sensitive recording layer that develops yellow color, a heat-sensitive recording layer that develops cyan color, and a heat-sensitive recording layer that develops magenta color, wherein water content of the multicolor heat-sensitive recording material including the support is 5.5% or less.

When the water content is 5.5% or less, curling is easily controlled and shelf life is superior. The water content is measured after the recording material has been coated and dried, according to a method of JIS P 8127.

The water content is preferably 50% or less, and more preferably 4.5% or less. When the water content is more than 5.5%, fogging is generated when the heat-sensitive recording material id stored.

The wet coated amount of all of the heat-sensitive recording layers is preferably 250 g/m² or less, and more preferably 220 g/m² or less. When the wet coated amount is 250 g/m² or less, the amount of time required for the recording material to dry can be shortened, so that productivity of the recording material can be improved.

By “all layers” is meant all layers (e.g. the heat-sensitive recording layers, an intermediate layer, a light-transmittance adjusting layer and a protective layer) formed on the side of the support at which the heat-sensitive layers are disposed.

The wet coated amount is represented by the total amount of solutions applied per 1 m² when all layers are prepared as coating solutions. Therefore, “wet coated amount” means the total amount of the coating solutions before drying.

The solid coated amount of all layers formed on the side of the support disposed with the heat-sensitive recording layers is preferably 40 g/m² or less, and more preferably 38 g/m² or less. When the solid coated amount is 40 g/m² or less, it becomes easy to balance curling of the final product and to convey the recording material within a heat-sensitive recording device.

Each of the heat-sensitive recording layers preferably comprises a diazo compound and/or a diazonium salt, and a coupler which reacts with the diazo compound and/or the diazonium salt to develop the corresponding color.

A protective layer may be included in the multicolor heat-sensitive recording material of the invention. The protective layer may comprise two or more layers as necessary. Examples of material used for the protective layer include water-soluble polymer compounds, such as polyvinyl alcohol, carboxylic group-modified polyvinyl alcohol, vinyl acetate-acrylamide copolymer, silicon-modified polyvinyl alcohol, starch, modified starch, methylcellulose, carboxymethylcellulose, hydroxymethylcellulose, gelatins, Arabian gum, casein, styrene-maleic acid copolymer hydrates, styrene-maleic acid copolymer half-ester hydrates, isobutene-maleic anhydrate copolymer hydrates, polyacrylamide derivatives, polyvinyl pyrrolidone, sodium polystyrenesulfonate and sodium arginate, and latexes, such as styrene-butadiene rubber latex, acrylonitril-butadine rubber latex, methyl acrylate-butadene rubber latex, and vinyl acetate emulsion.

Storage stability of the water-soluble polymer compounds can be further improved when the compounds are crosslinked. A crosslinking agent for the crosslinking may be appropriately selected from known crosslinking agents. Examples thereof include water-soluble initial condensates, such as N-methylolurea, N-methylolmelamine and urea-formalin; dialdehyde compounds, such as glyoxal, and glutalaldehyde, inorganic crosslinking agents, such as boric acid and borax; and polyamide epichrolhydrin.

Known pigments, metal soaps, waxes, and surfactants may also be used in the protective layer.

The coated amount of the protective layer when dried is preferably from 0.2 to 5 g/m², and more preferably from 0.5 to 2 g/m². The film thickness thereof is preferably from 0.2 to 5 μm, and more preferably from 0.5 to 2 μm.

When the protective layer is formed, known ultraviolet absorbents, and precursors thereof may be incorporated therein.

The protective layer can be formed by a known coating method in the same way that the heat-sensitive recording layers are formed on the support.

As the support in the present embodiment, for example, a plastic film, paper, plastic resin-laminated paper, or synthetic paper may be used.

The multicolor heat-sensitive recording material of the invention may also include a light-transmittance adjusting layer and an intermediate layer.

The light-transmittance adjusting layer contains a component that functions as a precursor of an ultraviolet absorbent. The component does not function as the ultraviolet absorbent before being irradiated with light having a wavelength necessary for fixation. Therefore, this layer has a high light-transmittance and can sufficiently transmit light having the wavelength necessary for fixation when the heat-sensitive recording layers are fixed with light. The layer has a high transmittance to visible rays. Thus, the layer does not hinder fixation of the heat-sensitive recording layers. Characteristics of the light-transmittance adjusting layer can be arbitrarily selected depending on the characteristics of the light-fixing heat-sensitive recording layers.

The precursor of the ultraviolet absorbent reacts by light or heat after the light-fixing heat-sensitive recording layer is irradiated with light having the wavelength necessary for fixation. As a result, the precursor comes to function as the ultraviolet absorbent. The ultraviolet absorbent absorbs most of the light rays having wavelengths necessary for fixation based on the ultraviolet-absorbing range, so that transmittance there through becomes low. Thus, the light-resistance of the heat-sensitive recording material is improved, but no visible ray is absorbed. Therefore, transmittance to visible rays does not change substantially.

Compounds described in Japanese Patent Application Laid-Open (JP-A) No. 9-1928 may be used as the compound contained in the light-transmittance adjusting layer.

Preferably, at least one light-transmittance adjusting layer is disposed on the light-fixing heat-sensitive recording material. Most preferably, this layer is formed between the light-fixing magenta heat-sensitive recording layer and the protective layer, which is the outermost layer.

The intermediate layer is formed in order to prevent color-mixing between the respective photosensitive, heat-sensitive recording layers. This intermediate layer is preferably made from a water-soluble polymer compound, such as gelatin, gelatin modified with phthalic acid, polyvinyl alcohol, or polyvinyl pyrrolidone. The layer may appropriately contain various additives.

In the case of using a support having a high O₂-transmittance, such as laminated paper, an undercoat layer may be disposed as an O₂-cutting layer, whereby light-resistance can be improved.

In order to make the intermediate layer and the undercoat layer thinner and improve light-resistance and prevent color-mixing, it is effective to incorporate the swelling, inorganic laminar compound described in Japanese Patent Application No. 7-113825.

Description will now given of a preferable structure for the layer in the multicolor heat-sensitive recording material of the invention. The multicolor heat-sensitive recording material preferably has a structure in which the yellow heat-sensitive recording layer, the cyan heat-sensitive recording layer and the magenta heat-sensitive recording layer are arranged in this order on the support. The color-developing mechanism of each of the layers is preferably based on a diazo color-developing system composed of a diazo compound or the like, and a coupler. Specifically, the recording material of the invention preferably has a structure in which the following layers are arranged successively disposed on the support: a heat-sensitive recording layer comprising a diazo compound or the like having a maximum absorbency wavelength of 350 nm or less, and a coupler that reacts with the diazo compound or the like to develop yellow; a light-fixing heat-sensitive recording layer comprising a diazo compound or the like having a maximum absorbency wavelength of 370±30 nm or less, and a coupler that reacts with the diazo compound or the like to develop cyan; and a light-fixing heat-sensitive recording layer comprising a diazonium salt compound or the like having a maximum absorbency wavelength of 430±30 nm or less, and a coupler that reacts with the diazonium salt compound or the like to develop magenta. In the above-mentioned structure, the heat-sensitive recording layer that develops yellow may be non-fixing. However, the yellow heat-sensitive recording layer may be a light-fixing heat-sensitive recording layer to improve image stability.

In the heat-sensitive recording material of the invention, preferably a light-transmittance adjusting layer and an outermost protective layer are disposed on the heat-sensitive recording layers, particularly on the magenta heat-sensitive recording layer. More preferably, a light-transmittance adjusting layer is particularly disposed between the light-fixing magenta heat-sensitive recording layer and the protective layer, so that transmittance of light of any wavelength within the range of light wavelengths used in light-fixation decreases after fixation. In this case, light transmittance after irradiation with light and fixation is preferably 10% and less at 350 nm. By “irradiation with light” is meant irradiation with light having an energy of 13 kJ/m² at a wavelength of 420 nm from a xenon lamp forcible tester, specifically irradiation with light having an energy of 0.9 W/m² from Weather Ometer Ci65 (made by Atlas Electric Co.) for 4 hours.

Known color-developing components can be used for the color-developing component that comprises the diazo compound or the like and the coupler and is included in each of the heat-sensitive recording layers of the invention, may be any known one. The heat-sensitive recording material may also contain a basic material for promoting reaction of the diazo compound or the like with the coupler, a sensitizer, or the like. As described above an appropriate combination of the known diazo compound or the like with the coupler may be used. In order to exhibit the effect of the invention sufficiently, a combination of the diazo compound or the like with the coupler suitable for each of the yellow heat-sensitive recording layer, the cyan heat-sensitive recording layer and the magenta heat-sensitive recording layer is used. Description will be given below of most suitable examples for each of these color-developing components and their combinations.

### Yellow Heat-Sensitive Recording Layer

The maximum absorbency wavelength λmax of the diazo compound or the like used in the yellow heat-sensitive recording layer is preferably 350 nm or less, and more preferably 340 nm or less, in view of the advantageous effect of the invention. When the diazo compound or the like has a longer λmax than the above-mentioned wavelength range, the diazo compound or the like in the yellow heat-sensitive recording layer may be inactivated by irradiation with light for fixations of the layer(s) above the yellow heat-sensitive recording layer.

The diazo compound or the like in the yellow heat-sensitive recording layer, which is disposed nearest to the support in the heat-sensitive recording material of the invention, is preferably a compound represented by the following general formula (I):

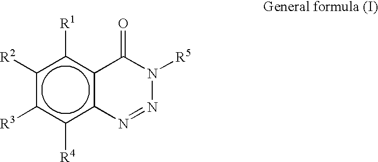

in which R¹, R², R³ and R⁴ each independently represent any one selected from the group consisting of a hydrogen atom, a halogen atom, and alkyl, aryl, —OR⁵¹, —SR⁵¹, —COOR⁵¹, —CONR⁵¹R⁵², —SO₂R⁵¹, —SO₂NR⁵¹R⁵², —COR⁵¹, —NR⁵¹R⁵², nitro and cyano groups, wherein R⁵¹ and R⁵² each independently represent any one selected from the group consisting of a hydrogen atom, and alkyl, aryl and acyl group; R⁵ represents any one selected from the group consisting of a hydrogen atom, and alkyl, aryl, —COOR⁵³, —CONR⁵³R⁵⁴, —SO₂R⁵³, —SO₂NR⁵³R⁵⁴, and —COR⁵³ groups, wherein R⁵³ and R⁵⁴ each independently represent any one selected from the group consisting of a hydrogen atom, and alkyl, aryl and acyl groups.

In the general formula (I), R¹, R², R³ and R⁴ each independently represent any one selected from the group consisting of a hydrogen atom, a halogen atom, and alkyl, aryl, —OR⁵¹, —SR⁵¹, —COOR⁵¹, —CONR⁵¹R⁵², —SO₂R⁵¹, —SO₂NR⁵¹R⁵², —COR⁵¹, —NR⁵¹R⁵², nitro and cyano groups.

In the general formula (I), halogen atoms represented by R¹ to R⁴ are preferably fluorine, chlorine, bromine, and iodine atoms, and more preferably fluorine and chlorine atoms.

In the case in which R¹ to R⁴ each represent an alkyl group in the general formula (I), the alkyl group may or may not have a substituent. The alkyl group may be in a linear or branched chain, and may have an unsaturated bond.

In the general formula (I), the alkyl group represented by each of R¹ to R⁴ is preferably an alkyl group having 1 to 20 carbon atoms, and more preferably an alkyl group having 1 to 10 carbon atoms. Specifically, the alkyl group is preferably methyl, ethyl, n-propyl, i-propyl, n-butyl, t-butyl, n-hexyl, n-octyl, 2-ethylhexyl, 3,5,5-trimethylhexyl, dodecyl, 2-chloroethyl, 2-methanesulfonylethyl, 2-methoxyethyl, 2-benzoyloxyethyl, N,N-dibutylcarbamoylmethyl, 2-ethoxycarbonylethyl, butoxycarbonylmethyl, 2-isopropyloxyethyl, 2-(2,5-di-t-amylphenoxy)ethyl, 2-phenoxyethyl, 1-(4-methoxyphenoxy)-2-propyl, 1-(2,5-di-t-amylphenoxy)-2-propyl, benzyl, α-methylbenzyl, trichloromethyl, trifluoromethyl, 2,2,2-trifluoroethyl or the like.

In the case in which R¹ to R⁴ each represent an aryl group in the general formula (I), the aryl group may or may not have a substituent. The aryl group represented by each of R¹ to R⁴ is preferably an aryl group having 6 to 30 carbon atoms. Specific examples thereof include phenyl, 4-methylphenyl and 2-chlorophenyl.

In the case in which R¹ to R⁴ each represent —OR⁵¹, —SR⁵¹, —COOR⁵¹, CONR⁵¹R⁵², —SO₂R⁵¹, —SO₂NR⁵¹R⁵², —COR⁵¹, or —NR⁵¹R⁵² in the general formula (I), R⁵¹ and R⁵² each independently represent any one selected from the group consisting of a hydrogen atom, and alkyl, aryl and acyl groups.

The alkyl group represented by each of R⁵¹ and R⁵² in the general formula (I) may or may not have a substituent. It is preferably an alkyl group having 1 to 30 carbon atoms, and more preferably an alkyl group having 1 to 10 carbon atoms. Specifically, preferable examples thereof include methyl, ethyl, i-propyl, s-butyl, t-butyl, and t-amyl.

The aryl group represented by each of R⁵¹ and R⁵² in the general formula (I) may or may not have a substituent. It is preferably an aryl group having 6 to 30 carbon atoms. Specifically, preferable examples thereof include phenyl, 2-methylphenyl, 3-methylphenyl, 4-methylphenyl, 2-chlorophenyl, and 2,5-t-amylphenyl.

The acyl group represented by each of R⁵¹ and R⁵² in the general formula (I) may or may not have a substituent. It is preferably an acyl group having 1 to 30 carbon atoms, and more preferably an acyl group having 1 to 10 carbon atoms. Specifically, preferable examples thereof include acetyl, propanoyl, butanoyl, and benzonoyl.

In the general formula (I), R⁵ represents any one selected from the group consisting of a hydrogen atom, and alkyl, aryl, —COOR⁵³, —CONR⁵³R⁵⁴, —SO₂NR⁵³R⁵⁴, and —COR⁵³ groups.

In the general formula (I), the alkyl group represented by R⁵ may or may not have a substituent. The alkyl group may be in a linear or branched chain, and may have an unsaturated bond. The alkyl group represented by R⁵ is preferably an alkyl group having 1 to 30 carbon atoms. Specifically, the alkyl group is preferably methyl, ethyl, n-propyl, i-propyl, n-butyl, i-butyl, 2-butyl, t-butyl, n-hexyl, n-octyl, 2-ethylhexyl, 3,5,5-trimethylhexyl, dodecyl, 2-chloroethyl, 2-methanesulfonylethyl, 2-methoxyethyl, 2-methoxypropyl, 2-benzoyloxyethyl, N,N-dibutylcarbamoylmethyl, 2-ethoxycarbonylethyl, butoxycarbonylmethyl, octyloxycarbonylmethyl, cyclohexyl, 2-isopropyloxyethyl, 2-(2,5-di-t-amylphenoxy)ethyl, 2-phenoxyethyl, 1-(4-methoxyphenoxy)-2-propyl, 1-(2,5-di-t-amylphenoxy)-2-propyl, benzyl, α-methylbenzyl, phenetyl, 3-phenylpropyl, allyl, methallyl, trichloromethyl, trifluoromethyl, 2,2,2-trifluoroethyl or the like.

The aryl group represented by R⁵ in the general formula (I) may or may not have a substituent, and is preferably an aryl group having 6 to 30 carbon atoms. Specifically, preferable examples thereof include phenyl, 2-methylphenyl, 3-methylphenyl, 4-methylphenyl, 4-ethylphenyl, and 4-isopropylphenyl.

In the case in which R⁵ represents —COOR⁵³, —CONR⁵³R⁵⁴, —SO₂R⁵³, SO₂NR⁵³R⁵⁴ or —COR⁵³— in the general formula (I), R⁵³ and R⁵⁴ each independently represent any one selected from the group consisting of a hydrogen atom, and alkyl, aryl and acyl groups.

The alkyl group represented by each of R⁵³ and R⁵⁴ in the general formula (I) may or may not have a substituent. It is preferably an alkyl group having 1 to 30 carbon atoms, and more preferably an alkyl group having 1 to 10 carbon atoms. Specifically, examples thereof include methyl, ethyl, i-propyl, s-butyl, t-butyl, and t-amyl.

The aryl group represented by each of R⁵³ and R⁵⁴ in the general formula (I) may or may not have a substituent, and is preferably an aryl group having 6 to 30 carbon atoms. Specifically, preferable examples thereof include phenyl, 2-methylphenyl, 3-methylphenyl, 4-methylphenyl, 2-chlorophenyl, and 2,5-t-amylphenyl.

The acyl group represented by each of R⁵³ and R⁵⁴ in the general formula (I) may or may not have a substituent. It is preferably an acyl group having 1 to 30 carbon atoms, and more preferably an acyl group having 1 to 10 carbon atoms. Specifically, preferable examples thereof include acetyl, propanoyl, butanoyl, and benzonoyl.

Below, specific examples of the diazo compound represented by the general formula (I) will be given as exemplary compounds A-1 to A-42, and specific examples 1 to 28 of substituents R¹ to R⁵ in the general formula (I) are specifically listed. However, the diazo compound used in the yellow heat-sensitive recording layer is not limited to the following compounds.

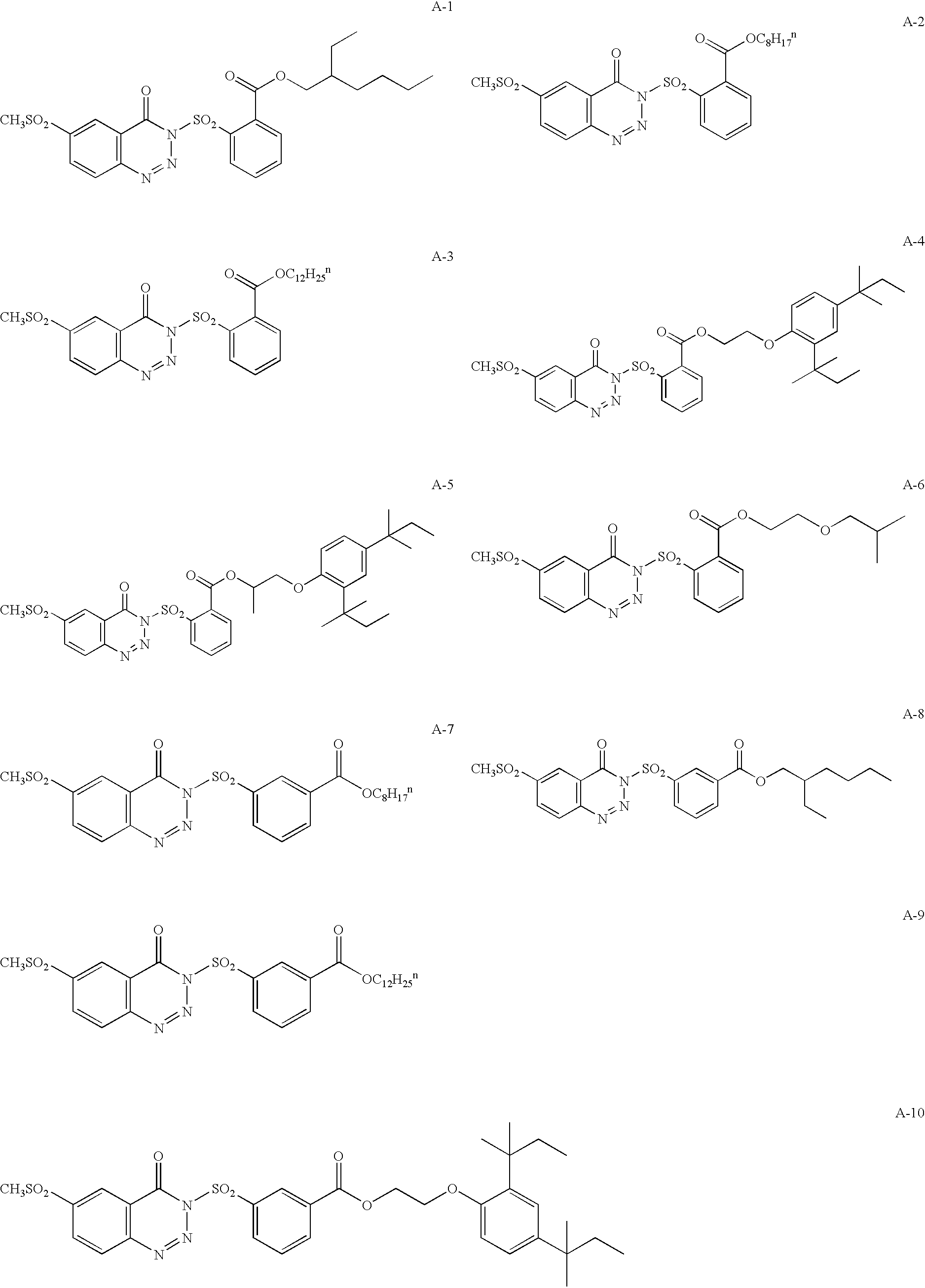

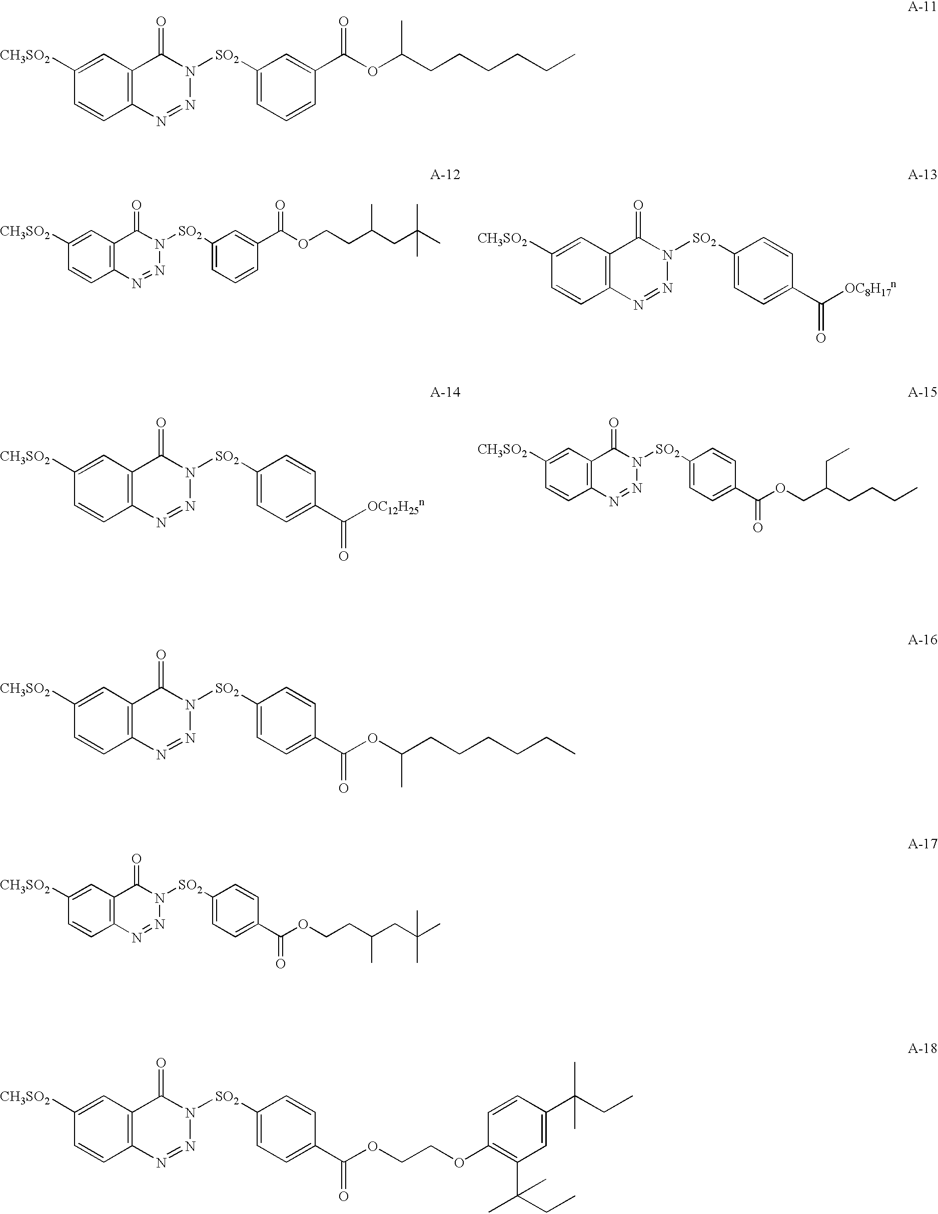

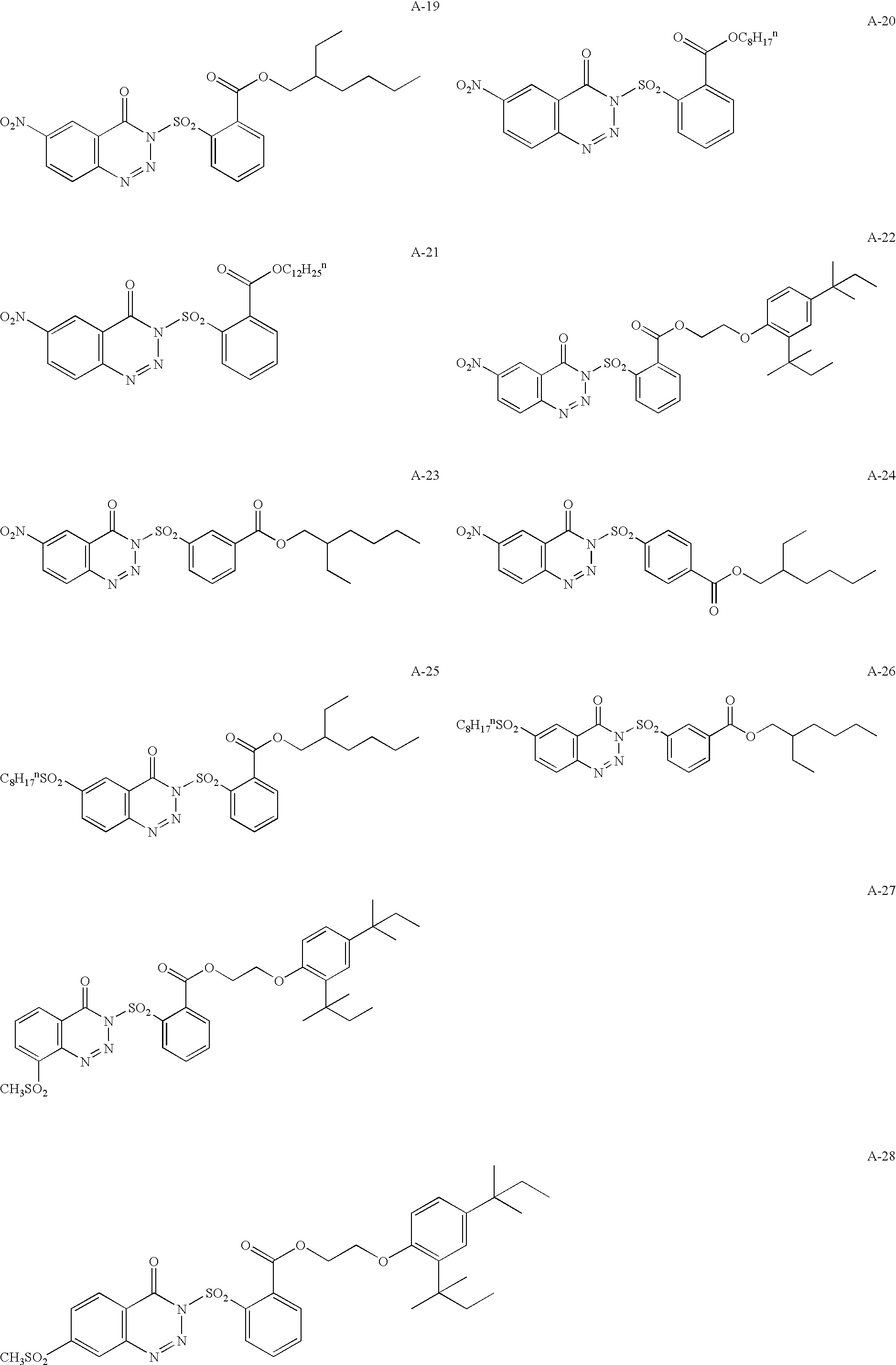

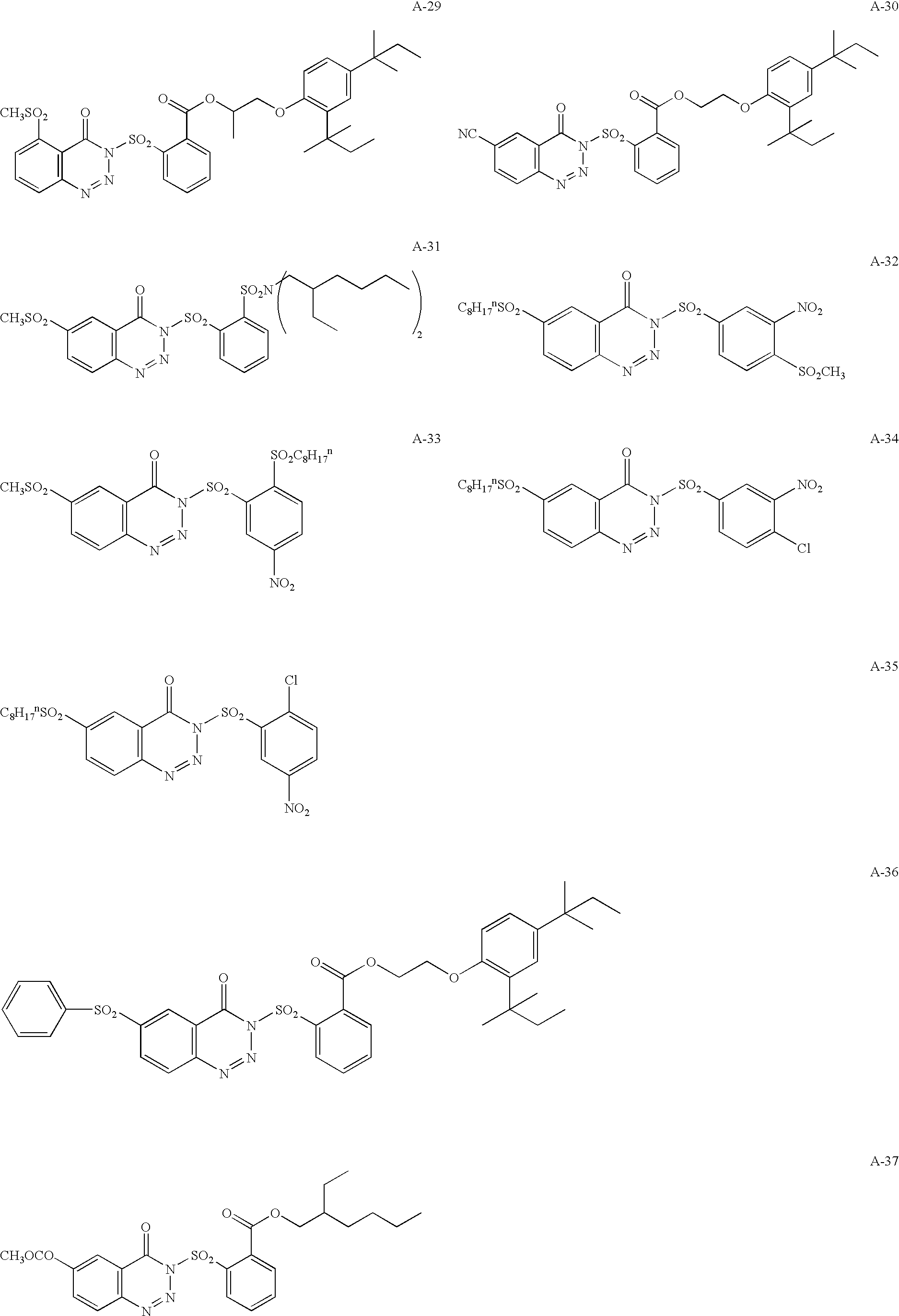

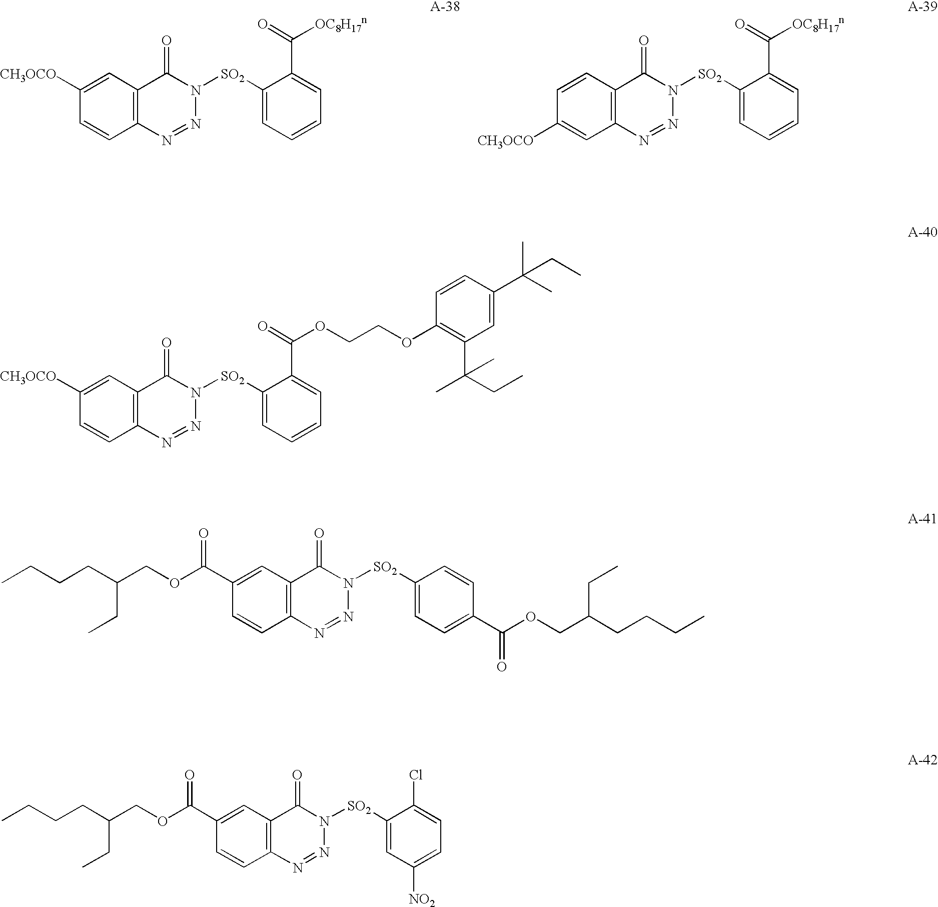

| | |
|---|---|
| | General formula (I) |
| 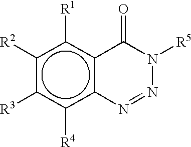 | |

| Specific | | | | | |
|---|---|---|---|---|---|
| Exam- | | | | | |
| ples | R¹ | R² | R³ | R⁴ | R⁵ |
| 1 | —H | 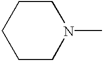 | H— | —H | 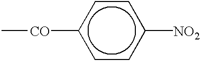 |
| 2 | —H | 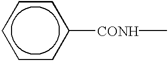 | H— | —H | 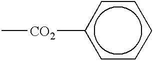 |
| 3 | —H | 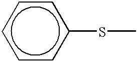 | C₄H₉O— | —H | 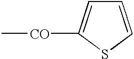 |
| 4 | —H | 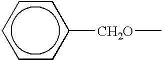 | 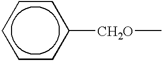 | —H | 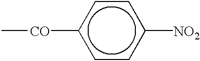 |
| 5 | —H | 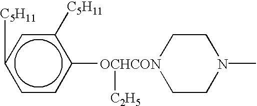 | H— | —H | 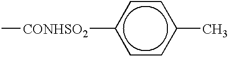 |
| 6 | —H | C₆H₁₃O— | C₆H₁₃O— | —OC₆H₁₃ | 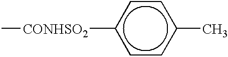 |
| 7 | —H | 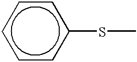 | H— | —H | 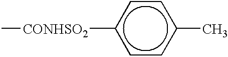 |
| 8 | —H | 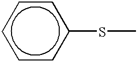 | C₈H₁₇O— | —H | 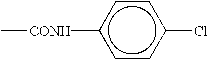 |
| 9 | —H | 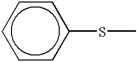 | H— | —H | 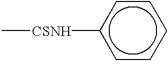 |
| 10 | —H | H— | H— | —H | 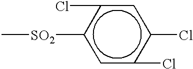 |
| 11 | —H | 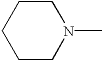 | H— | —H | 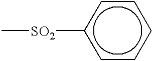 |
| 12 | —H | 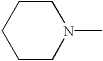 | H— | —H | 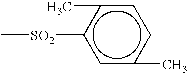 |
| 13 | —H | (C₈H₁₇)₂N— | H— | —H | —SO₂CH₃ |
| 14 | —H | 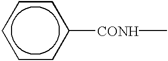 | H— | —H | —SO₂C₈H₁₇ |
| 15 | —H | CH₃CONH— | H— | —H | 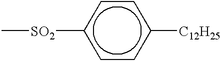 |
| 16 | —H | 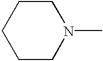 | C₄H₉O— | —H | 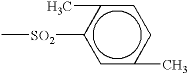 |
| 17 | —H | 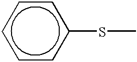 | H— | —H | 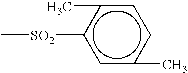 |
| 18 | —H | 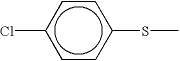 | H— | —H | 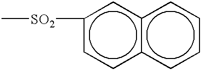 |
| 19 | —H | 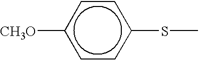 | H— | —H | 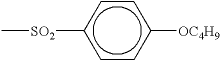 |
| 20 | —H | 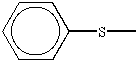 | C₄H₉O— | —H | 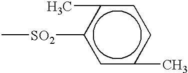 |
| 21 | —H | 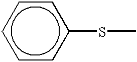 | CH₂═CHCH₂O— | —H | 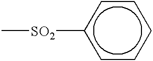 |
| 22 | —H | 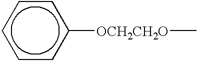 | H— | —H | 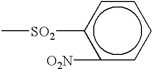 |
| 23 | —H | C₄H₉O— | C₄H₉O— | —H | 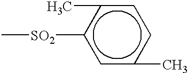 |
| 24 | —H | C₆H₁₃O— | C₆H₁₃O— | —OC₆H₁₃— | 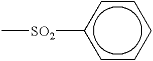 |
| 25 | —H | C₈H₁₇O— | H— | —OC₈H₁₇ | 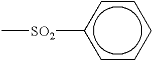 |
| 26 | —H | Cl— | 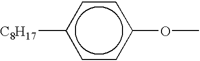 | —H | 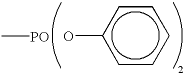 |
| 27 | —H | C₈H₁₇O— | CH₃— | —OC₈H₁₇ | 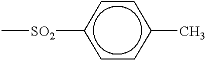 |
| 28 | —CONH₂ | H— | C₁₂H₂₅O— | —H | 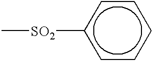 |

The yellow heat-sensitive recording layer contains at least one selected from the diazo compounds represented by the general formula (I), and may contain two or more diazo compounds or another diazo compound. The recording layer contains the diazo compound represented by the general formula (I) preferably in an amount of 0.02 to 3 g/m², and more preferably 0.1 to 2 g/m². A content less than 0.02 g/m² is not preferable in view of color-developability, and a content exceeding 3 g/m² is not preferable in the view of coating thickness.

The compound represented by the general formula (I) is preferably used together with an aromatic hydrocarbon. The aromatic hydrocarbon is preferably an aromatic hydrocarbon having 12 to 50 carbon atoms, and more preferably an aromatic hydrocarbon having 12 to 25 carbon atoms, in view of solubility and handling characteristics when being used. The aromatic hydrocarbon is preferably one represented by the following general formula (II):

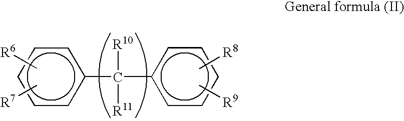

in which R⁶ to R¹¹ each independently represent a hydrogen atom or an alkyl group; n is an integer of 0 to 3. R⁶ and R⁷, R⁸ and R⁹, or R¹⁰ and R¹¹ may be bonded to each other to form a ring. In the case in which R⁶ to R¹¹ each independently represent an alkyl group, the alkyl group may be in a linear or branched chain, and may have an unsaturated bond. Substitution positions for R⁶ to R⁹ are not particularly limited.

In the general formula (II), each of R⁶ to R⁹ is preferably a hydrogen atom or an alkyl group having 1 to 8 carbon atoms, and each of R¹⁰ and R¹¹ is preferably a hydrogen atom or a methyl group. The integer n is preferably 0 or 1.

Examples of the above-mentioned aromatic hydrocarbon include the following. However, the aromatic hydrocarbon is not limited to these examples.

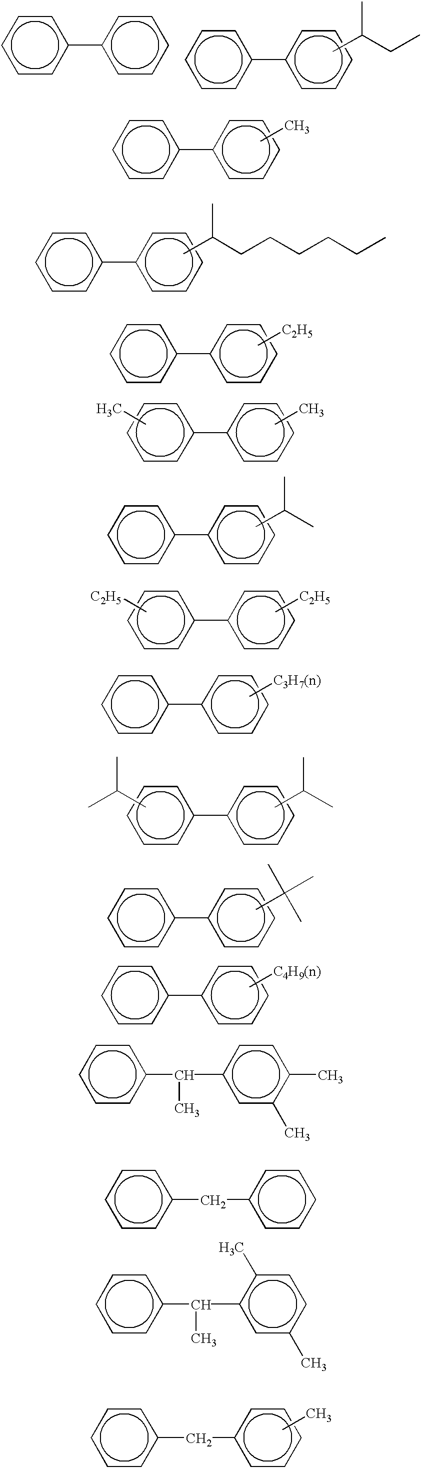

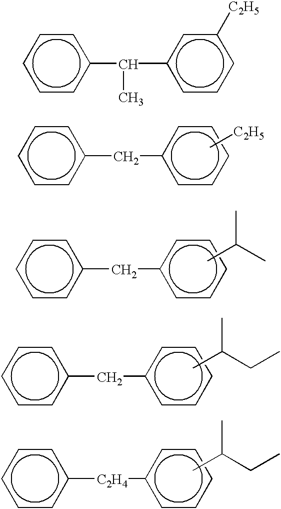

The aromatic hydrocarbon may be used alone or in combination of two or more.

Description will now be given of the coupler that reacts with the above-mentioned diazo compound to color.

The coupler in the yellow heat-sensitive recording layer may be any compound that couples with the diazo compound in a basic atmosphere to form a dye. Any one of the so-called 4-equivalent couplers, which are known in the field of silver halide photographic photosensitive materials, can be used as the coupler in the yellow heat-sensitive recording layer. An appropriate coupler can be selected from these couplers, dependently on the desired yellow hue.

Examples of known couplers that can be used in the yellow heat-sensitive recording layer include active methylene compounds having a methylene group adjacent to a carbonyl group, a phenol derivative, a naphthol derivative or the like. Specific examples thereof include the following. These can be used so far as the object of the invention is achieved.

Specific examples of known couplers include resorcin, phloroglucin, sodium 2,3-dihydroxynaphthalene-6-sulfonate, sodium 2-hydroxy-3-naphthalenesulfonate, 2-hydroxy-3-naphthalenesulfonic acid anilide, 1-hydroxy-2-naphthoic acid morpholinopropylamide, 2-hydroxy-3-naphthalenesulfonic acid morpholinopropylamide, 2-hydroxy-3-naphthalenesulfonic acid-2-ethylhexyloxypropylamide, 2-hydroxy-3-naphthalenesulfonic acid-2-ethylhexylamide, 5-acetoamide-1-naphthol, sodium 1-hydroxy-8-acetoamidenaphthalene-3,6-disulfonate, 1-hydroxy-8-acetoamidenaphthalene-3,6-disulfonic acid dianilide, 1,5-dihydroxynaphthalene, 2,3-dihydroxynaphthalene, 2-hydroxy-3-naphtoenic acid morpholinopropylamide, 2-hydroxy-3-naphthoenic acid octylamide, 2-hydroxy-3-naphthoenic acid anilide, 5,5-dimethyl-1,3-cyclohexanedione, 1,3-cyclopentanedione, 5-(2-n-tetradecyloxyphenyl)-1,3-cyclohexanedione, and 5-phenyl-4-methoxycarbonyl-1,3-cyclohexanedione, 5-(2,5-di-n-octyloxyphenyl)-1,3-cyclohexanedione, 1,3-dicyclohexylbarbituric acid, 1,3-di-n-dodecylbarbituric acid, 1-n-octyl-3-n-octadecylbarbituric acid, 1-phenyl-3-(2,5-di-n-octyloxyphenyl)barbituric acid, 1,3-bis(octadecyloxycarbonylmethyl)barbituric acid, 1-phenyl-3-methyl-5-pyrozolone, 1-(2,4,6-trichlorophenyl)-3-anilino-5-pyrazolone, 1-(2,4,6-trichlorophenyl)-3-benzamide-5-pyrazolone, 6-hydroxy-4-methyl-3-cyano-1-(2-ethylhexyl)-2-pyridone, 2-[3-[α-(2,4-di-tert-amylphenoxy)butanamide]benzamide]phenol, 2,4-bis-(benzoylacetoamide)toluene, 1,3-bis-(pyvaloylacetoaminomethyl)benzene, benzoylacetonitrile, thenoylacetonitrile, acetoacetoanilide, benzoylacetoanilide, pyvaloylacetoanilide, 2-chloro-5-(N-n-butylsulfamoyl)-1-pivaloylacetoamidebenzene, 1-(2-ethylhexyloxypropyl)-3-cyano-4-methyl-6-hydroxy-1,2-dihydropyridine-2-one, 1-(dodecyloxypropyl)-3-acetyl-4-methyl-6-hydroxy-1,2-dihydropyridine-2-one, 1-(4-n-octyloxyphenyl)-3-tert-butyl-5-aminopyrazole, trifluoroacetoacetoanilide, 4-hydroxycoumalin, pyrazolo[1,5-a]pyrimidinedione, and 3-ethyl-6-ethoxyuracil.

Details on the couplers are described in JP-A Nos. 4-201483, 7-125446, 7-96671, 7-223367, and 7-223368.

The coupler used in the yellow heat-sensitive recording layer is preferably a compound represented by the following general formula (III). Details of the coupler represented by the general formula (III) will be described below.

General formula (III)

E¹-CH₂-E²

In the general formula (III), an electron-withdrawing group represented by each of E¹ and E² is a substituent whose Hammett's σₚ value is positive, and E¹ and E² may be the same or mutually different. Preferable examples thereof include acyl groups, such as acetyl, propionyl, pyvaloyl, chloroacetyl, trifluoroacetyl, 1-methylcyclopropylcarbonyl, 1-ethylcyclopropylcarbonyl, 1-benzylcyclopropylcarbonyl, benzoyl, 4-methoxybenzoyl and thenoyl; oxycarbonyl groups, such as methoxycarbonyl, ethoxycarbonyl, 2-methoxyethoxycarbonyl, and 4-methoxyphenoxycarbonyl; carbamoyl groups, such as carbamoyl, N,N-dimethylcarbamoyl, N,N-diethylcarbamoyl, N-phenylcarbamoyl, N-2,4-bis(pentyloxy)phenylcarbamoyl, N-2,4-bis(octyloxy)phenylcarbamoyl, and morpholinocarbonyl; a cyano group; sulfonyl groups, such as methanesulfonyl, benzenesulfonyl, and toluenesulfonyl; phosphono groups such as diethylphosphono; and heterocyclic groups, such as benzooxazole-2-yl, benzothiazole-2-yl, 3,4-dihydroquinazoline-4-one-2-yl, and 3,4-dihydroquinazoline-4-sulfone-2-yl.

The electron-withdrawing groups represented by E¹ and E² in the general formula (III) may be bonded to each other to form a ring. The ring composed of E¹ and E² are preferably a 5- or 6-membered carbon ring or heteroring.

Specific examples of the coupling component represented by the general formula (III) are given below. In the invention, however, the coupling component is not limited thereto.

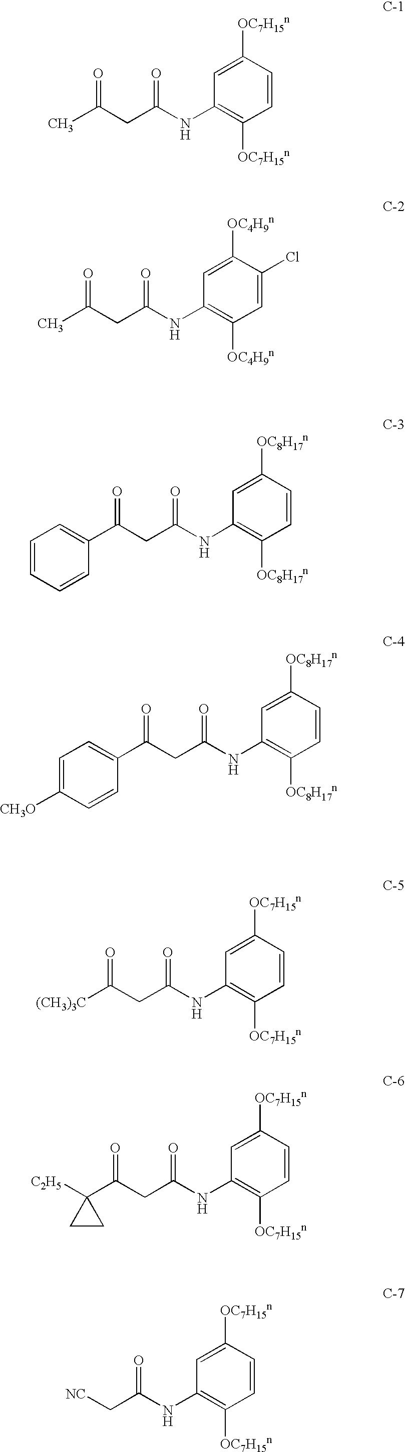

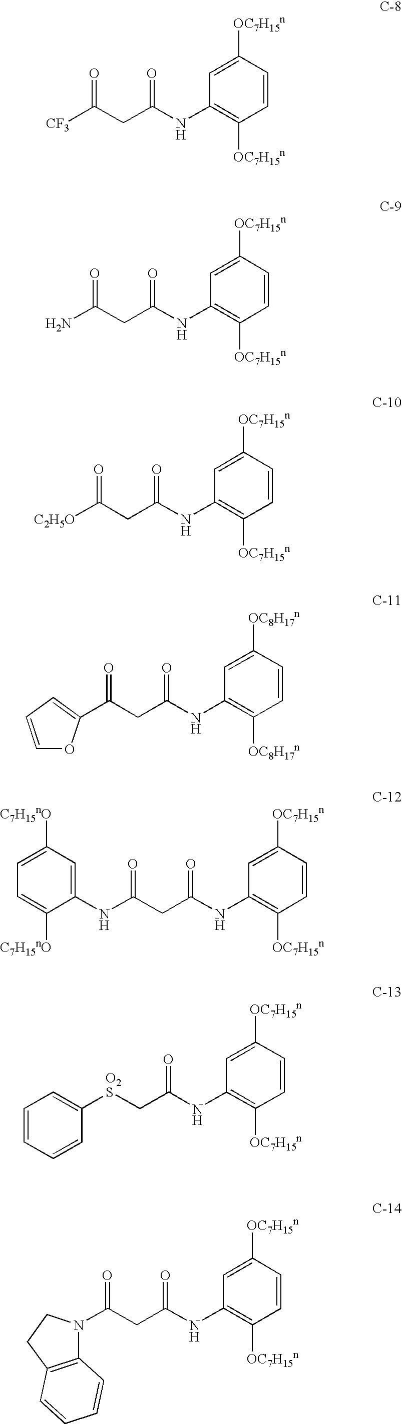

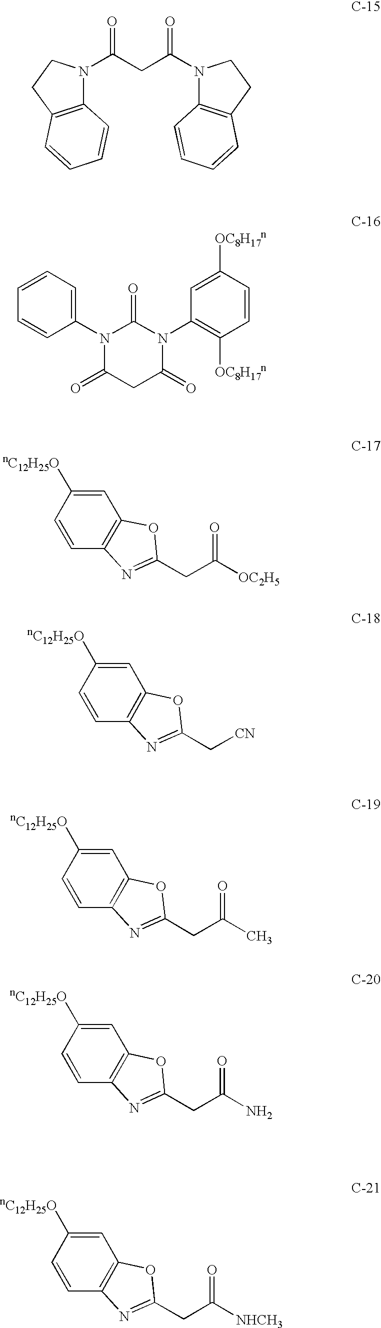

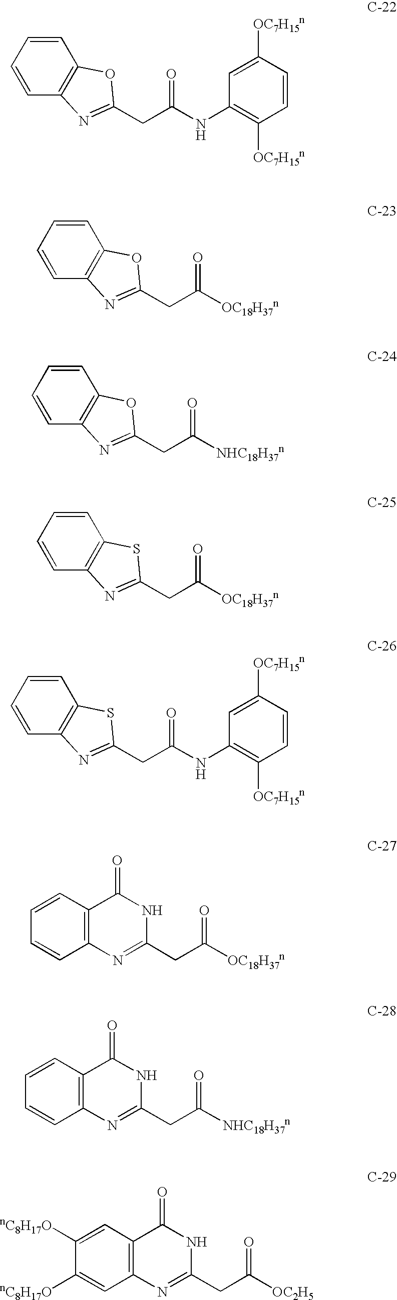

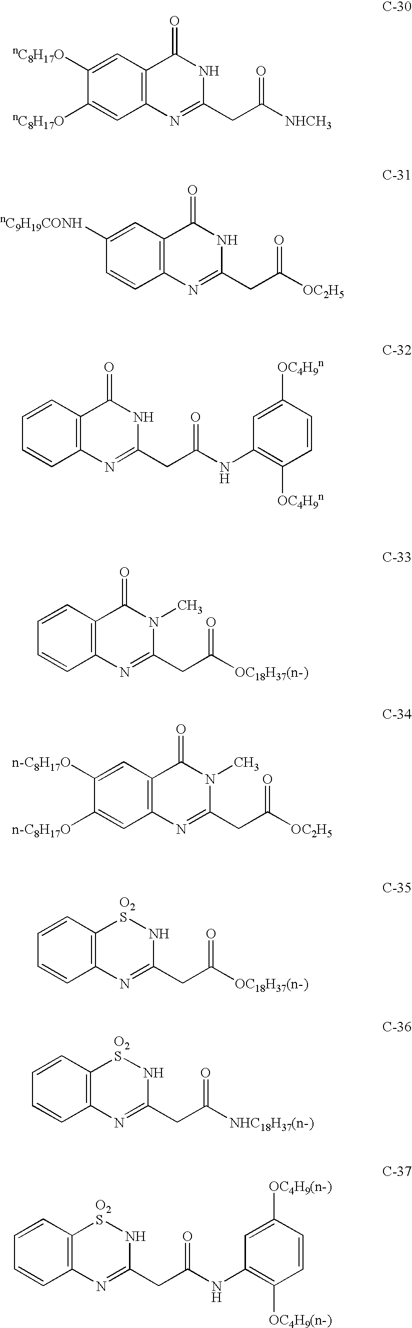

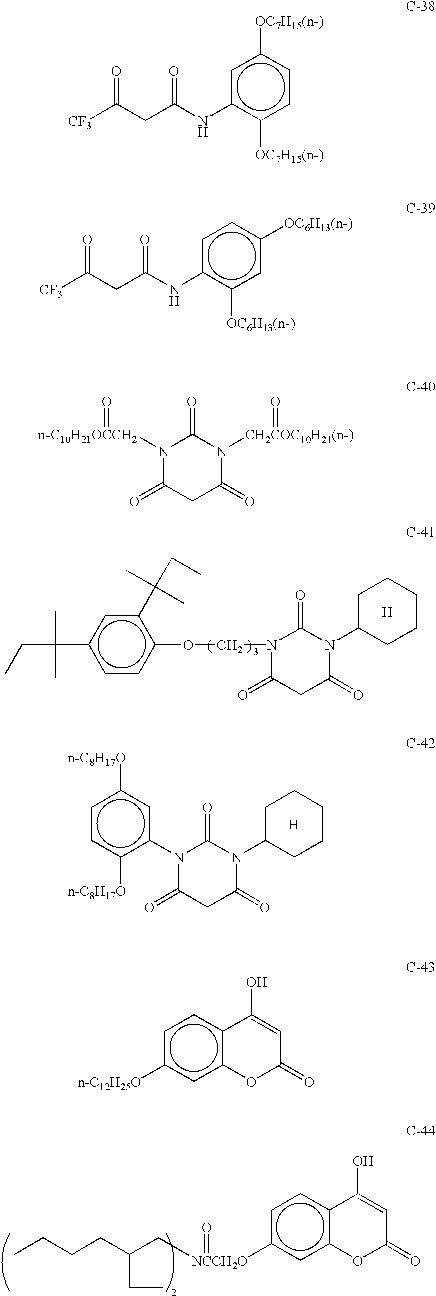

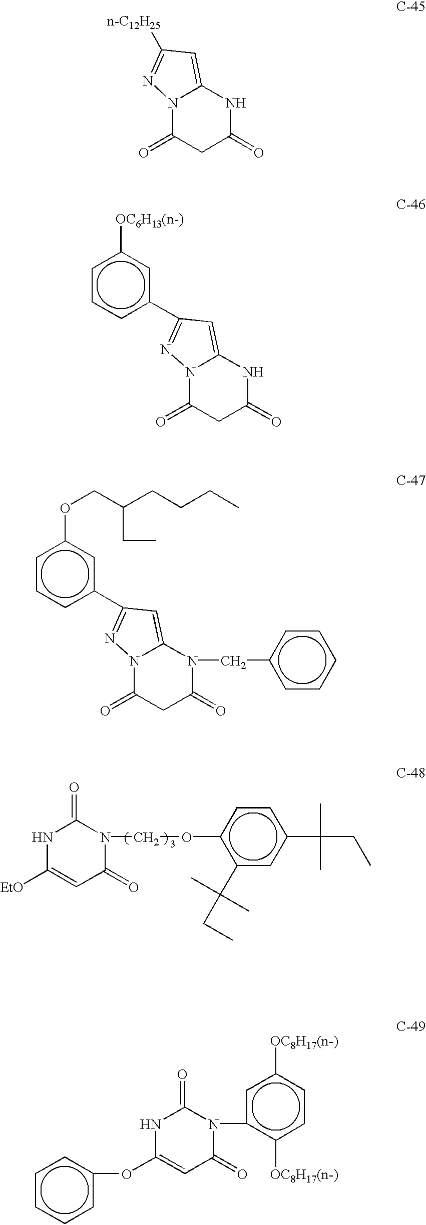

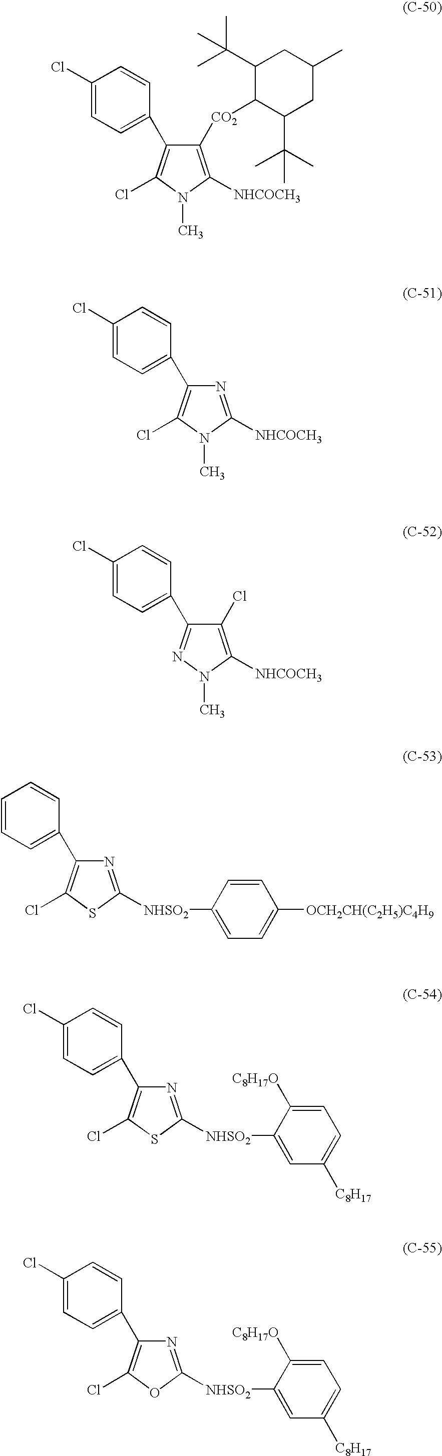

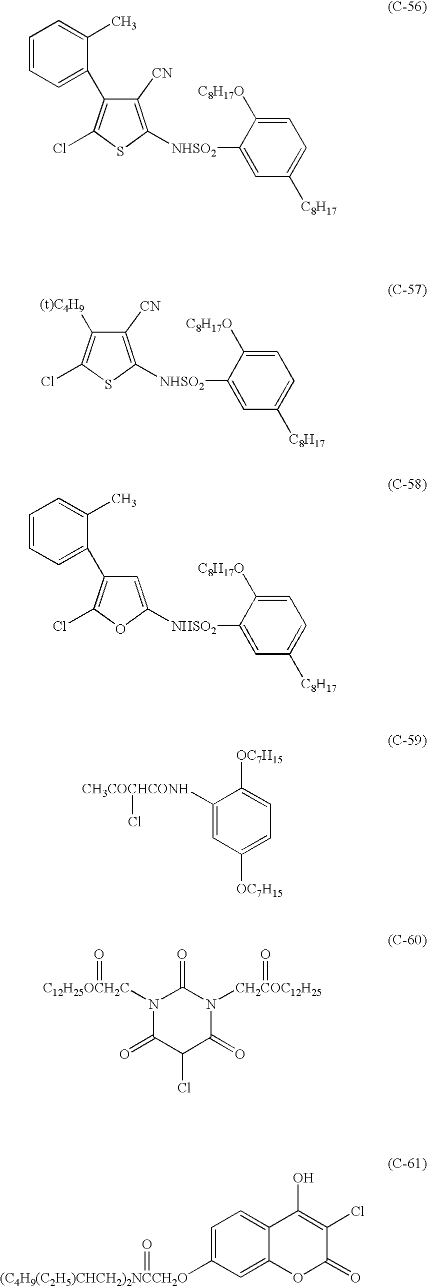

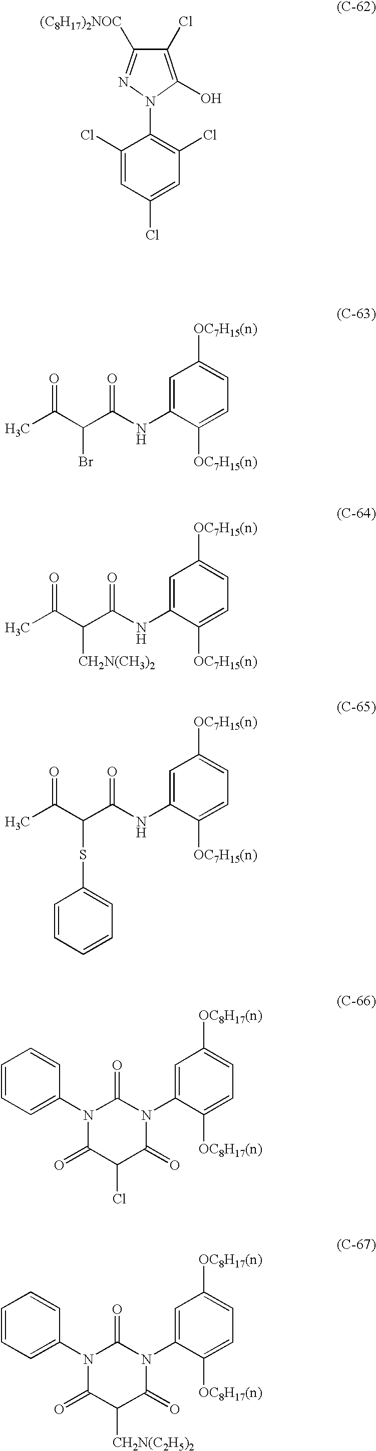

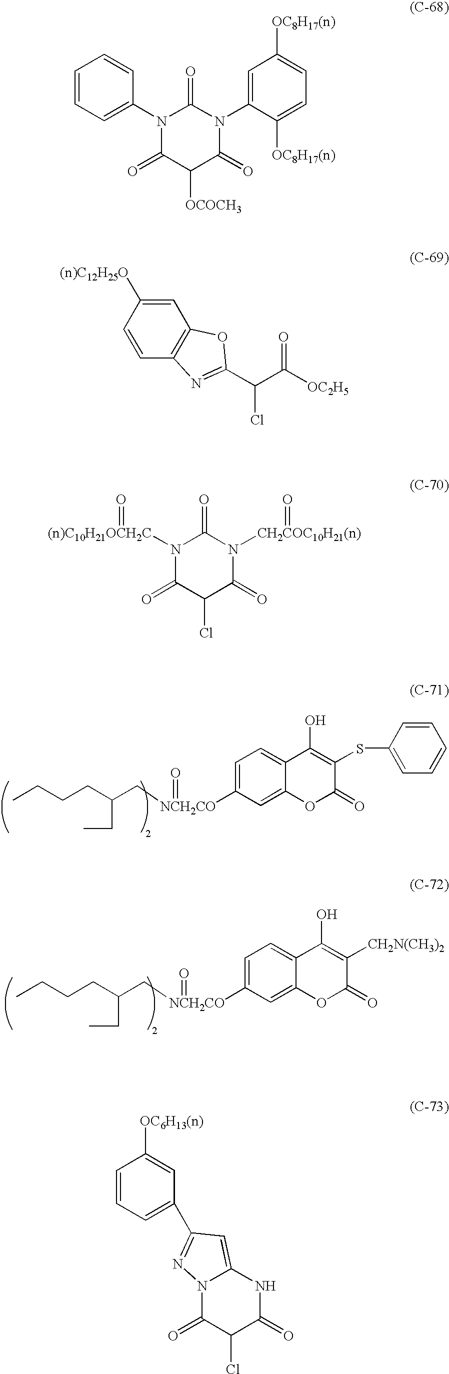

In the yellow heat-sensitive recording layer, the total coupler amount is preferably 1 to 10 times by mole as much as the amount of the diazo compound in the yellow heat-sensitive recording layer, and more preferably 2 to 5 times by mole as much as the amount of the diazo compound, in view of the effect of the invention.

When the amount is less than one time by mole, sufficient color-developability may not be obtained. When the amount is more than 10 times by mole, color-developability may similarly deteriorate, which is not preferable in view of coating thickness.

### Cyan Heat-Sensitive Recording Layer

The cyan heat-sensitive recording layer in the heat-sensitive recording material of the invention is disposed between the yellow heat-sensitive recording layer and the magenta heat-sensitive recording layer. The maximum absorbency wavelength λmax of the diazo compound or the like used in the cyan heat-sensitive recording layer is preferably 340 to 400 nm, and more preferably 360 to 390 nm, in view of the effect of the invention. When the diazo compound or the like has a longer λmax than the above-mentioned wavelength range, the diazo compound or the like may be inactivated by irradiation with light for fixing of the layer(s) above the cyan heat-sensitive recording layer. When the diazo compound or the like has a shorter λmax than the above-mentioned range, image-fixing ability, image-preserving ability and hues of developed colors from violet to cyan may deteriorate in combination with the corresponding coupler.

The diazonium salt used in the cyan heat-sensitive recording layer is preferably a compound represented by Ar⁻N₂⁺.X⁻, in which Ar represents an aromatic moiety and X⁻ represents an anion of an acid. This compound causes a coupling reaction with a coupler by heating, so as to color, and is decomposed or inactivated by light. The maximum absorbency wavelength of the compound can be controlled by changing the position or the kind of substituent in the Ar moiety.

Specific examples of the diazonium, which forms a salt, include 4-(p-tolylthio)-2,5-dibutoxybenzenediazonium, 4-(4-chlorophenylthio)-2,5-dibutoxybenzenediazonium, 4-(N,N-dimethylamino)benzenediazonium, 4-(N,N-diethylamino)benzenediazonium, 4-(N,N-dipropylamino)benzenediazonium, 4-(N-methyl-N-benzylamino)benzenediazonium, 4-(N,N-dibenzylamino)benzenediazonium, 4-(N-ethyl-N-hydroxyethylamino)benzenediazonium, 4-(N,N-diethylamino)-3-methoxybenzenediazonium, 4-(N,N-dimethylamino)-2-methoxybenzenediazonium, 4-(N-benzoylamino)-2,5-diethoxybenzenediazonium, 4-morpohlino-2,5-dibutoxybenzenediazonium, 4-anilinobenzenediazonium, 4-[N-(4-methoxybenzyol)amino]-2,5-diethoxybenzenediazonium, 4-pyrrolidino-3-ethylbenzenediazonium, 4-[N-(1-methyl-2-(4-methoxyphenoxy)ethyl)-N-hexylamino]-2-hexyloxybenzenediazonium, 4-[N-(2-(4-methoxyphenoxy)ethyl)-N-hexylamino]-2-hexyloxybenzenediazonium, and 2-(1-ethylpropyloxy)-4-[di-(di-n-butylaminocarbonylmethyl) amino]benzenediazonium.

Among the above-mentioned diazonium salts, diazonium salts represented by the following general formulae (A), (B) or (C) are preferable in view of hues of the dyes, image-preserving ability and image-fixing ability.

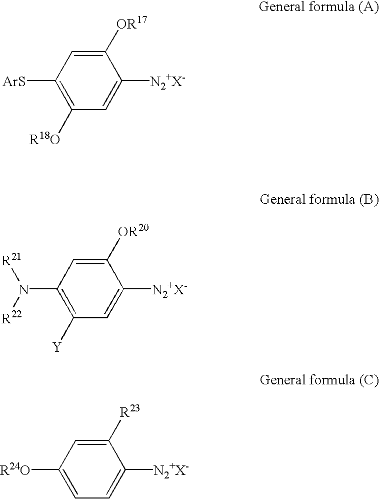

In the general formula (A), Ar represents a substituted or unsubstituted aryl group. R¹⁷ and R¹⁸ each independently represent a substituted or unsubstituted alkyl group, or a substituted or unsubstituted aryl group, and may be the same or mutually different.

Examples of the substituent include alkyl, alkoxy, alkylthio, aryl, aryloxy, arylthio, acyl, alkoxycarbonyl, carbamoyl, carboamide, sulfonyl, sulfamoyl, sulfonamide, ureido, amino and heterocyclic groups, and halogen atom. These substituents may be further substituted.

In the general formula (B), R²⁰, R²¹ and R²² each independently represent a substituted or unsubstituted alkyl group, or a substituted or unsubstituted aryl group, and may be the same or mutually different. Y represents a hydrogen atom or an OR¹⁹ group, wherein R¹⁹ represents a substituted or unsubstituted alkyl group or a substituted or unsubstituted aryl group.

Examples of the substituent include alkyl, alkoxy, alkylthio, aryl, aryloxy, arylthio, acyl, alkoxycarbonyl, carbamoyl, carboamide, sulfonyl, sulfamoyl, sulfonamide, ureido, amino and heterocyclic groups, and halogen atom.

In view of adjusting of hue, an alkyloxy group, wherein Y is a hydrogen atom or R¹⁹ is an alkyl group, is more preferable.

In the general formula (C), R²³ and R²⁴ each independently represent a substituted or unsubstituted alkyl group, or a substituted or unsubstituted aryl group, and may be the same or mutually different.

Examples of the substituent include alkyl, alkoxy, alkylthio, aryl, aryloxy, arylthio, acyl, alkoxycarbonyl, carbamoyl, carboamide, sulfonyl, sulfamoyl, sulfonamide, ureido, amino and heterocyclic groups, and halogen atom.

In the general formulae (A) to (C), X⁻ represents an anion of an acid, and examples thereof include polyfluoroalkylcarboxylic acid having 1 to 9 carbon atoms, polyfluoroalkylsulfonic acid having 1 to 9 carbon atoms, tetrafluoroboron, tetraphenylboron, hexafluorophosphoric acid, aromatic carboxylic acid, and aromatic sulfonic acid. Hexafluorophosphoric acid is preferable in view of crystallinity.

The following are specific examples of the diazonium salts represented by the general formulae (A), (B) and (C). In the invention, however, the diazonium salts are not limited thereto.

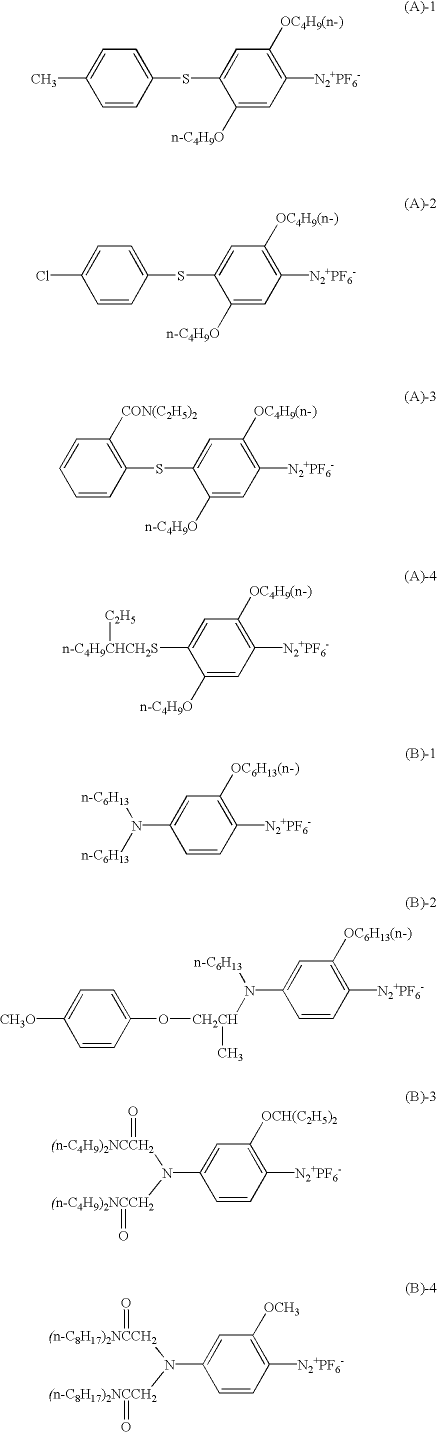

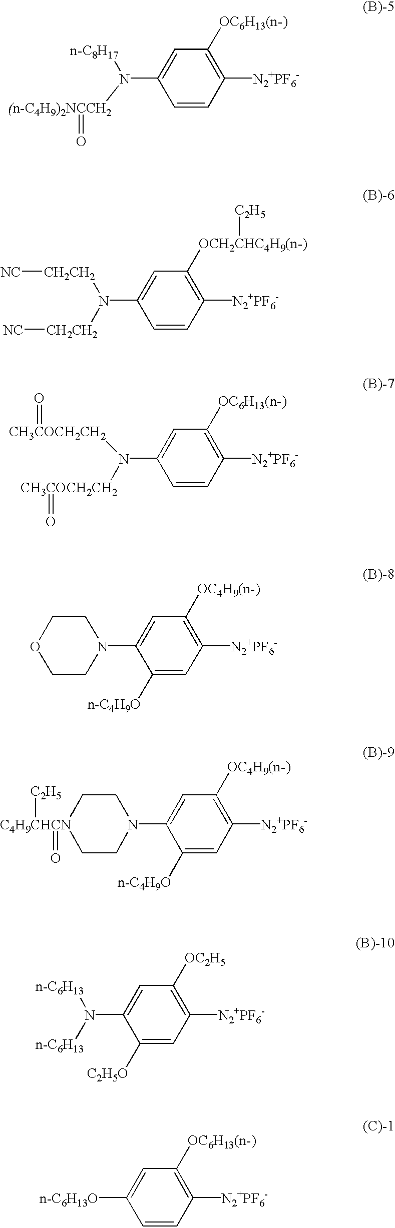

In the invention, the diazonium salts represented by the general formulae (A) to (C) may be used alone or in combination of two or more. The diazonium salts represented by the general formulae (A) to (C) may be used together with an existing diazonium salt, depending on various purposes such as adjustment of hue.

In the heat-sensitive recording material of the invention, the content of the diazonium salt in the heat-sensitive recording layer is preferably 0.02 to 3 g/m², and more preferably 0.1 to 2 g/m².

The cyan heat-sensitive recording layer preferably comprises, as a coupler, at least one of compounds represented by the general formulae (D), (E) or (F). These couplers have characteristics in that they are coupled with the diazonium salt, they produce a good cyan hue and a sufficient developed color density, and also causes improvement in image-preserving property against light and heat. These also have effects that a color-developing reaction can be effectively caused, Dmax is exhibited even in a small amount of the diazonium salt, and fixing sensitivity and stains can be reduced since the amount of the diazonium salt can be decreased.

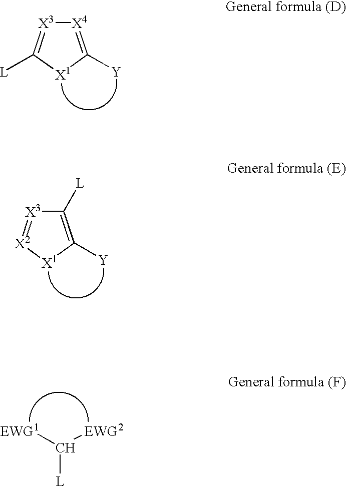

In the general formulae (D) to (F), X¹, X², X³ and X⁴ each independently represent an atomic group necessary for forming a 5-membered aromatic heterocyclic ring. Y represents an amino group, a substituted amino group, a hydroxyl group, an alkoxy group, or an alkyl group that may have a substituent. L represents a substituent which can leave when the coupler is coupled with the diazonium salt. EWG¹ and EWG² each independently represent an electron-withdrawing group. X¹ and Y, or EWG¹ and EWG² may be bonded to each other to form a heterocyclic ring.

Among the compounds represented by the general formulae (D) to (F), a pyrrolopyrimidineone compound represented by the following general formula (G) and a pyrrolotriazineone compound represented by the following general formula (H) are particularly preferable.

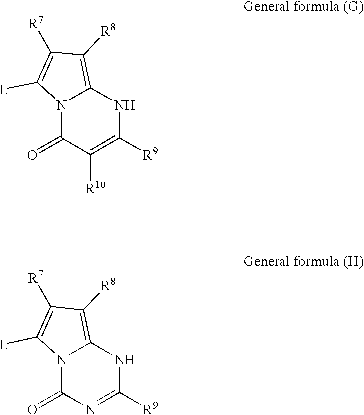

In the general formulae (G) and (H), R⁷ and R⁸ each independently represent a hydrogen atom, halogen atom, or aryl, alkyl, cyano, acyl, carbamoyl, alkoxycarbonyl, aryloxycarbonyl, alkylsulfonyl or arylsulfonyl group. R⁹ represents an amino, substituted amino, hydroxyl, acyloxy, arylcarboxy, alkoxy, aryloxy, alkylthio, or arylthio group. R¹⁰ represents a hydrogen atom, a halogen atom, or an electron-withdrawing group whose Hammett's substituent constant σₚ is 0.2 or more. L represents a substituent which can leave when the present compound reacts with the diazonium salt.

Among the substituents represented by R⁷ and R⁸, at least one of R⁷ and R⁸ is preferably an electron-withdrawing group whose Hammett's substituent constant σₚ is 0.20 or more. At least one of R⁷ and R⁸ is more preferably an electron-withdrawing group whose Hammett's substituent constant σₚ is 0.35 or more.

Among the withdrawing groups whose σₚ is 0.20 or more, preferable are cyano (σₚ: 0.66), perfluoroalkyl (for example, σₚ of trifluoromethyl: 0.54), acyl (for example, σₚ of acetyl: 0.50, and σₚ of benzoyl: 0.43), carbamoyl (σₚ: 0.36), and alkoxycarbonyl (for example, σₚ of ethoxycarbonyl: 0.45) groups. However, preferable substituents are not limited thereto.

Examples of the halogen atom include fluorine, chlorine and bromine atoms. A fluorine atom and a chlorine atom are more preferable.

In the general formula (G), preferable examples of the electron-withdrawing group whose Hammett's substituent constant σₚ is 0.2 or more include aryl, cyano, acyl, carbamoyl, alkoxycarbonyl, aryloxycarbonyl, alkylsulfonyl, arylsulfonyl, alkylphospholyl, arylphospholyl, and perfluoroalkyl groups. However, the electron-withdrawing groups are not limited thereto.

Details on the pyrropyrimidineone compound and pyrrolotriazineone compound are described in the specifications of Japanese Patent Applications Nos. 11-101546, 11-114929, and 11-317792. In the invention, all compounds described in these specifications can be suitably used.

The following are typical, specific examples of the couplers represented by the general formulae (D) to (F). In the invention, however, the couplers are not limited to these examples.

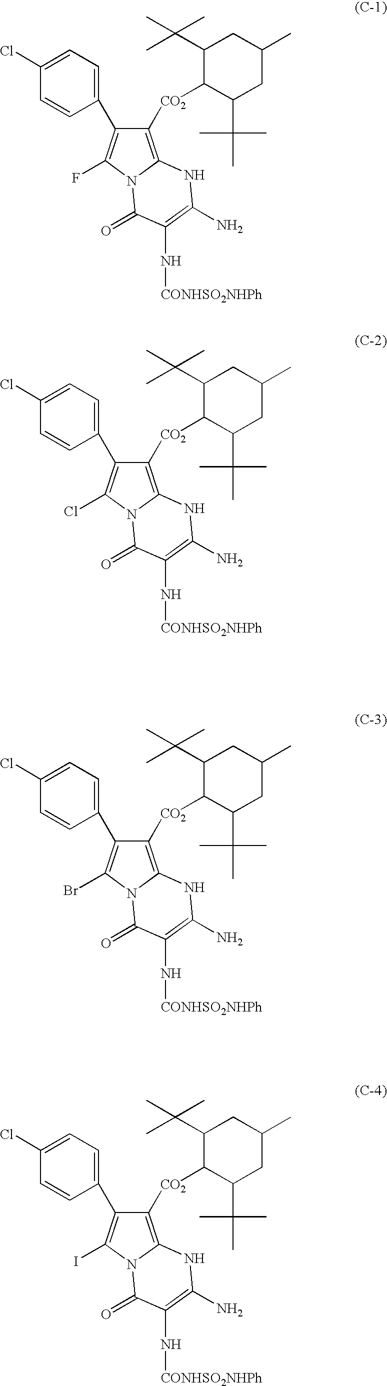

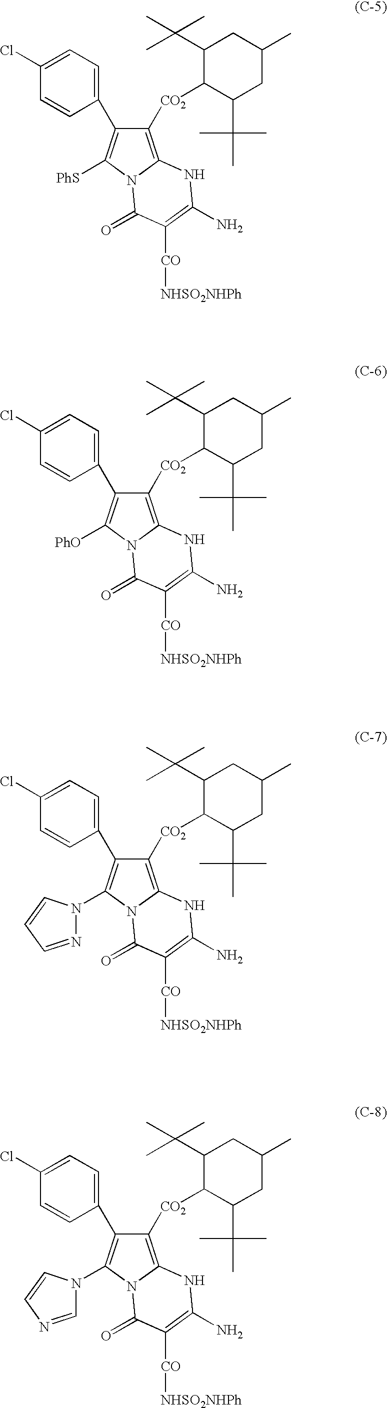

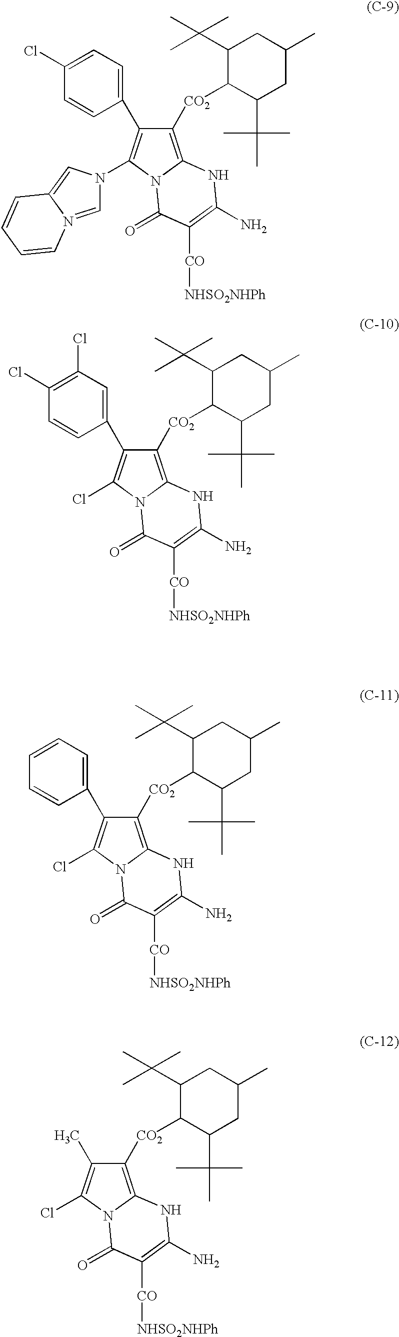

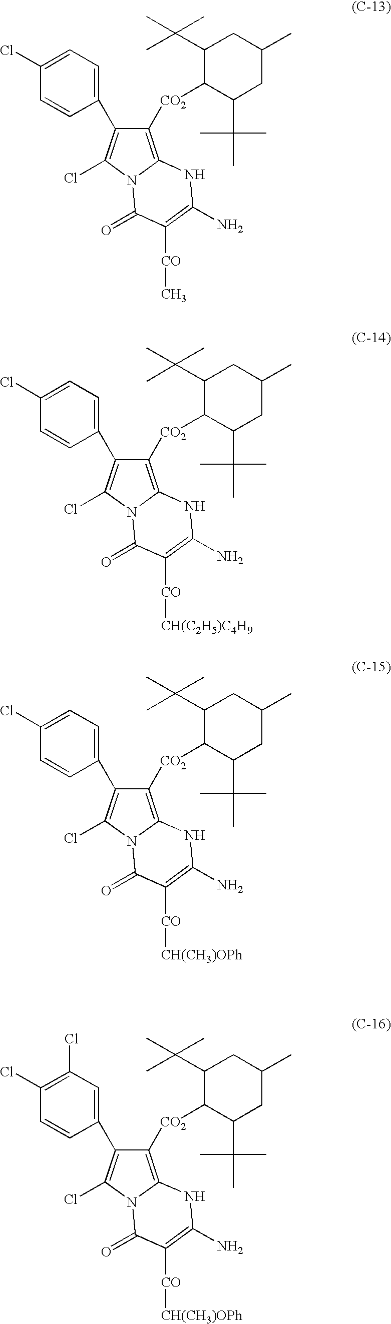

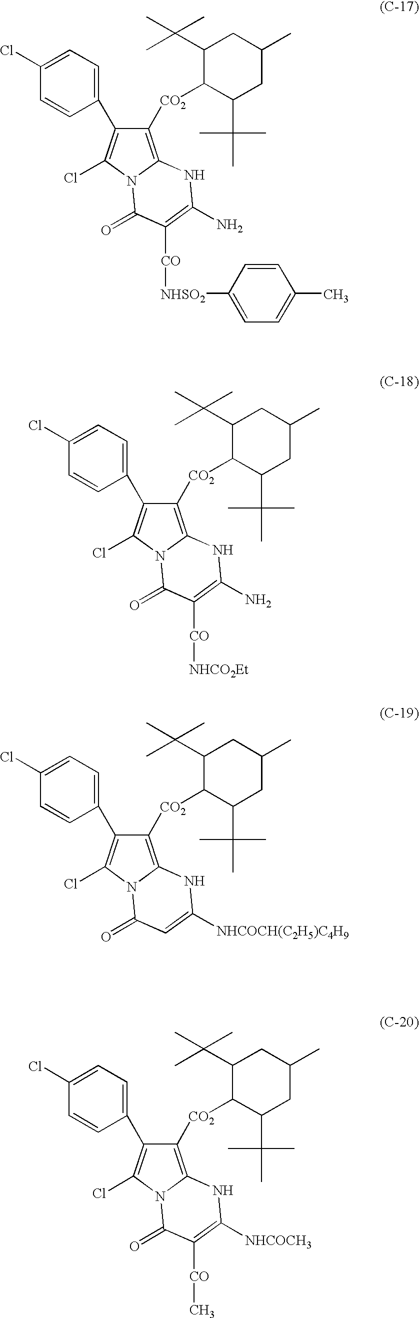

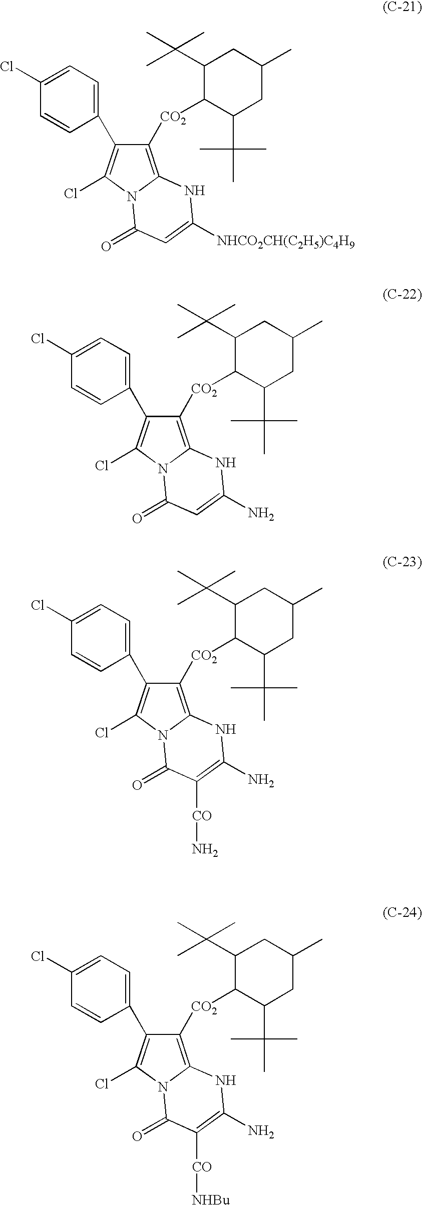

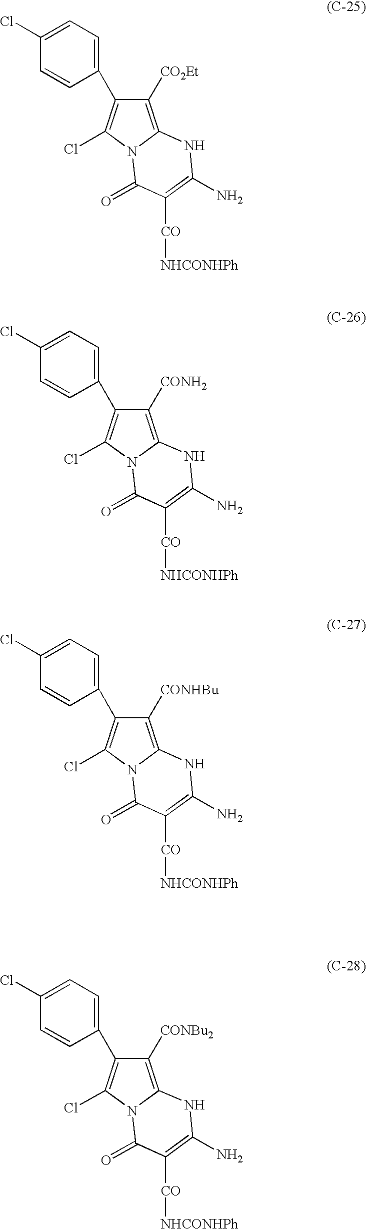

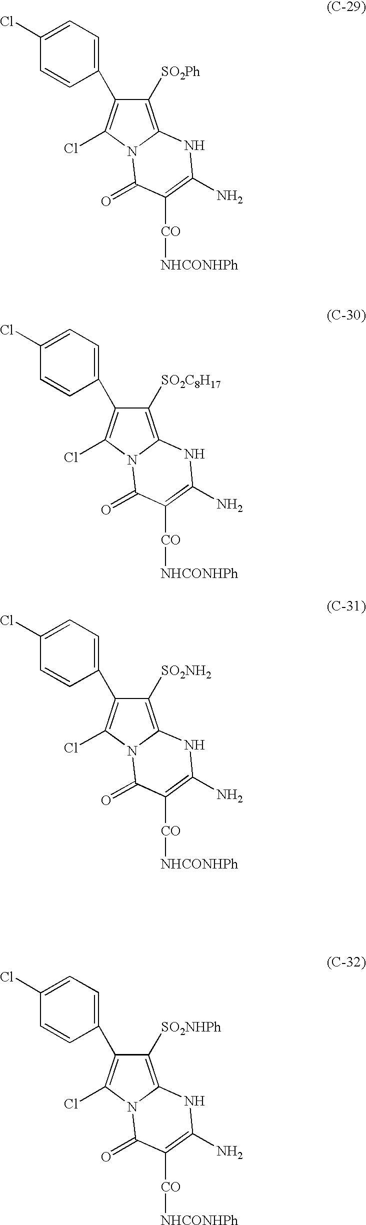

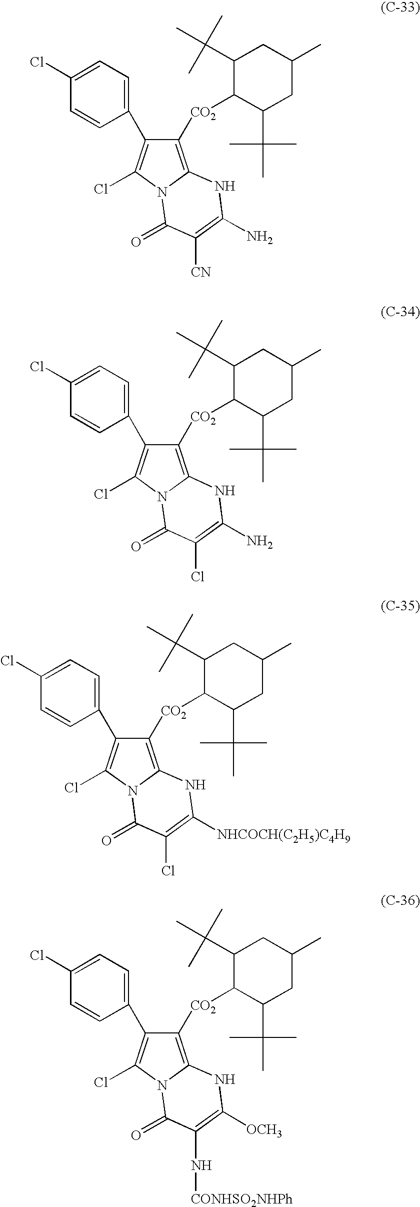

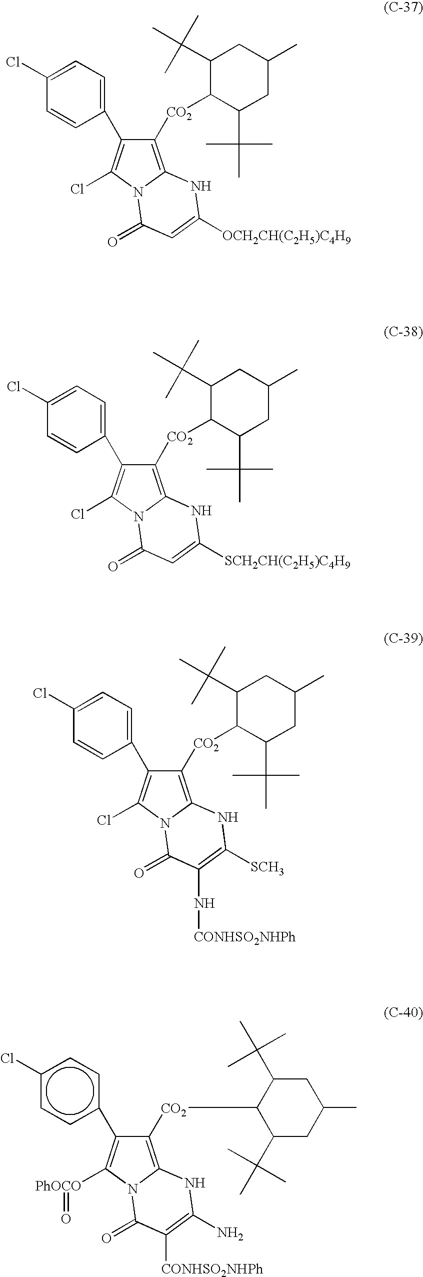

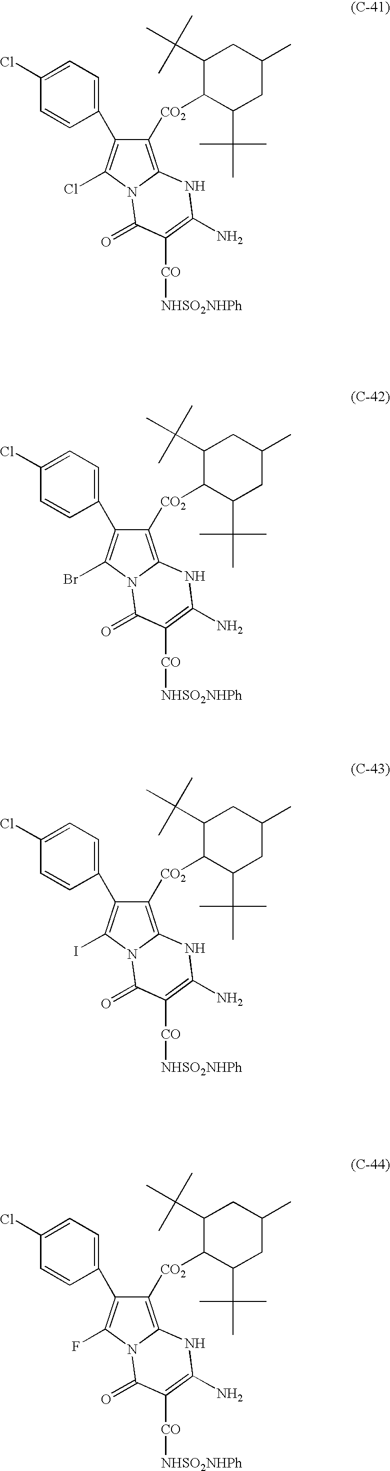

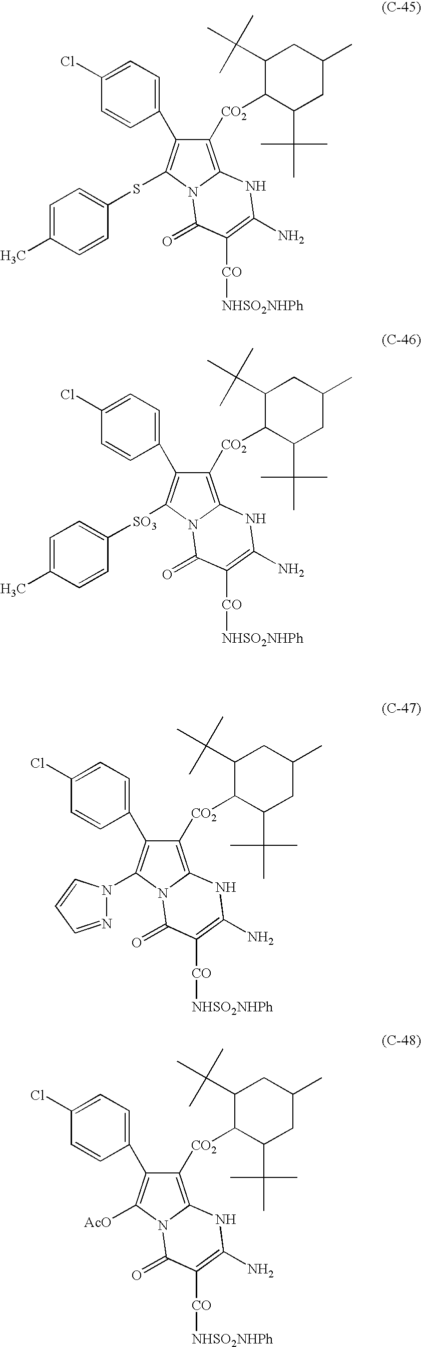

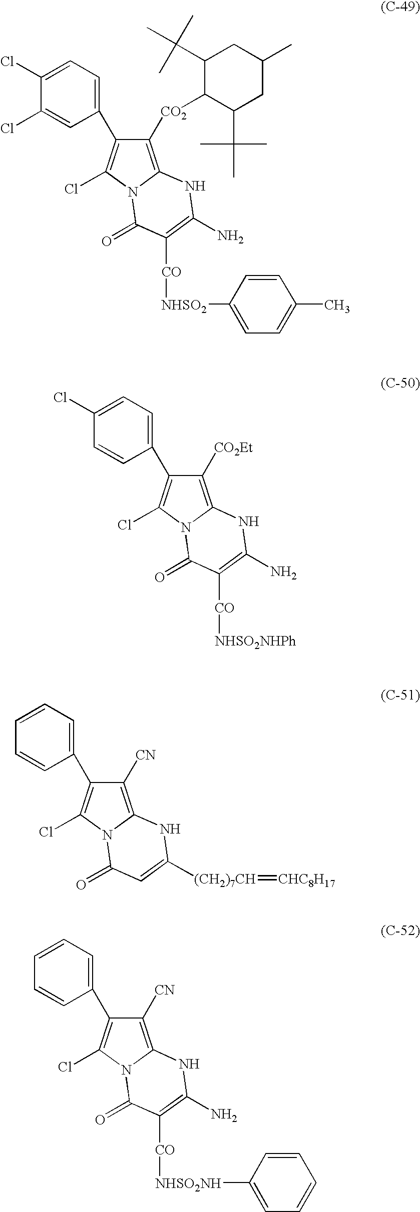

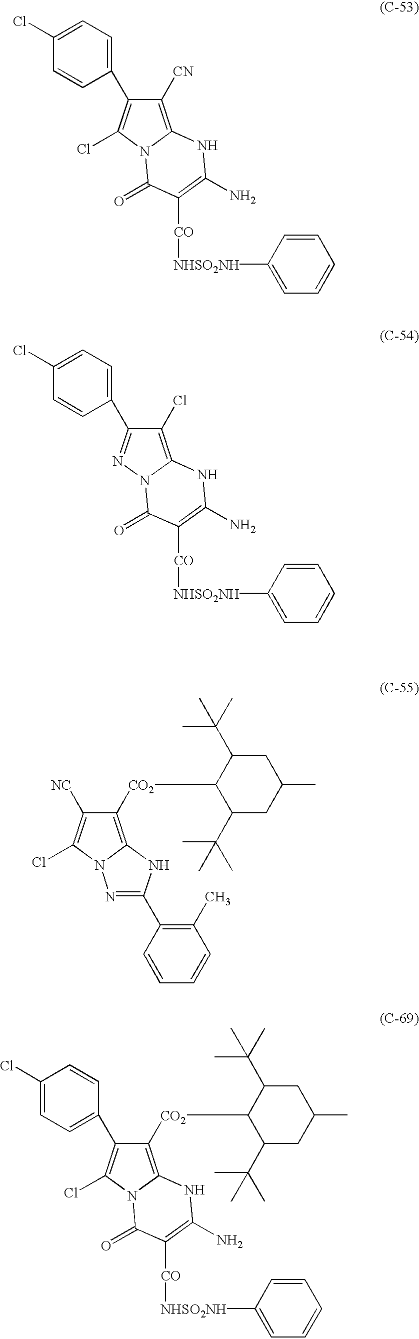

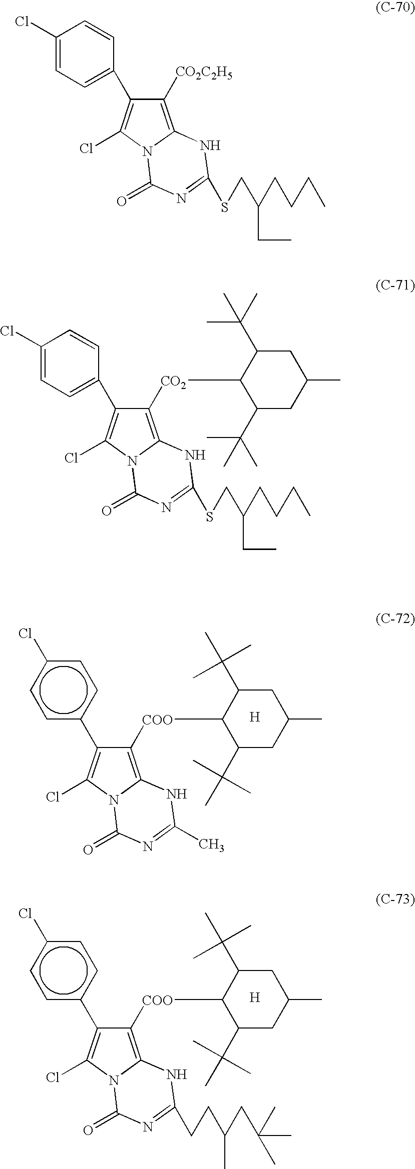

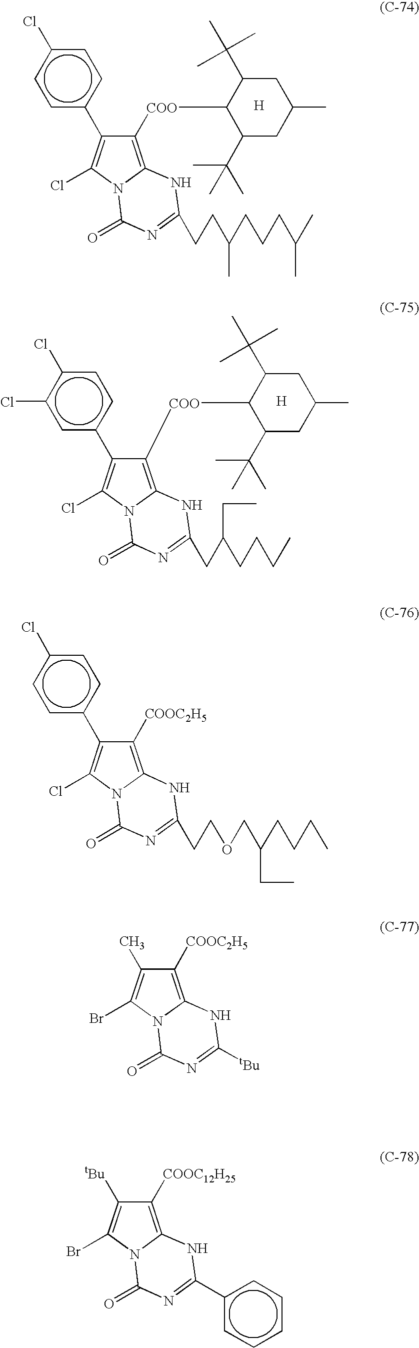

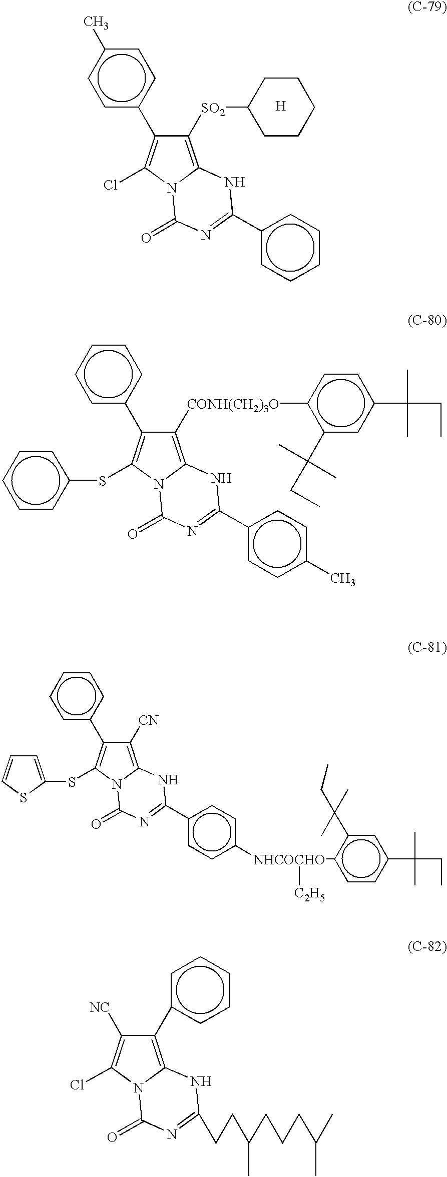

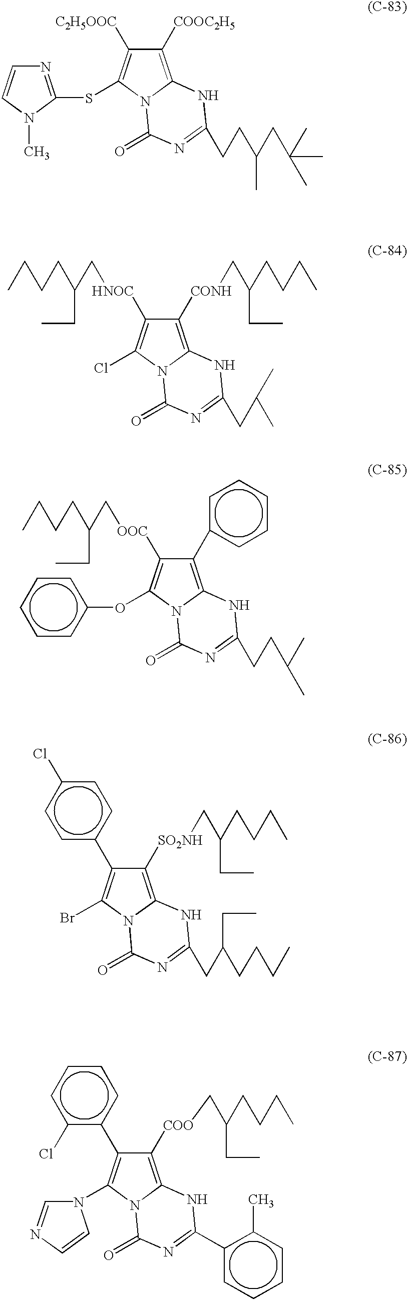

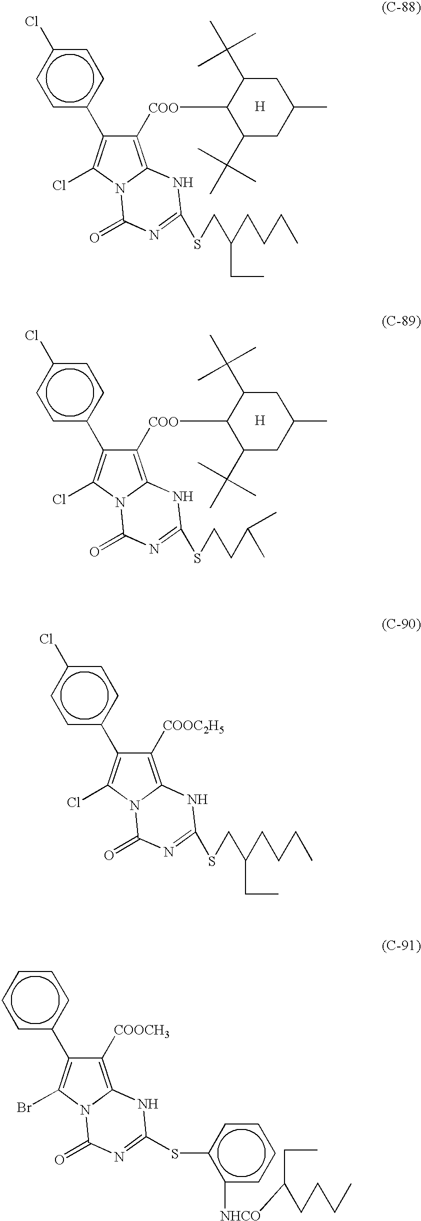

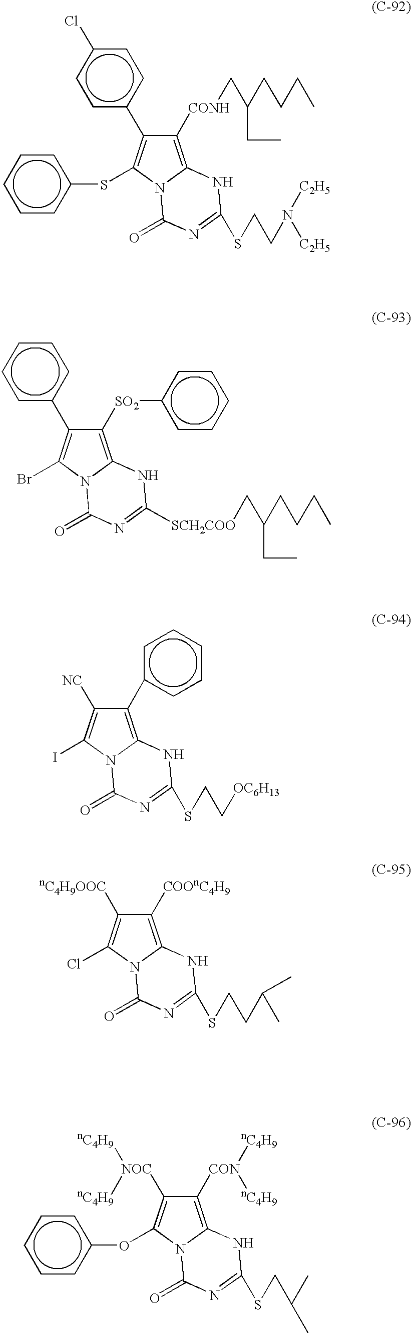

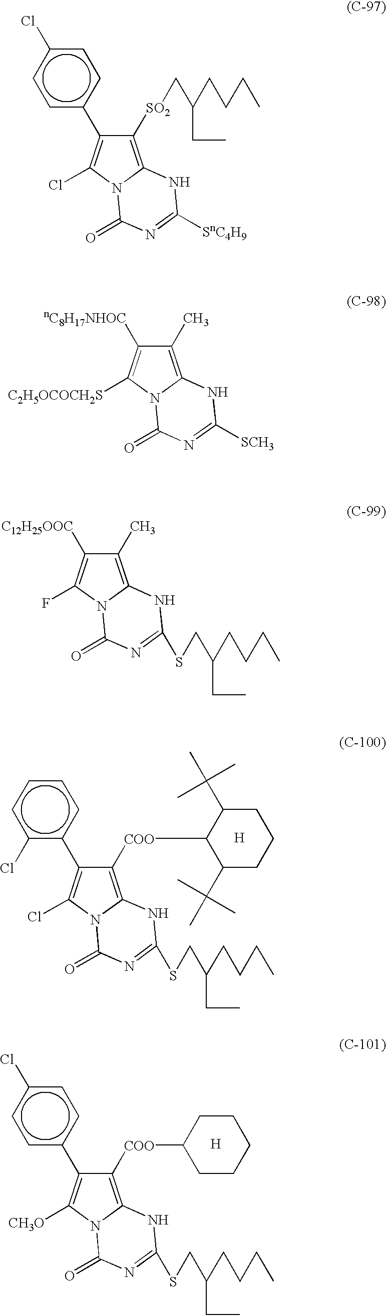

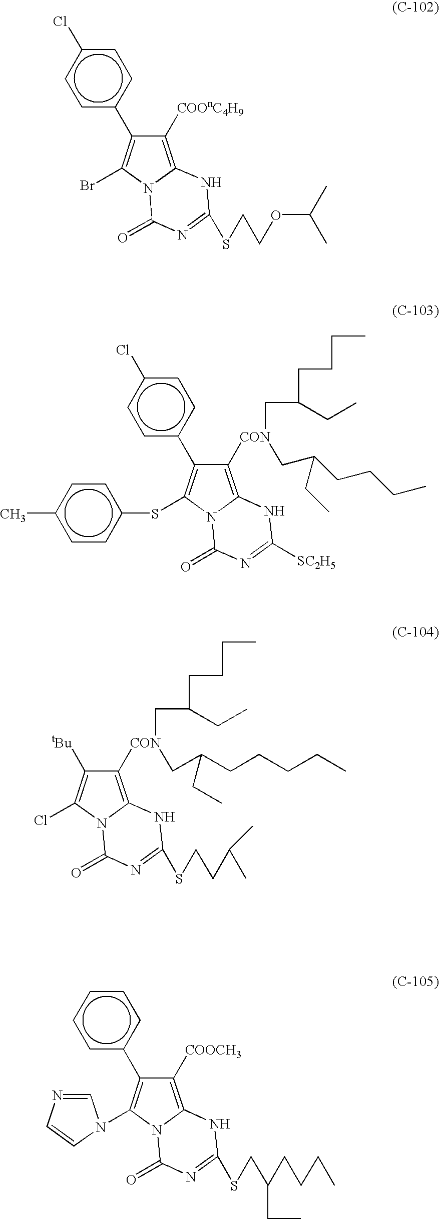

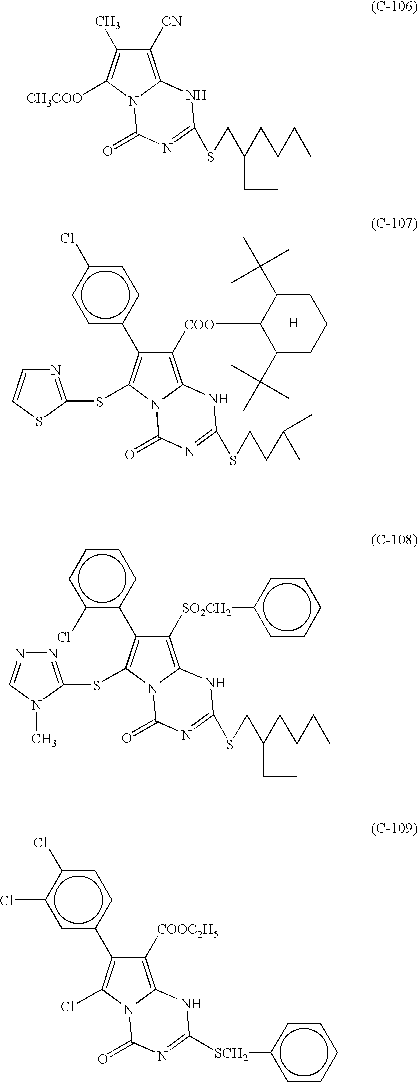

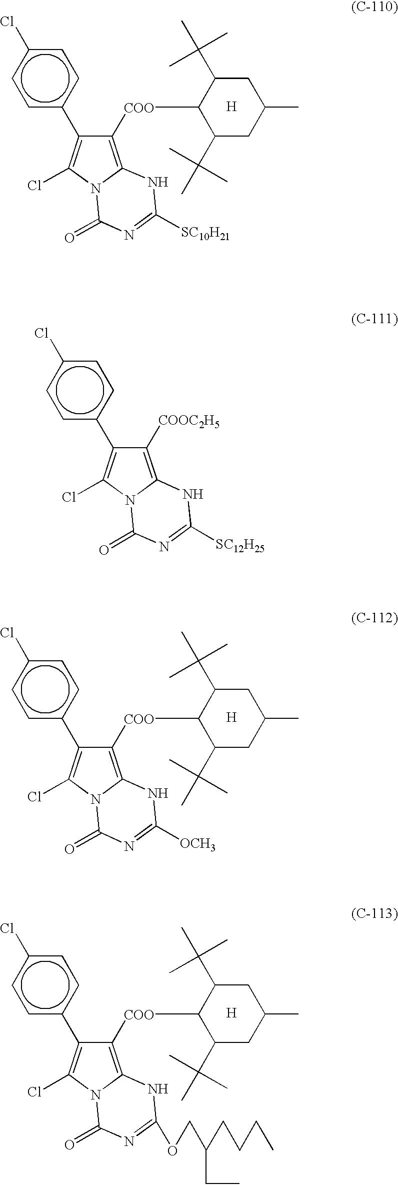

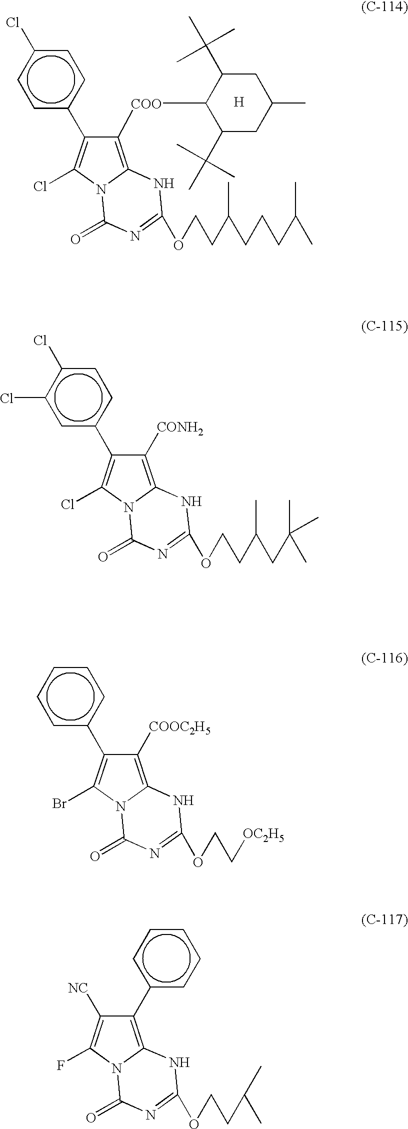

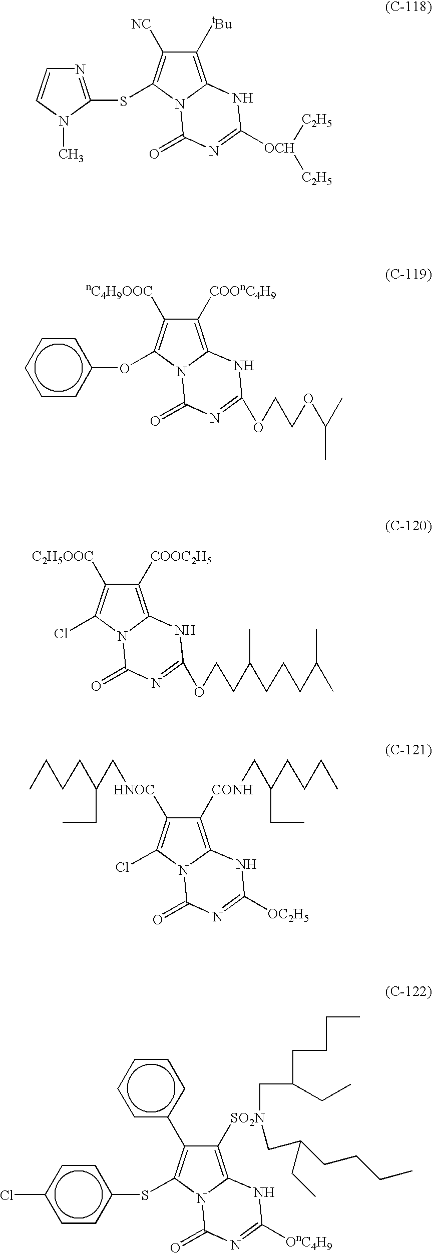

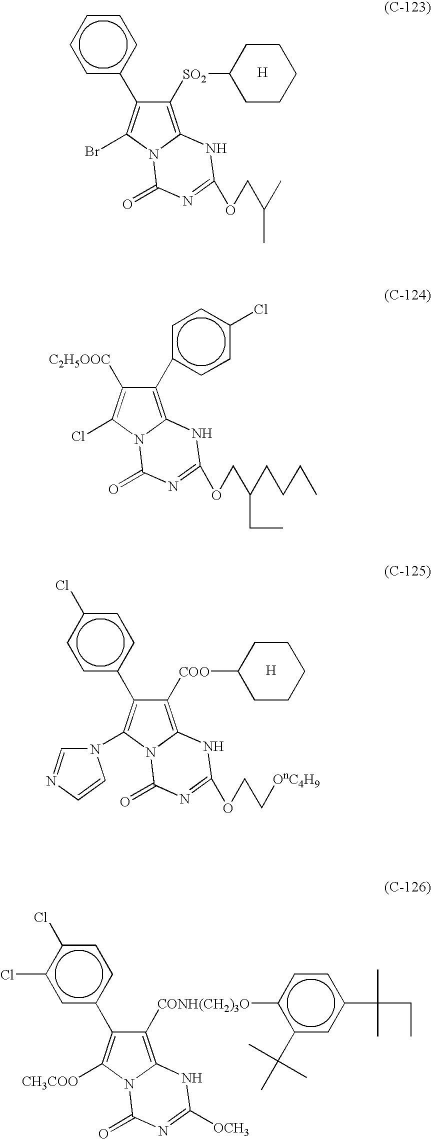

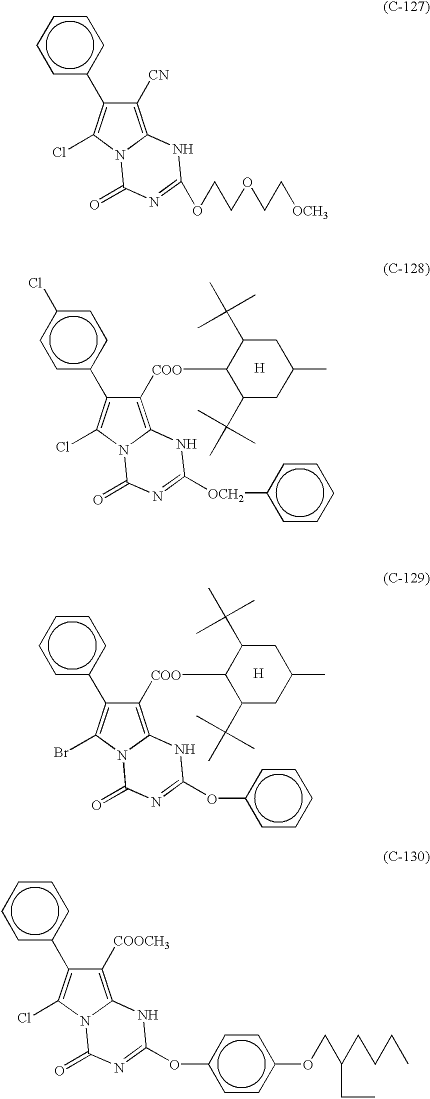

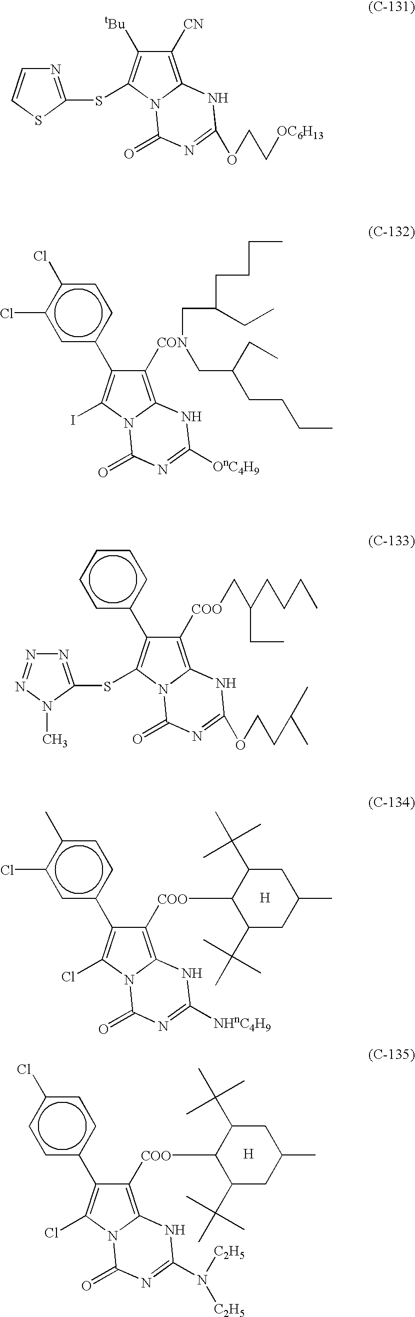

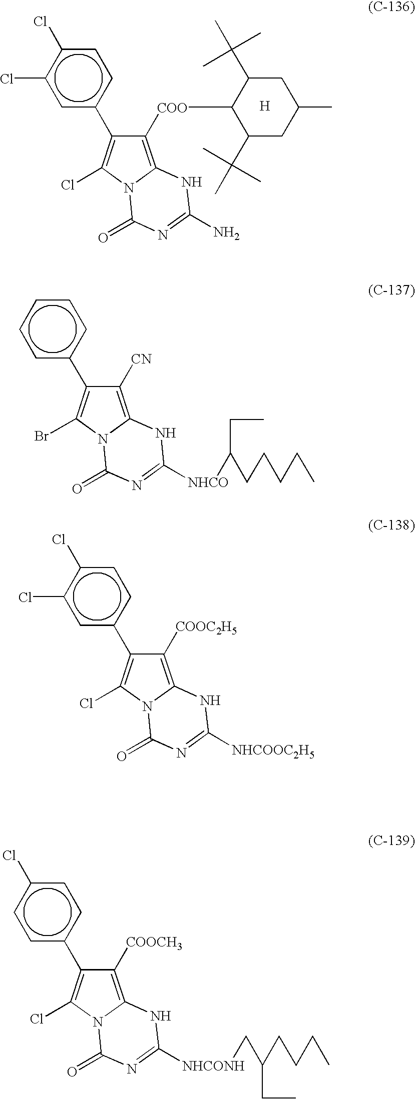

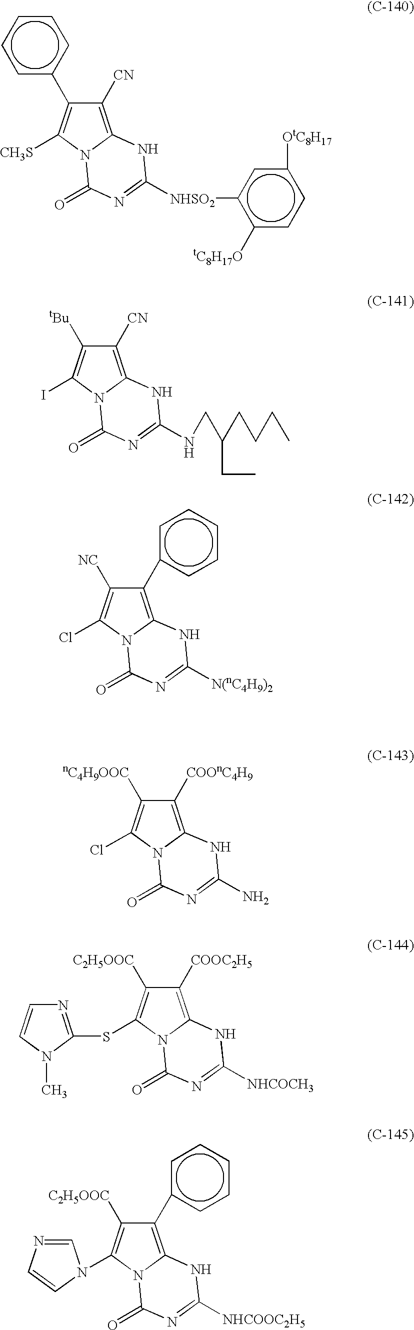

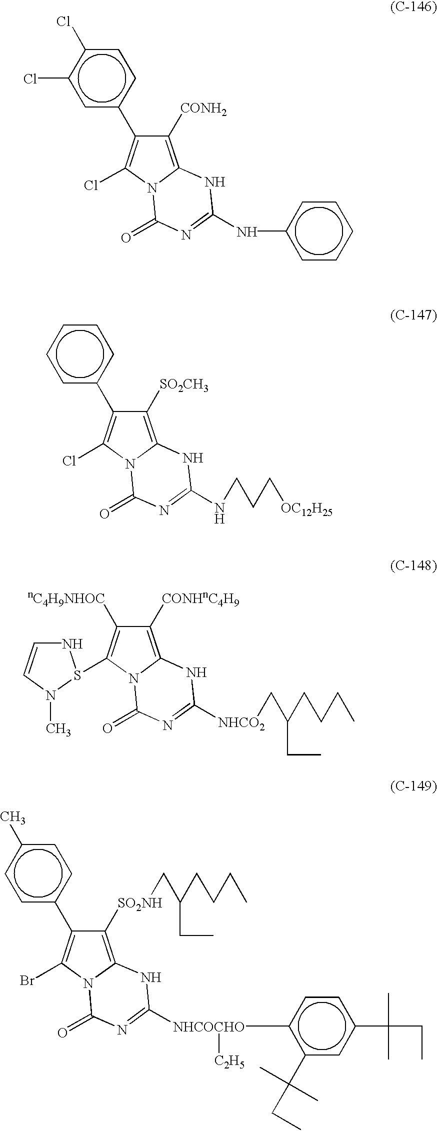

The above-mentioned coupler used in the cyan heat-sensitive recording layer may be used together with a known coupler, depending on various purposes such as adjustment of hue. Examples of known couplers include active methylene compounds having a methylene group adjacent to a carbonyl group, a phenol derivative, a naphthol derivative or the like. These can be used so far as the object of the invention is achieved. The known coupler may be any one of the known couplers previously listed in connection with the yellow heat-sensitive recording layer.

In the heat-sensitive recording material of the invention, the following reducing agent is preferably added to the heat-sensitive recording layer in order to promote the coupling reaction. Examples thereof include: an aminophenol-based, phenol-based, catechol-based, hydroquinone-based, amine-based, hydroxylamine-based, alcohol-based, thiol-based, sulfide-based, hydrazide-based, phenydone-based, aniline-based, phenyl ether-based, or L-ascorbic acid-based compounds; alkali metals; alkali earth metals; or metal hydrides. Hydroquinone-based, catechol-based, and aminophenol-based reducing agents are particularly preferable. Specific examples of these compounds include compounds (R-1) to (R-55) indicated in paragraphs [0067] to [0070] of the specification of Japanese Patent Application No. 2000-116580.

These reducing agents may be dispersed as solid fine particles, in the recording layer, or may be dissolved alone in oil and used as an emulsion. These reducing agents may be added to the oil phase of the emulsion of the coupler. When the diazo compound or the coupler is encapsulated into microcapsules, the reducing agents may be added to the inside of the microcapsules or to both the inside and the outside of the microcapsules.

The amount of the reducing agent is preferably from 1 to 10 times by mole, and more preferably from 1 to 4 times by mole, as much as the amount of the diazo compound. When the amount is less than one time by mole, the effects of improving color-developability and image-preserving ability may not be sufficiently achieved. When the amount is more than 10 times by mole, the effect of improving color-developability becomes small and shelf life may deteriorate.

In the cyan heat-sensitive recording layer, the total coupler amount is preferably 0.2 to 8 times by mole as much as the amount of the diazo compound in the cyan heat-sensitive recording layer. In view of the effect of the invention, the amount is more preferably 1 to 5 moles by mole.

When the amount is less than 0.2 times by mole, sufficient color-developability cannot be obtained. When the amount is more than 8 times by mole, suitability for coating may deteriorate.

Although water-soluble polymers can be added to the coupler of the invention together with other components and the coupler can be used by solidly dispersing it with a sand mill or the like, the coupler is preferably emulsified with an emulsification assistant. There is no particular limitation on how the coupler is solidly dispersed or emulsified, and conventionally known methods can be used. Details on such methods are described in JP-A Nos. 59-190886, 2-141279 and 7-17145.

### Magenta Heat-Sensitive Recording Layer

The magenta heat-sensitive recording layer is the outermost (topmost) layer of the heat-sensitive recording layers of the heat-sensitive recording material of the invention. The maximum absorbency wavelength λmax of the diazo compound or the like used in the magenta heat-sensitive recording layer is preferably 460 nm or less, and more preferably 430 to 460 nm, in view of the effect of the invention. When the diazo compound or the like has a longer λmax than the above-mentioned wavelength range, shelf life may deteriorate. When the diazo compound or the like has a shorter λmax than the above-mentioned wavelength range, fixation speed may deteriorate. The diazo compound or the like used in the magenta heat-sensitive recording layer is preferably a diazonium salt represented by the following general formula (8):

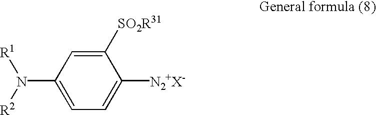

in which R¹ and R² each independently represent a hydrogen atom, an alkyl group or an aryl group; R³¹ represents an alkyl group or an aryl group; and X⁻ represents an anion.

In the general formula (8), R¹, R² and R³¹ each independently represent a hydrogen atom, an alkyl group or an aryl group, and X⁻ represents an anion. In the general formula (8), R¹ and R² are the same these as in the general formula (1) below and will be described later. In the general formula (8), the alkyl group represented by R³¹ may have a substituent, and is preferably an alkyl group having 1 to 3 carbon atoms as a whole. Preferable examples of the alkyl group include methyl, ethyl, n-propyl, i-propyl, n-butyl, t-butyl, s-butyl, i-butyl, n-pentyl, 2-pentyl, 3-pentyl, i-pentyl, n-hexyl, n-octyl, 2-ethylhexyl, 3,5,5-trimethylhexyl, n-dodecyl, cyclohexyl, benzyl, 2-chlorobenzyl, 2-methylbenzyl, 3-chlorobenzyl, 3-methylbenzyl, 3-methoxybenzyl, α-methylbenzyl, allyl, 2-chloroethyl, methoxycarbonylmethyl, methoxycarbonylethyl, and butoxycarbonylethyl groups. The aryl group represented by R³¹ may have a substituent, and is preferably an aryl group having 6 to 30 carbon atoms as a whole. Preferable examples thereof include phenyl, 4-methylphenyl, 3-methylphenyl, 2-methylphenyl, 4-chlorophenyl and 2-chlorophenyl groups. The diazonium salt represented by the general formula (8) is particularly preferably a diazonium salt represented by the following general formula (1):

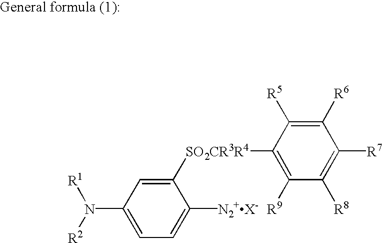

in which R¹ and R² each independently represent a hydrogen atom, an alkyl group or an aryl group.

This alkyl group is preferably an allyl group having 1 to 20 carbon atoms, and may or may not have a substituent. Examples thereof include methyl, ethyl, n-propyl, isopropyl, n-butyl, t-butyl, n-hexyl, n-octyl, 2-ethylhexyl, 3,5,5-trimethylhexyl, n-decyl, n-dodecyl, 2-chloroethyl, 2-methanesulfonylethyl, 2-methoxyethyl, N,N-dibutylcarbamoylmethyl, 2-ethoxycarbonylethyl, butoxycarbonylmethyl, 2-isopropyloxyethyl, 2-(2,5-di-t-amylphenoxy)ethyl, 2-phenoxyethyl, 1-(4-methoxyphenoxy)-2-propyl, 1-(2,5-di-t-amylphenoxy)-2-propyl, allyl, benzyl, a(-methylbenzyl, 4-chlorobenzyl, 2-chlorobenzyl, 3,4-dichlorobenzyl, 4-fluorobenzyl, trichloromethyl, trifluoromethyl, and 2,2,2-trifluoromethyl groups.

The above-mentioned aryl group is preferably an aryl group having 6 to 30 carbon atoms, and may or may not have a substituent. Examples thereof include phenyl, 4-methylphenyl and 2-chlorophenyl groups.

Of these, an aryl group having 6 to 10 is more preferable, and phenyl and 4-methylphenyl groups are particularly preferable.

When the R¹ and R² are alkyl groups in the general formula (1), R¹ and R² may be bonded to each other to form a cyclic structure, i.e., a cyclic group containing a nitrogen atom. Examples of the cyclic group include pyrrolidino, piperidino, morpholino, 4-octanoylpiperazino, 4-(2-(2,4-di-t-amylphenoxy))butanoylpiperazino, 4-(2-(n-octyloxy)-5-t-octylphenyl)sulfonylpiperazino, hexamethyleneimino, and indolino groups. Of these, pipedino and hexamethyleneimino groups are preferable.

More preferably, at least one of R¹ and R² in the general formula (1) is a methyl group.

R³and R⁴ in the general formula (1) each independently represent a hydrogen atom, an alkyl group, an aryl group or a halogen atom. The alkyl and aryl groups are the same as those mentioned in the case of the above-mentioned R¹ and R². More preferably, at least one of R³ and R⁴ in the general formula (1) is a methyl group.

Examples of the above-mentioned halogen atom include fluorine, chlorine, bromine and iodine atoms. Of these, fluorine and chlorine atoms are preferable.

R⁵, R⁶, R⁷, R³ and R⁹ in the general formula (1) each independently represent a hydrogen or halogen atom, or an alkyl, aryl, alkoxy, aryloxy, alkoxycarbonyl, acyloxy, carbamoyl, amide, cyano, alkylthio, arylthio, alkylsulfonyl or arylsulfonyl group, but at least one of R⁵ to R⁹ is a halogen atom.

The above-mentioned alkyl and aryl groups are the same as those mentioned in the case of the above-mentioned R¹ and R². The above-mentioned halogen atom is the same as that mentioned in the case of the above-mentioned R³ and R⁴.

The above-mentioned alkoxy group is preferably an alkoxy group having 1 to 20 carbon atoms, and may or may not have a substituent. Examples thereof include methoxy, ethoxy, n-butoxy, t-butoxy, hexyloxy, octyloxy, 2-ethylhexyloxy, trifluoromethoxy, 2-ethoxyethoxy, 2-chloroethoxy, 2-phenoxyethoxy, benzyloxy, 2-chlorobenzyloxy, 4-chlorobenzyloxy, 3,4-dichlorobenzyloxy, allyloxy-2,4-di-t-amylphenoxyethoxy, and 2,4-di-t-amylphenoxybutoxy groups.

Of these, alkoxy groups having 1 to 10 carbon atoms are more preferable, and methoxy, ethoxy, n-butoxy and benzyloxy groups are particularly preferable.

The above-mentioned aryloxy group is preferably an aryloxy group having 6 to 20 carbon atoms, and may or may not have a substituent. Examples thereof include phenoxy, 4-methylphenoxy, 4-methoxyphenoxy, 4-chlorophenoxy, 2-chlorophenoxy and 2,4-di-t-amylphenoxy groups.

Of these, aryloxy groups having 6 to 10 carbon atoms are more preferable, and phenoxy, 4-methylphenoxy and 4-methoxyphenoxy groups are particularly preferable.

The above-mentioned alkoxycarbonyl group is preferably an alkoxycarbonyl group having 2 to 20 carbon atoms, and may or may not have a substituent. Examples thereof include methoxycarbonyl, ethoxycarbonyl, n-butoxycarbonyl, and 2-ethoxyethoxycarbonyl groups.

Of these, alkoxycarbonyl groups having 2 to 10 carbon atoms are more preferable, and methoxycarbonyl, ethoxycarbonyl and n-butoxycarbonyl groups are particularly preferable.

The above-mentioned acyloxy group is preferably an acyloxy group having 2 to 20 carbon atoms, and may or may not have a substituent. Examples thereof include acetyloxy, butanoyloxy, chloroacetyloxy, phenoxyacetyloxy, and benzoyloxy groups.

Of these, acyloxy groups having 3 to 10 carbon atoms are more preferable, and acetyloxy, phenoxyacetyloxy and benzoyloxy groups are particularly preferable.

The above-mentioned carbamoyl group is preferably a carbamoyl group having 1 to 20 carbon atoms, and may or may not have a substituent. Examples thereof include unsubstituted carbamoyl, N,N-dimethylcarbamoyl, piperidinocarbonyl, and N,N-di(2-ethylhexyl)carbamoyl groups.

Of these, carbamoyl groups having 1 to 10 carbon atoms are more preferable, and unsubstituted carbamoyl and piperidinocarbamoyl groups are particularly preferable.

The above-mentioned amide group is preferably an amide group having 2 to 20 carbon atoms, and may or may not have a substituent. Examples thereof include acetylamino, butanoylamino, pivaroylamino, octanoylamino, and benzoylamino groups.

Of these, amide groups having 2 to 10 carbon atoms are more preferable, and acetylamino, and butanoylamino groups are particularly preferable.

The above-mentioned alkylthio group is preferably an alkylthio group having 1 to 20 carbon atoms, and may or may not have a substituent. Examples thereof include methylthio, ethylthio, butylthio, octylthio, 2-ethylhexylthio, dodecylthio, and benzylthio groups.

Of these, alkylthio groups having 1 to 10 carbon atoms are more preferable, and methylthio, ethylthio, butylthio, and benzylthio groups are particularly preferable.

The above-mentioned arylthio group is preferably an arylthio group having 6 to 20 carbon atoms, and may or may not have a substituent. Examples thereof include phenylthio, 4-chlorophenylthio, 2-chlorophenylthio, and 4-methylthio groups.

Of these, arylthio groups having 6 to 10 carbon atoms are more preferable, and phenylthio and 2-chlorophenylthio groups are particularly preferable.

The above-mentioned alkylsulfonyl group is preferably an alkylsulfonyl group having 1 to 20 carbon atoms, and may or may not have a substituent. Examples thereof include methylsulfonyl, ethylsulfonyl, butylsulfonyl, octylsulfonyl, dodecylsulfonyl, and benzylsulfonyl groups.

Of these, alkylsulfonyl groups having 1 to 10 carbon atoms are more preferable, and methylsulfonyl, ethylsulfonyl, butylsulfonyl and benzylsulfonyl groups are particularly preferable.

The above-mentioned arylsulfonyl group is preferably an arylsulfonyl group having 1 to 20 carbon atoms, and may or may not have a substituent. Examples thereof include phenylsulfonyl, 4-chlorophenylslufonyl, 2-chlorophenylsulfonyl and 4-methylsulfonyl groups.

Of these, arylsulfonyl groups having 6 to 10 are more preferable, and phenylsulfonyl and 2-chlorophenylsulfonyl groups are particularly preferable.

When the group represented by each of R¹ to R⁹ has a substituent in the general formula (1), the substituent may be any one of diazonium salts represented by the above-mentioned general formula (1), and general formulae (2) and (6), which will be described later. In other words, a dimer of the diazonium salt, or multimers thereof may be formed.

X⁻ in the general formula (1) represents an anion. The anion may be an inorganic anion or an organic anion.

Examples of the above-mentioned inorganic anion include a hexafluorophosphate anion, a borofluoric ion, a chloride ion, a sulfate ion, and a hydrogensulfate ion. Of these, a hexafluorophosphate anion and a borofluoric ion are more preferable.

Examples of the above-mentioned organic anion include a polyfluoroalkylsulfonate ion, a polyfluoroalkylcarbonate ion, a tetraphenylborate ion, an aromatic carbonate ion, and an aromatic sulfonate ion. Of these, a polyfluoroalkylsulfonate ion is more preferable.

Of the diazonium salts represented by the general formula (1), a diazonium salt represented by the general formula (2) is preferable:

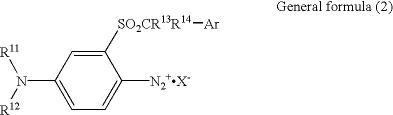

in which R¹¹ and R¹² each independently represent an alkyl group, which has the same meaning as in the case of each of R¹ and R² in the general formula (1); R¹³ and R¹⁴ each independently represent a hydrogen atom, an alkyl group, which is the same as that mentioned in the case of each of the above-mentioned R¹ and R², or a halogen atom, which has the same meanings as each of R³ and R⁴ in the general formula (1); and X⁻ represents an anion, which is the same as that mentioned in the general formula (1). At least one of R¹¹ and R¹² is preferably a methyl group and at least one of R¹³ and R¹⁴ is preferably a methyl group.

Ar in the general formula (2) represents the following general formula (3), (4) or (5):

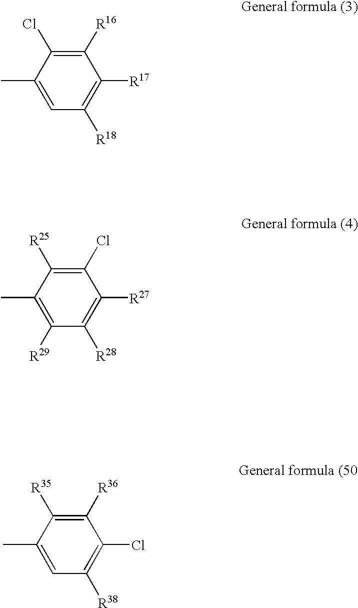

In the general formula (3), R¹⁶, R¹⁷ and R¹⁸ each independently represent a hydrogen atom, an alkyl group, an aryl group, a halogen atom, an alkoxy group or an aryloxy group. In the general formula (4), R²⁵, R²⁷, R²⁸ and R²⁹ each independently represent a hydrogen atom, an alkyl group, an aryl group, a halogen atom, an alkoxy group, or an aryloxy group, and at least one of R²⁵ and R²⁹ represents a hydrogen atom. In the general formula (5), R³⁵, R³⁶ and R³⁸ each independently represent a hydrogen atom, an alkyl group, an aryl group, an alkoxy group or an aryloxy group.

Each of the alkyl groups and the aryl groups in the general formulae (3) to (5) is the same as that mentioned in the case of R¹ and R² in the general formula (1). The above-mentioned halogen atom is the same as that mentioned in the case of R³ and R⁴, and the above-mentioned alkoxy and aryloxy groups have the same meanings as in the case of R⁵ to R⁹ in the general formula (1).

Of the diazonium salts represented by the general formula (2), a diazonium salt represented by the following general formula (6) is more preferable:

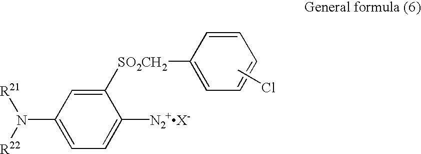

in which R²¹ and R²² each independently represent an alkyl group; X⁻ represents an anion; and the alkyl group and the anion are the same as those mentioned in the case of R¹, R² and X⁻ in the general formula (1). At least one of R²¹ and R²² is preferably a methyl group.

The diazonium salt compound which can be used in the magenta heat-sensitive recording layer is preferably a diazonium salt represented by the following general formula (9):

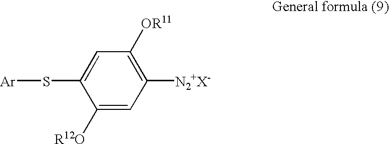

in which Ar represents an aryl group; and R¹¹ and R¹² each independently represent a substituted or unsubstituted alkyl group having 1 to 18 carbon atoms, or a substituted or unsubstituted aryl group having 6 to 20 carbon atoms. In the general formula (9), R¹¹ and R¹² may be the same or mutually different, and X⁻ represents an acid anion.

Below are specific examples of the diazonium salts represented by the above-mentioned general formulae (1), (2), (6), (8) and (9). In the invention, however, the diazonium salt is not limited to these examples.

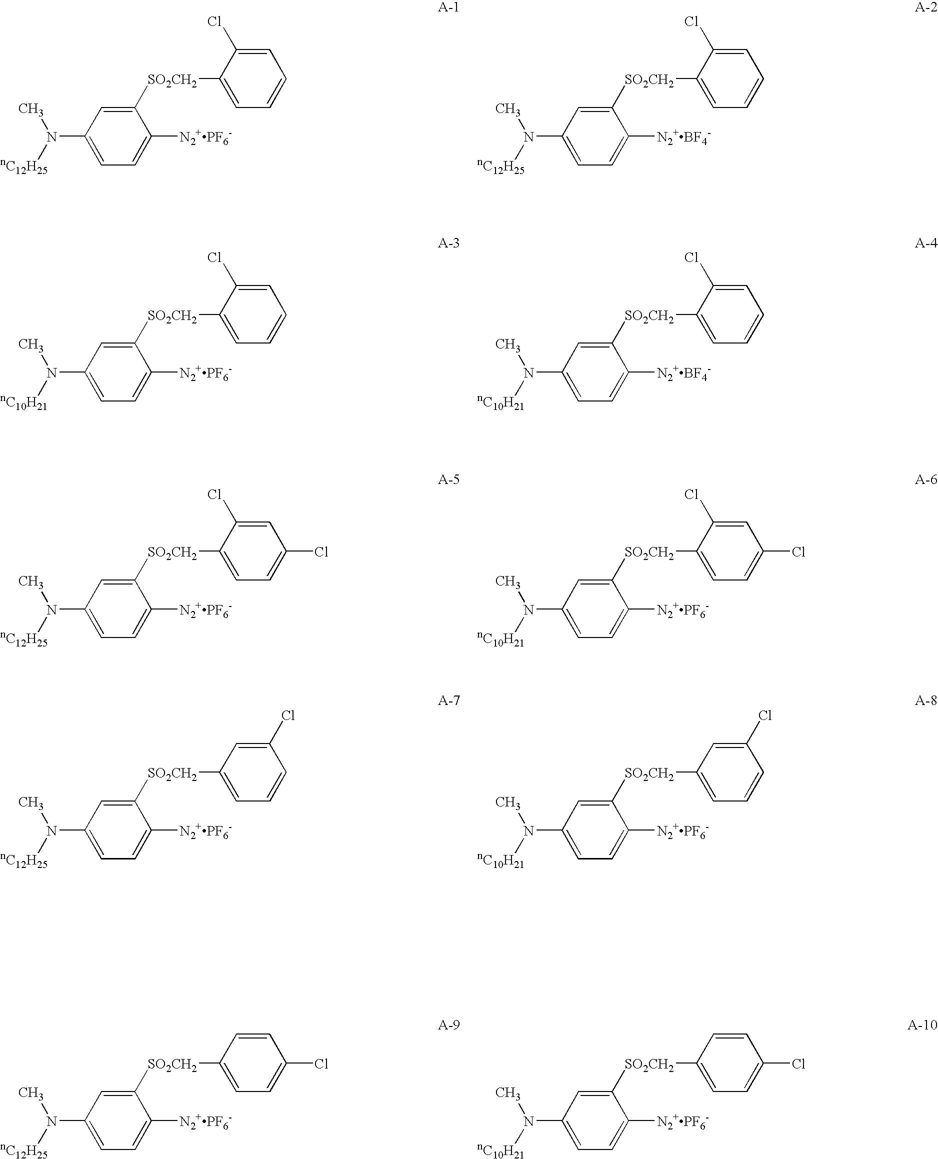

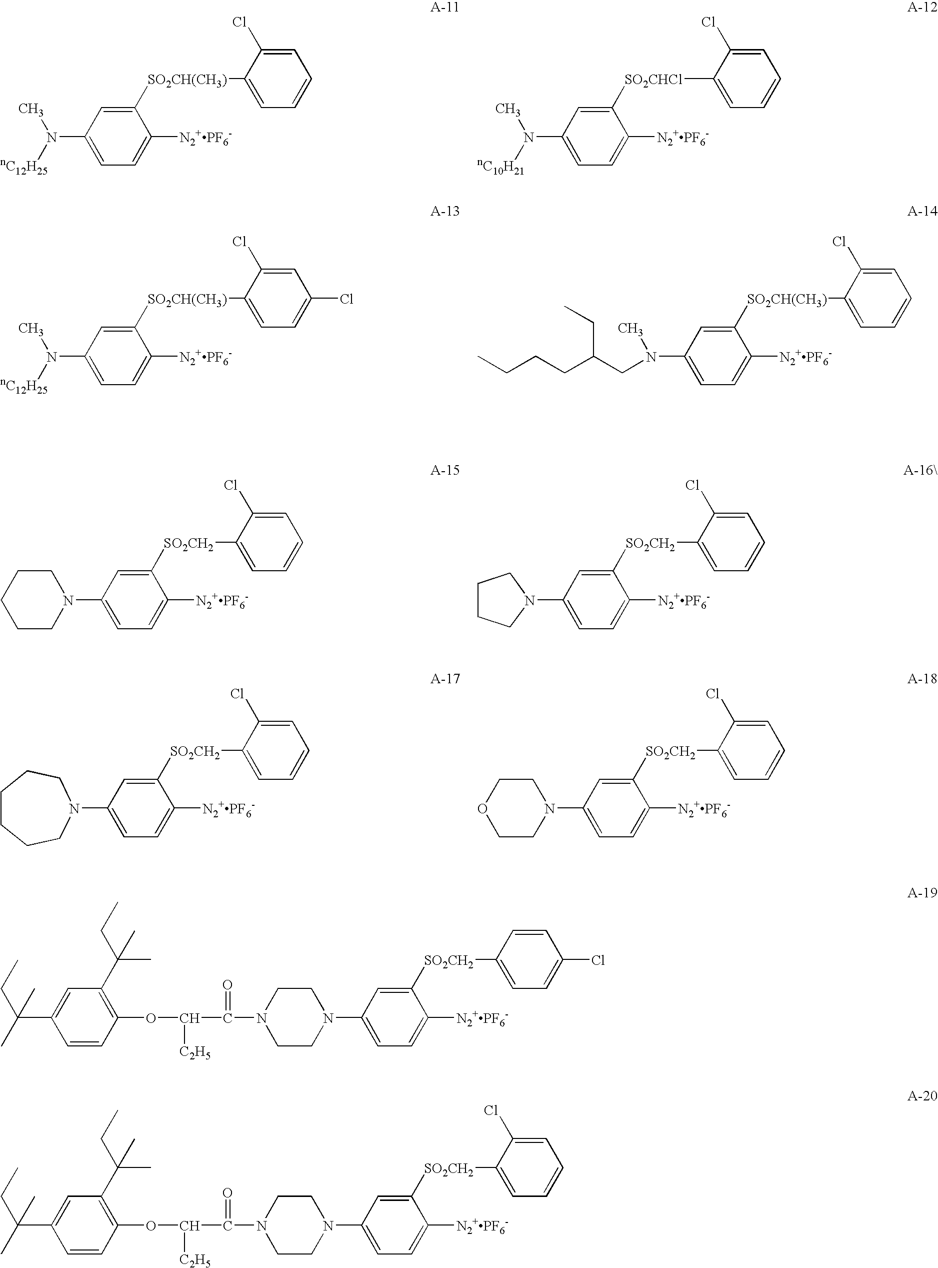

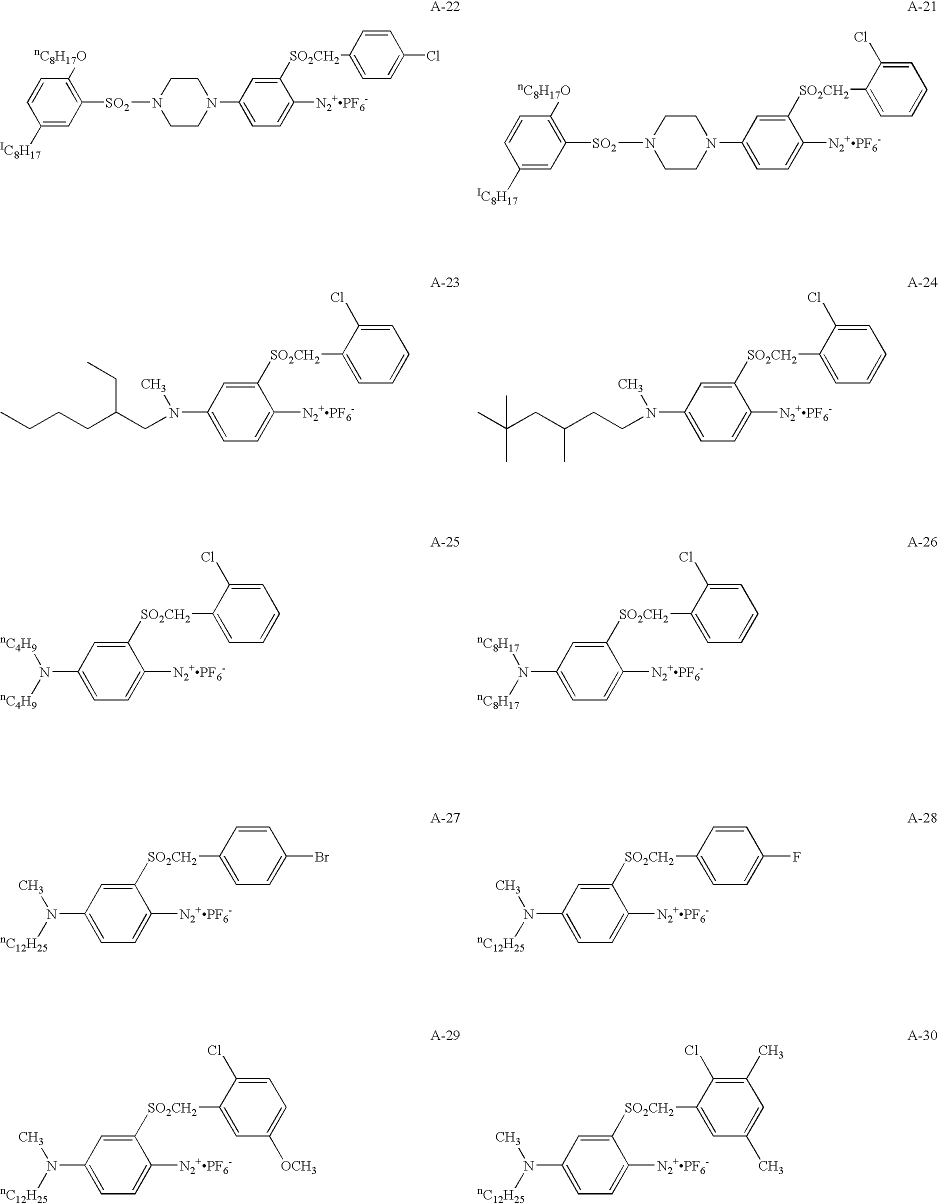

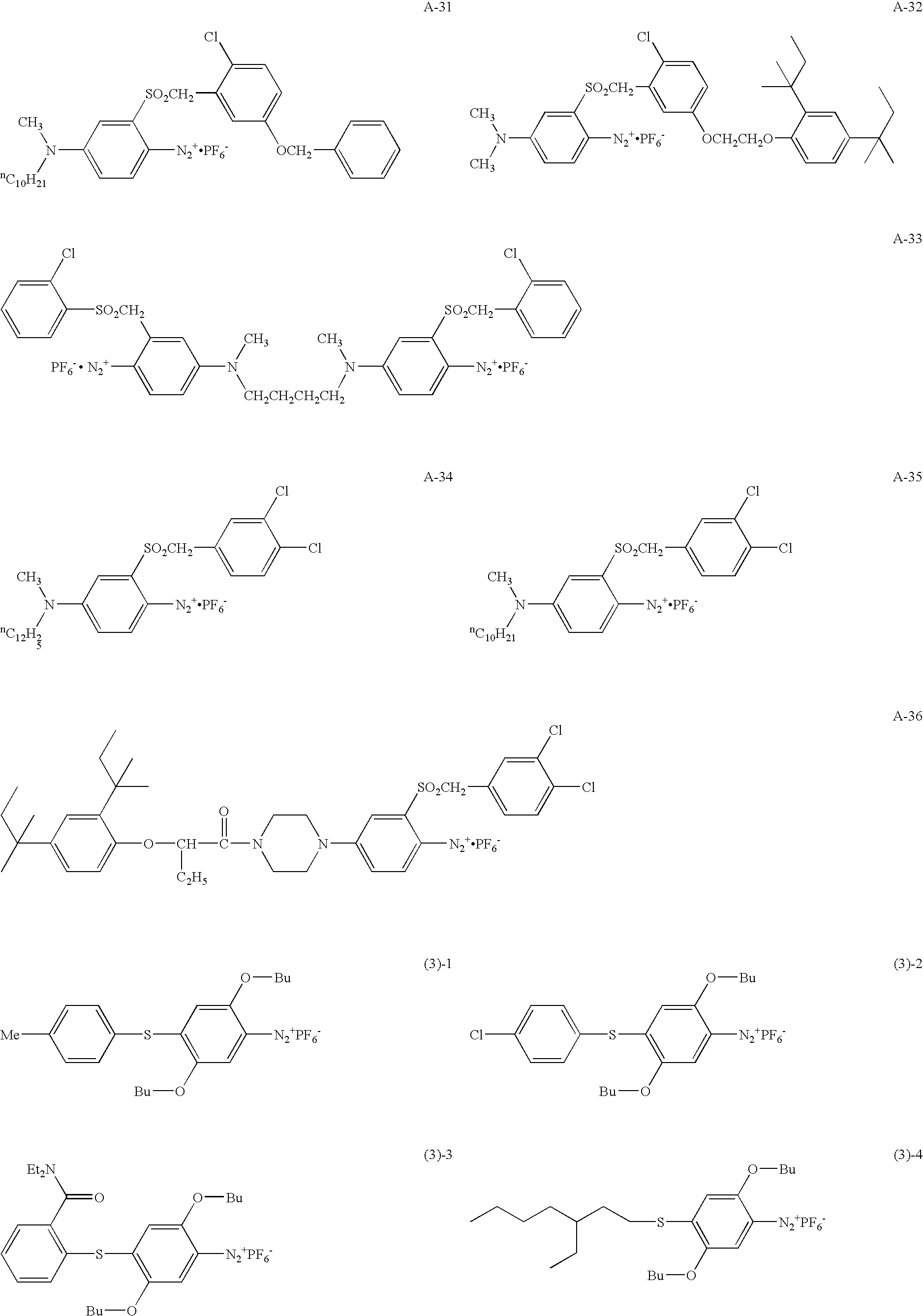

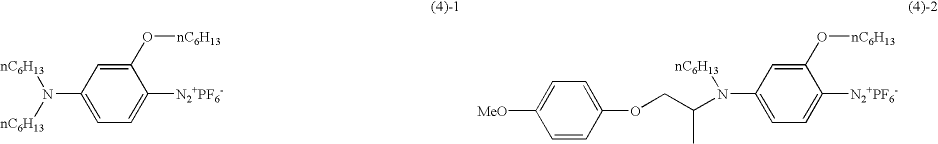

The diazonium salts represented by any one of the general formulae (1), (2) and (6) can be produced by a known method. That is, the salt can be synthesized by subjecting the corresponding aniline to diazotization with sodium nitrite, nitrosylsulfuric acid, isoamyl nitrite or the like in an acidic solvent.

The diazonium salt represented by any one of the diazonium salts represented by the general formulae (1), (2) and (6) may be in an oily or crystalline form, and is preferably in a crystalline form at room temperature in view of handling characteristics.

These diazonium salts may be used alone, or in combination of two or more. The diazonium salt may be used together with an existing diazonium salt.

When using the above-mentioned diazonium salt in the photosensitive, heat-sensitive recording layers of the photosensitive, heat-sensitive recording material, the content thereof is preferably 0.02 to 5 g/m², and more preferably 0.1 to 4 g/m² in view of color-developing density.

In order to stabilize the diazonium salt of the invention, zinc chloride, cadmium chloride, tin chloride or the like may be used to form a complex compound.

The diazonium salt represented by any one of the general formulae (1), (2) and (6) develops color by reacting with a coupler be described later, thereby producing a high developed color density, and has superior photolysis characteristics within the wavelength range of 380 to 460 nm from, for example, a fluorescent light lamp. The diazonium salt also rapidly decomposes, so that fixation can be sufficiently completed by irradiation with light for a short time. Therefore, the diazonium salt is very useful as a color-developing component in the light-fixing photosensitive, heat-sensitive recording material.

Description will now be given of the coupler (coupling component) used in the magenta heat-sensitive recording layer.

The coupler may be any compound that couples with the diazonium salt in a basic or neutral atmosphere to form a dye. All of the so-called 4-equivalent couplers for silver halide photographic photosensitive materials can be used as the coupler. From these couplers, an appropriate coupler may be selected dependently on a target magenta hue. Examples thereof include the active methylene compounds, which have a methylene group adjacent to a carbonyl group, phenol derivatives, and naphthol derivatives. Specific examples thereof include known couplers, examples of which have been mentioned in the description of the yellow heat-sensitive recording layer, and an appropriate coupler selected from these couplers so as to be consistent with the object of the invention is used.

Of the above-mentioned couplers, a compound represented by the general formula (7) or a tautomer thereof is particularly preferable.

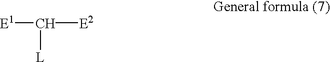

In the general formula (7), E¹ and E² each independently represent an electron-withdrawing group, and may be bonded to each other to form a ring, and L represents a substituent that can leave when the coupler is coupled with the diazo compound.

The electron-withdrawing groups represented by E¹ and E² mean substituents whose Hammett's σₚ values are positive, and may be the same or mutually different. Preferable examples thereof include acyl groups such as acetyl, propionyl, pivaloyl, chloroacetyl, trichloroacetyl, trifluoroacetyl, 1-methylcyclopropylcarbonyl, 1-ethylcyclopropylcarbonyl, 1-benzylcyclopropylcarbonyl, benzoyl, 4-methoxybenzoyl and thenoyl groups; oxycarbonyl groups such as methoxycarbonyl, ethoxycarbonyl, 2-methoxyethoxycarbonyl and 4-methoxyphenoxycarbonyl groups; carbamoyl groups such as carbamoyl, N,N-dimethylcarbamoyl, N,N-diethylcarbamoyl, N-phenylcarbamoyl, N-[2,4-bis(pentyloxy)phenyl]carbamoyl, N-[2,4-bis(octyloxy)phenyl]carbamoyl, and morpholinocarbonyl groups; alkylsulfonyl or arylsulfonyl groups such as methanesulfonyl, benzenesulfonyl and toluenesulfonyl groups; phosphono groups such as diethylphosphono group; heterocyclic groups such as benzooxazole-2-yl, benzothiazole-2-yl, 3,4-dihydroquinazoline-4-one-2-yl, and 3,4-dihydroquinazoline-4-sulfone-2-yl groups; a nitro group; an amino group; and a cyano group.

The electron-withdrawing groups represented by E¹ and E² may be bonded to each other to form a ring. The ring composed of E¹ and E² is preferably a 5-memebered or 6-membered carbon ring or heteroring.

L in the general formula (7) represents a substituent that can leave when the coupler is coupled with the diazo compound. L is preferably a halogen atom, an alkylthio group that may have a substituent, an arylthio group that may have a substituent, an alkyl group that may have a substituent, an alkoxy group that may have a substituent, an aryloxy group that may have a substituent, an arylsulfonyloxy group that may have a substituent, an acyloxy group that may have a substituent, a benzoyloxy group that may have a substituent, a dialkylaminocarbonyloxy group that may have a substituent, a diarylaminocarbonyloxy group that may have a substituent, an alkoxycarbonyloxy group that may have a substituent, an aryloxycarbonyloxy group that may have a substituent, an N-pyrazolyl group that may have a substituent, an N-imidazolyl group that may have a substituent, or an N-benzotriazolyl group that may have a substituent.

Below are specific examples of the coupler represented by the general formula (7). In the invention, however, the coupler is not limited to these examples. Tautomers of the couplers listed up below are also preferable examples.

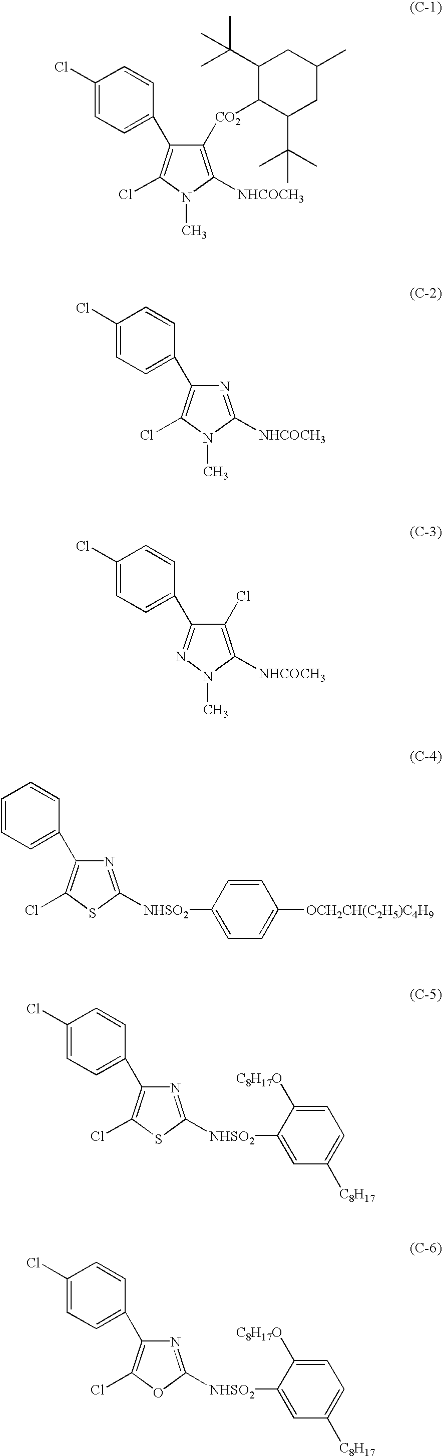

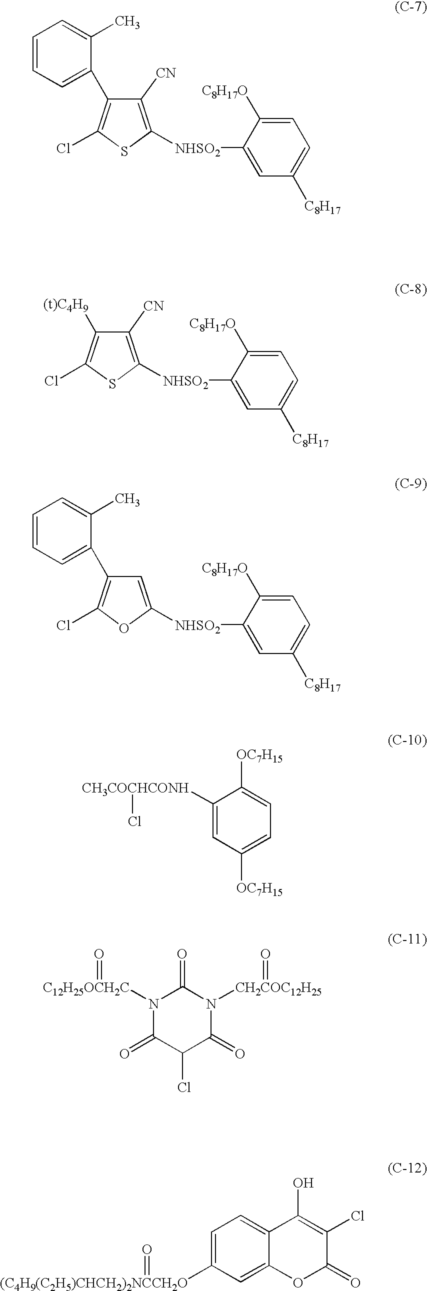

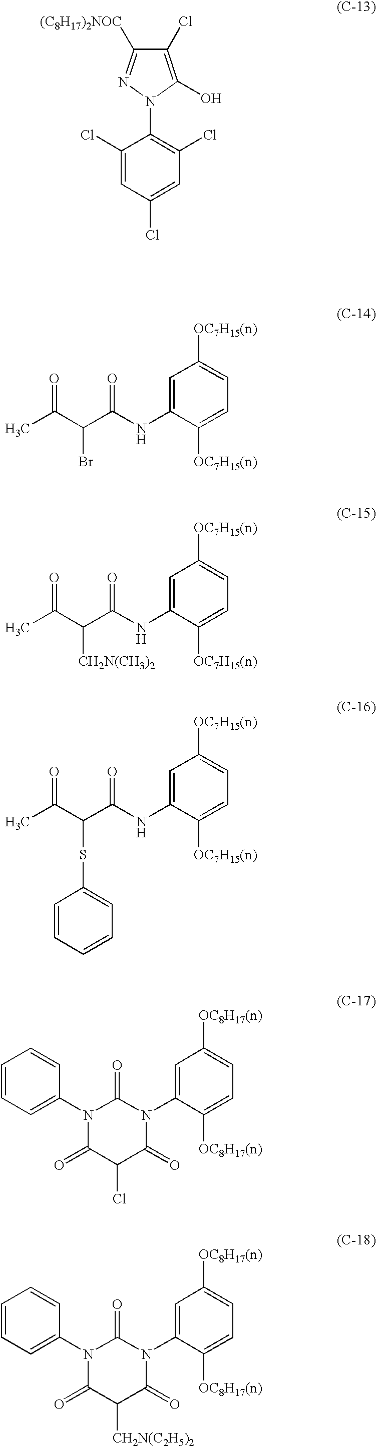

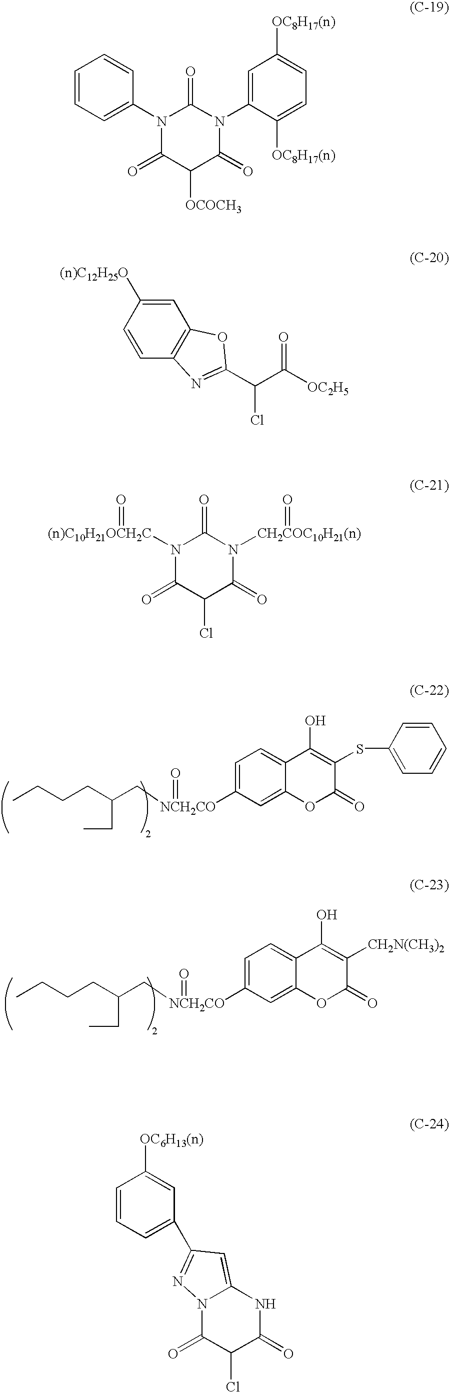

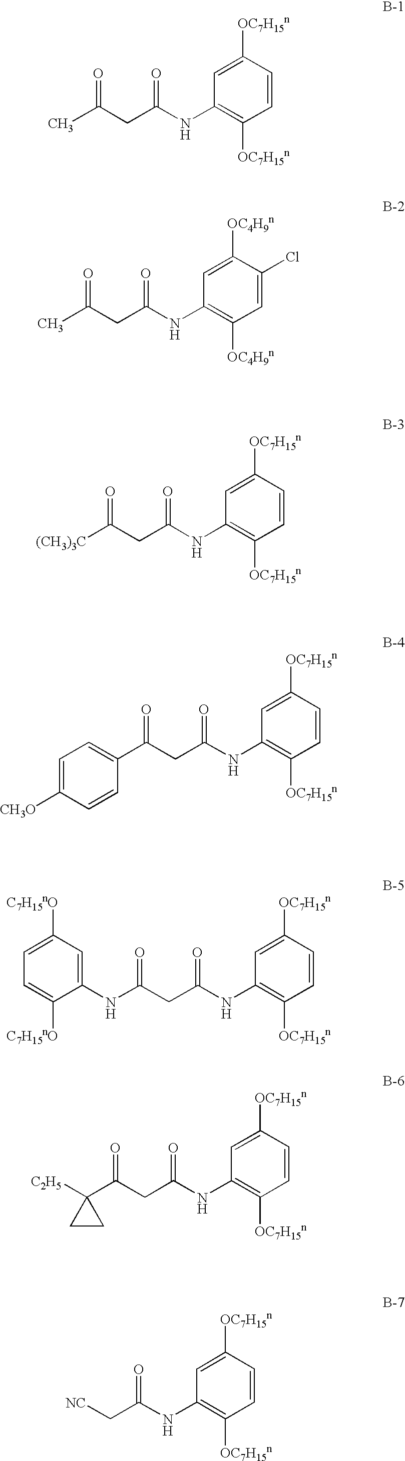

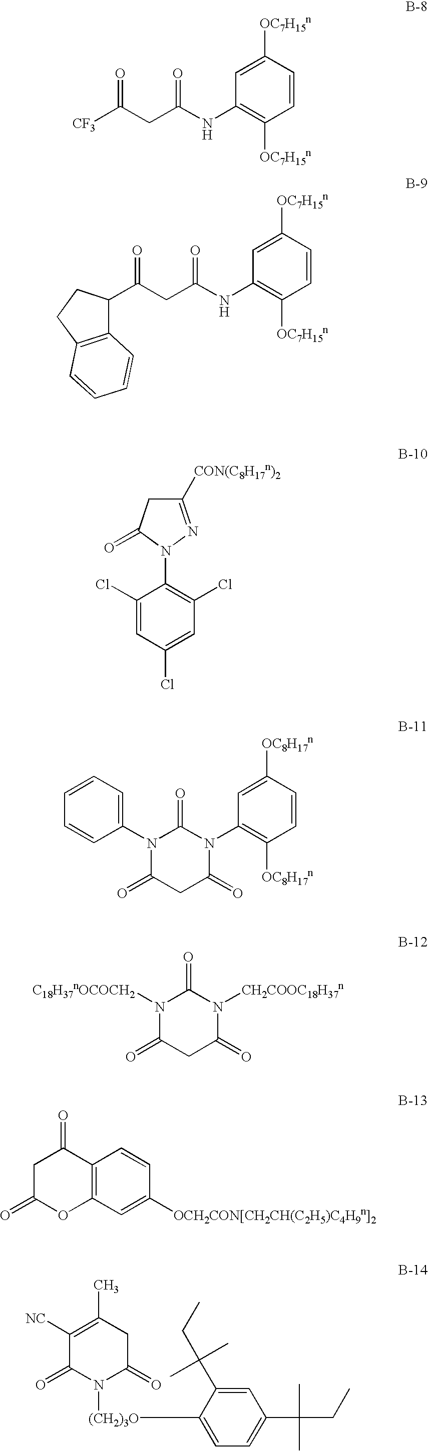

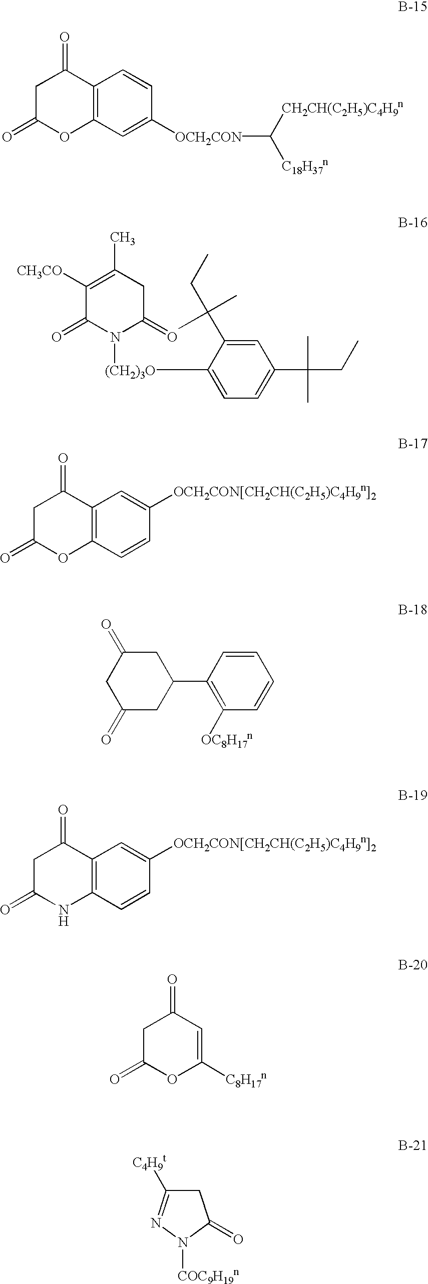

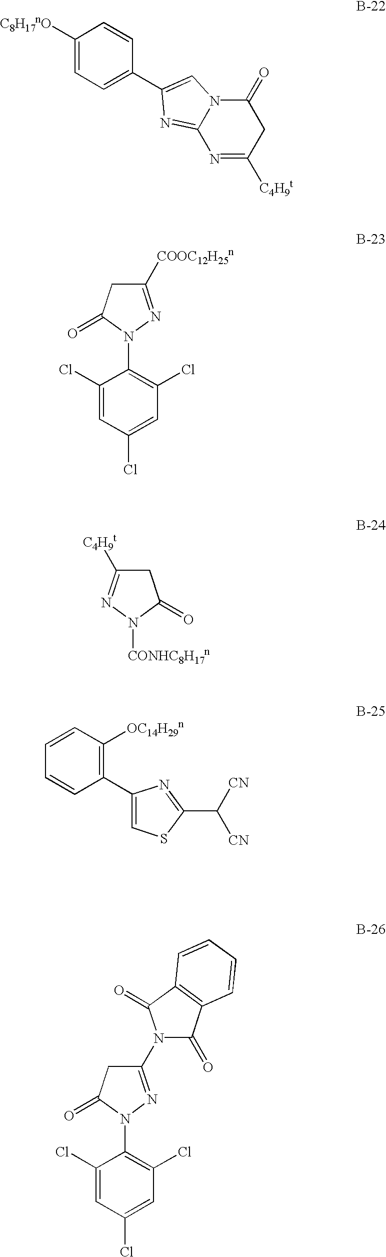

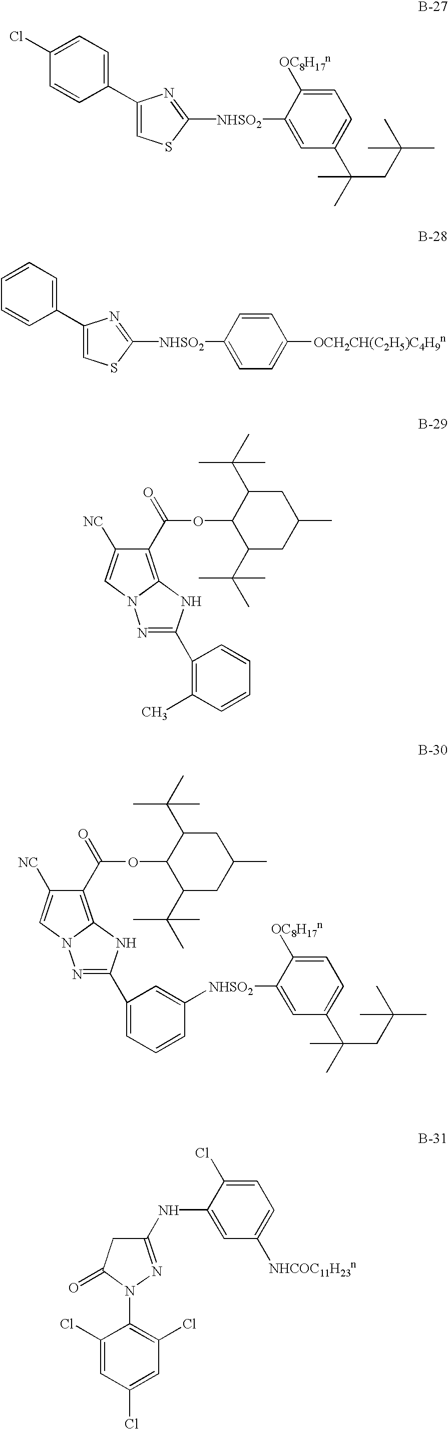

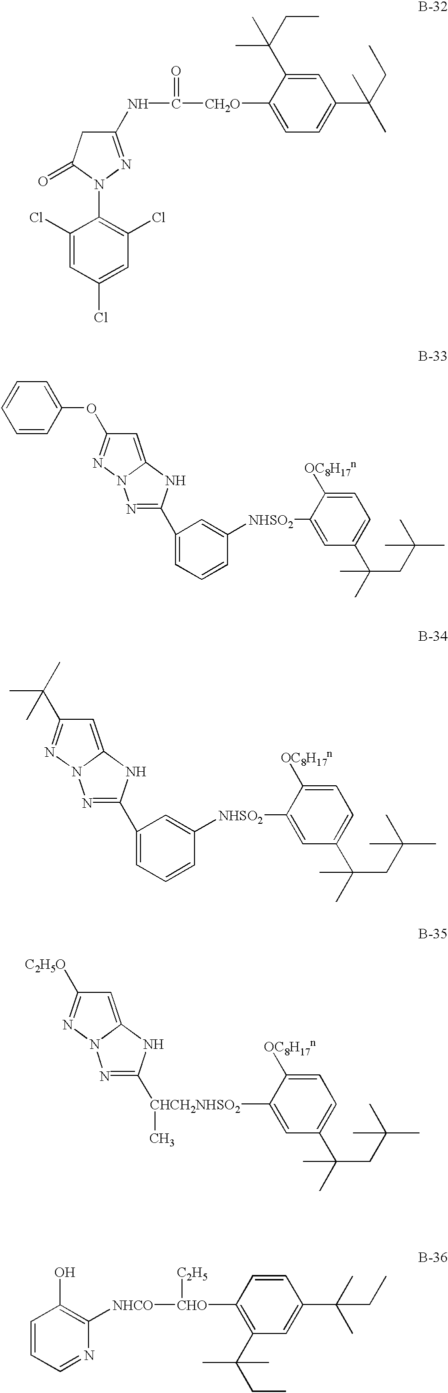

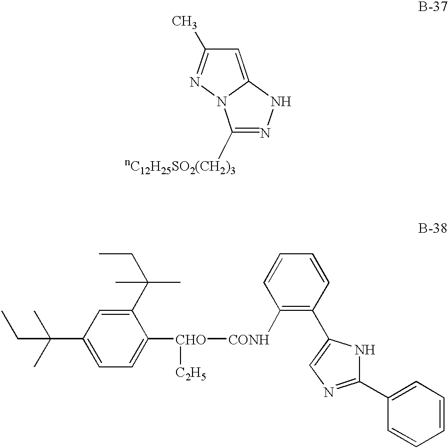

The tautomers of the above-mentioned couplers are isomers of the couplers, and the structure of each of the coupler and the structure of the corresponding tautomer change easily from each other. As the coupler used in the invention, the tautomers are also preferable.

In the magenta heat-sensitive recording layer, the total coupler amount is preferably 0.5 to 10 times by mole as much as the amount of the diazonium salt in the magenta heat-sensitive recording layer, and more preferably 1 to 5 times by mole in view of the effect of the invention.

When the added amount is less than 0.5 times by mole as much as the amount of the diazonium salt, sufficient color-developability may not be obtained. When the amount is more than 10 times by mole number, color-developability deteriorates because of low heat efficiency, which is not preferable in view of thickness.

### Basic Material

The basic material is an inorganic or organic basic compound, and may a compound that decomposes being heated so as to emit an alkali material. Typical examples thereof include nitrogen-containing compounds such as organic ammonium salts, organic amines, amides, urea, thiourea, and derivatives thereof, tiazoles, pyrroles, pyrimidines, piperazines, guanidines, indoles, imidazoles, imidazolines, triazoles, morpholines, piperidines, amidines, formazines, and pyridines. Specific examples thereof include tricyclohexylamine, tribenzylamine, octadecylbenzylamine, stearylamine, allylurea, thiourea, methylthiourea, allylthiourea, ethylenethiourea, 2-benzylimidazole, 4-phenylimidazole, 2-phenyl-4-methylimidazole, 2-undecylimidazoline, 2,4,5-trifuryl-2-imidazoline, 1,2-diphenyl-4,4-dimethyl-2-imidazoline, 2-phenyl-2-imidazoline, 1,2,3-triphenylguanidine, 1,2-dicyclohexylguanidine, 1,2,3-tricyclohexylguanidine, guanidinetrichloro acetate, N,N′-dibenzylpiperazine, 4,4′-dithiomorpholine, morpholinium trichloroacetate, 2-aminobenzothiazole, and 2-benzoylhydrazinobenzothiazole. Two or more thereof may be used in combination.

### Sensitizer

The sensitizer is preferably a low melting-point organic compound having aromatic groups and polar groups appropriately in the molecule. Examples thereof include benzyl p-benzyloxybenzoate, α-naphtyl benzyl ether, β-naphtyl benzyl ether, phenyl β-naphthoate, phenyl α-hydroxy-β-naphthoate, β-naphthol-(p-chlorobenzyl) ether, 1,4-butanediol phenyl ether, 1,4-butanediol-p-methyl phenyl ether, 1,4-butanediol-p-ethyl phenyl ether, 1,4-butanediol-m-methyl phenyl ether, 1-phenoxy-2-(p-tolyloxy)ethane, 1-phenoxy-2-(p-ethylphenoxy)ethane, 1-phenoxy-2-(p-chlorophenoxy)ethane, and p-benzylbiphenyl.

### Microcapsules

In the invention, there are no particular limitations on the mode in which the diazo compound and/or the diazonium salt, the coupler that reacts with the diazo compound or the like upon being heated to develop a color, the basic material, and the sensitizer are used. These components can be used, for example, by being (1) dispersed in a solid state, (2) emulsified and dispersed, (3) dispersed in polymer, (4) dispersed in latex, or (5) encapsulated in microcapsules. In view of preservability, the components are preferably encapsulated in microcapsules. In particular, it is preferable to encapsulate the diazo compound and diazonium salt in microcapsules.

Any known microcapsulating method can be used. That is, microcapsules can be prepared by dissolving a coloring agent, additives and microcapsule-wall precursor in an organic solvent that is slightly soluble or insoluble in water, adding the solution to an aqueous solution of a water-soluble polymer, emulsifying and dispersing the components with a homogenizer or the like, and raising the temperature of the emulsion to form a polymer material that becomes the microcapsule walls into a wall film on the interface between the oils and water.

Examples of the above-mentioned organic solvent include low boiling point co-solvents such as acetic esters, methylenechloride and cyclohexanone and/or high melting-point oils such as phosphoric esters, phthalic esters, acrylic esters, methacrylic esters, other carboxylic acid esters, fatty acid amides, alkylated biphenyl, alkylated terphenyl, alkylated naphthalene, diarylethane, chlorinated paraffin, alcohols, phenols, ethers, monoolefins, and epoxies. Specific examples thereof include tricresyl phosphate, trioctyl phosphate, octyldiphenyl phosphate, tricyclohexyl phosphate, dibutyl phthalate, dioctyl phthalate, dilaurate phthalate, dicyclohexyl phthalate, butyl olefinate, diethyleneglycol benzoate, dioctyl sebacate, dibutyl sebacate, dioctyl adipiate, trioctyl trimellitate, acetyltriethyl citrate, octyl malate, dibutyl malate, isoamylbiphenyl, chlorinated paraffin, diisopropylnaphthalene, 1,1′-ditolylethane, 2,4-ditertiaryamylphenol, N,N-dibutyl-2-butoxy-5-tertiaryoctylaniline, 2-ethylhexyl hydroxybenzoate, and polyethylene glycol. Of these, alcohols, phosphates, carboxylates, alkylated biphenyl, alkylated terphenyl, alkylated naphthalene, and diarylethane are particularly preferable. Moreover, a carbonization inhibitor, such as hindered phenol or hindered amine, may be added to the high boiling-point oil. The oil is desirably oil having an unsaturated fatty acid, and may be a-methylstyrene dimer or the like. An example of the α-methylstyrene dimer is “MSD100” (trade name) made by Mitsui Toatsu Chemicals Inc.

As the water-soluble polymer, polyvinyl alcohol or the like is used. An emulsion of a hydrophobic polymer, latex, or the like may be used together. Examples of the water-soluble polymer include polyvinyl alcohol, silanol-modified polyvinyl alcohol, carboxy-modified polyvinyl alcohol, amino-modified polyvinyl alcohol, itaconic acid-modified polyvinyl alcohol, styrene-maleic anhydride copolymer, butadiene-maleic anhydride copolymer, ethylene-maleic anhydride copolymer, isobutylene-maleic anhydride copolymer, polyacrylic amide, polystyrenesulfonic acid, polyvinylpyrrolidone, ethylene-acrylic acid copolymer, and gelatin. Of these, carboxy-modified polyvinyl alcohol or gelatin is preferable. Examples of the emulsion of the hydrophobic polymer or latex include styrene-butadiene copolymer, carboxy-modified styrene-butadiene copolymer, and acrylonitrile-butadiene copolymer. A known surfactant or the like may be added if necessary.

Specific examples of the polymer material that becomes the wall film of the microcapsules include polyurethane, polyurea, polyamide, polyester, polycarbonate, aminoaldehyde, melamine, polystyrene, styrene-acrylate copolymer, and styrene-methacrylate copolymer resins; gelatin; and polyvinyl alcohol, or the like. Polyurethane/polyurea resin is particularly preferable.

Microcapsules having a wall film made of polyurethane/polyurea resin are produced by incorporating a microcapsule wall precursor such as polyvalent isocyanate into a core material to be encapsulated, emulsifying and dispersing the same into an aqueous solution of a water-soluble polymer such as polyvinyl alcohol or gelatin, and raising the temperature of the emulsion to cause polymerization on the interface of oil droplets.

Specific examples of the polyvalent isocyanate compound include diisocyanates such as m-phenylenediisocyanate, p-phenylenediisocyanate, 2,6-tolylenediisocyanate, 2,4-tolylenediisocyanate, naphthalene-1,4-diisocyanate, diphenylmethane-4,4′-diisocyanate, 3,3′-diphenylmethane-4,4′-diisocyanate, xylene-1,4-diisocyanate, 4,4′-diphenylpropanediisocyanate, trimetylenedisocyanate, hexamethylenedisocyanate, propylene-1,2-disocyanate, butylene-1,2-disocyanate, cyclohexylene-1,2-disocyanate, cyclohexylene-1,4-disocyanate; triisocyaantes such as 4,4′,4″-triphenylmethanetriisocyanate, and toluene-2,4,6-triisocyanate; tetraisocyanates such as 4,4′-dimethylphenylmethane-2,2′,5,5′-tetraisocyanate; isocyanate prepolymers such as an adduct of hexamethylenediisocyanate and trimethylolpropane, an adduct of 2,4-tolylenediisocyanate and trimethylolpropane, an adduct of xylylenediisocyanate and trimethylolpropane, and an adduct of tolylenediisocyanate and hexanetriol. If necessary, two or more of these isocyanates may be used together. Of these, isocyanates having three or more isocyanate groups in their molecule are particularly preferable.

As the organic solvent for dissolving the coloring agent, the additives and the microcapsule wall precursor in the microcapsulating method, the same oil as described in connection with emulsification and dispersion can be used. The same is true of the water-soluble polymer.

The particle size of the microcapsules is preferably 0.1 to 1.0 μm, and more preferably 0.2 to 0.7 μm.

### Recording Method

The multicolor heat-sensitive recording material of the invention comprises three heat-sensitive recording layers, wherein at least three diazonium salts having mutually different photosensitive wavelengths are combined with couplers that respectively react with the diazonium salt compounds, upon being heated to develop different colors.

The heat-sensitive recording material is formed by, for example, a support having disposed thereon a first heat-sensitive recording layer containing a diazo compound or the like having a maximum absorbency wavelength of 350 nm or less and a coupler reacting with the diazo compound or the like upon being heated to color (yellow heat-sensitive recording layer), a second heat-sensitive recording layer containing a diazo compound or the like having a maximum absorbency wavelength of 370±30 nm and a coupler reacting with the diazo compound or the like upon being heated to color (cyan heat-sensitive recording layer), and a third heat-sensitive recording layer containing a diazo compound or the like having a maximum absorbency wavelength of 430±30 nm and a coupler reacting with the diazo compound or the like upon being heated to color (magenta heat-sensitive recording layer).

The multicolor heat-sensitive recording material is recorded by first heating the third heat-sensitive recording layer (magenta heat-sensitive recording layer) is heated to color by reacting the diazo compound or the like with the coupler contained in this layer. Next, the recording material is irradiated with light having a wavelength of 430±30 nm to decompose the diazo compound or the like that has not reacted in the third heat-sensitive recording layer. Thereafter, heat sufficient for causing the second heat-sensitive recording layer (cyan heat-sensitive recording layer) to color is applied to the recording material, so as to develop the color by reacting the diazo compound or the like with the coupler contained in this layer. At the same time, the third heat-sensitive recording layer is intensely heated. However, the third heat-sensitive recording layer develops no color since the diazo compound or the like has already decomposed to lose color-developability. Furthermore, the recording material is irradiated with light having a wavelength of 370±30 nm to decompose the diazo compound or the like that is contained in the second heat-sensitive recording layer. Finally, heat sufficient for causing the first heat-sensitive recording layer to color is applied to the recording material, so as to develop the color. At the same time, the third and second heat-sensitive recording layers are intensely heated. However, the third and second heat-sensitive recording layers develop no colors since the diazo compound or the like contained in the third and second heat-sensitive recording layers have already decomposed to lose color-developability.

Examples of the light source used in the photolysis (light fixation) of the above-mentioned diazo compound or the like include various fluorescent lamps, xenon lamps and mercury lamps. In order to achieve fixation with a high efficiency, it is preferable that the emission spectrum of the light source is substantially consistent with the absorption spectrum of the diazonium salt in the photosensitive, heat-sensitive recording material.

In the invention, a light source having a central emission wavelength of 340 to 460 nm is particularly preferably used.

The recording material of the invention can be used as a photowritable, heat-developable, heat-sensitive recording material, wherein writing is imagewise achieved by light and then the latent image is heat-developed to form an image. In this case, printing of characters or images is achieved by a light source such as a laser ray or the like instead of a heating device.

### Antioxidant

In order to improve light-resistance, a known antioxidant can be used in the invention. Examples of known antioxidants include those described in EP Nos. 310,551, 310,552, 459,416, 223,739, 309,402, 309,401; DP No. 3,435,443; JP-A Nos. 3-121449, 2-262654, 2-71262, 63-163351, 54-48535, 5-61166, 5-119449, 63-113536, 62-262047; and U.S. Pat. Nos. 4,814,262, and 4,980,275. Specific examples thereof are as follows.

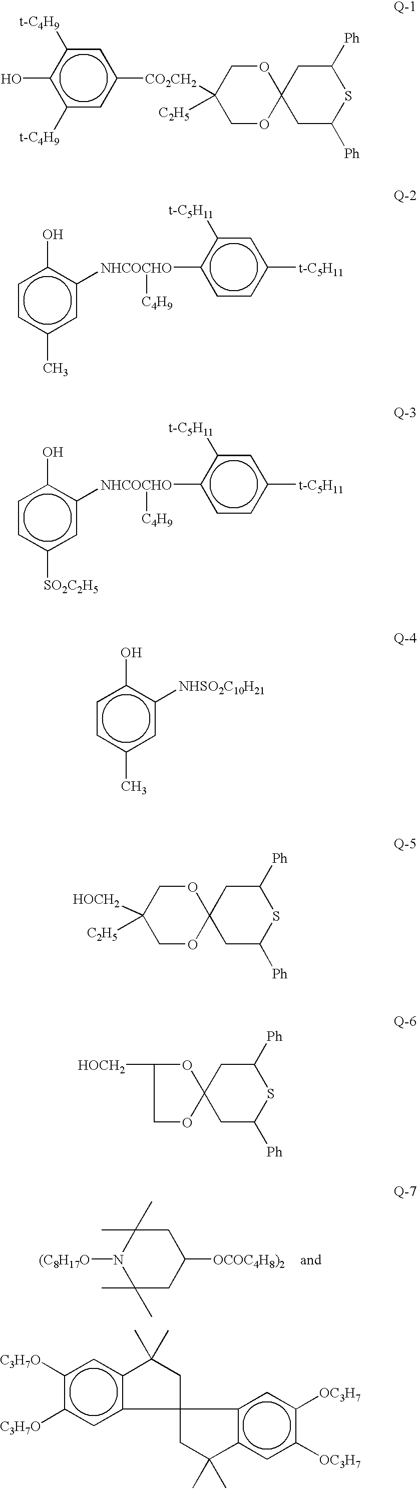

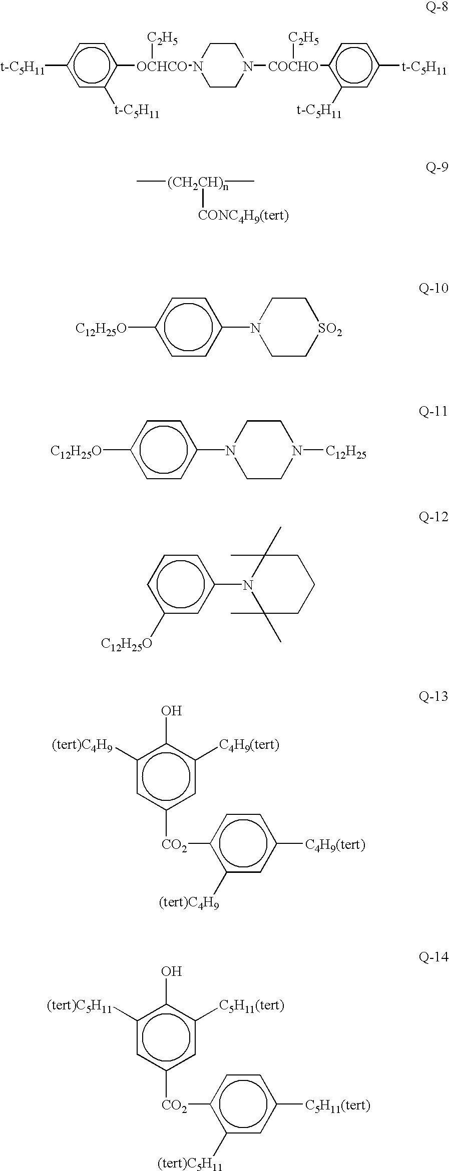

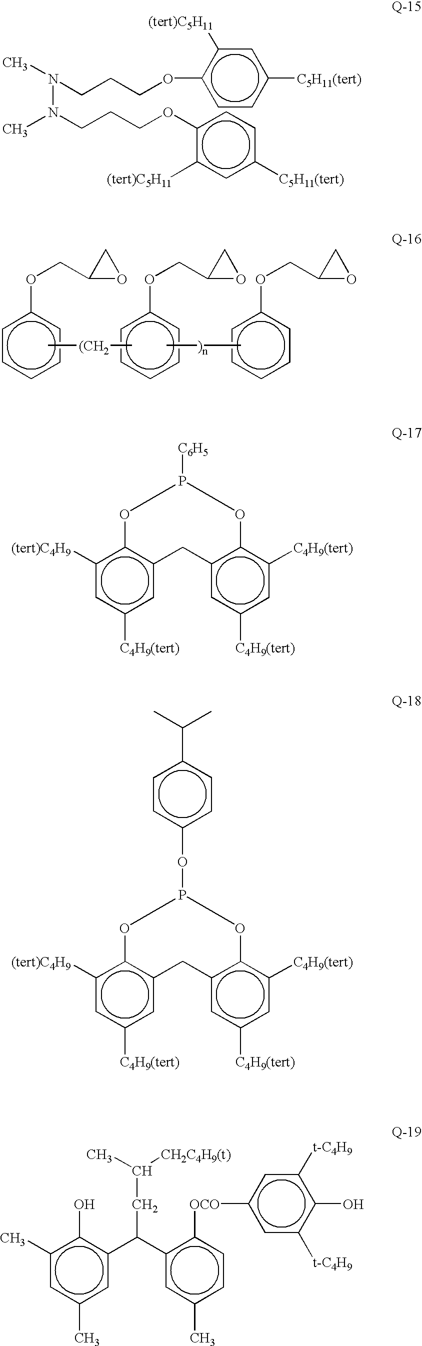

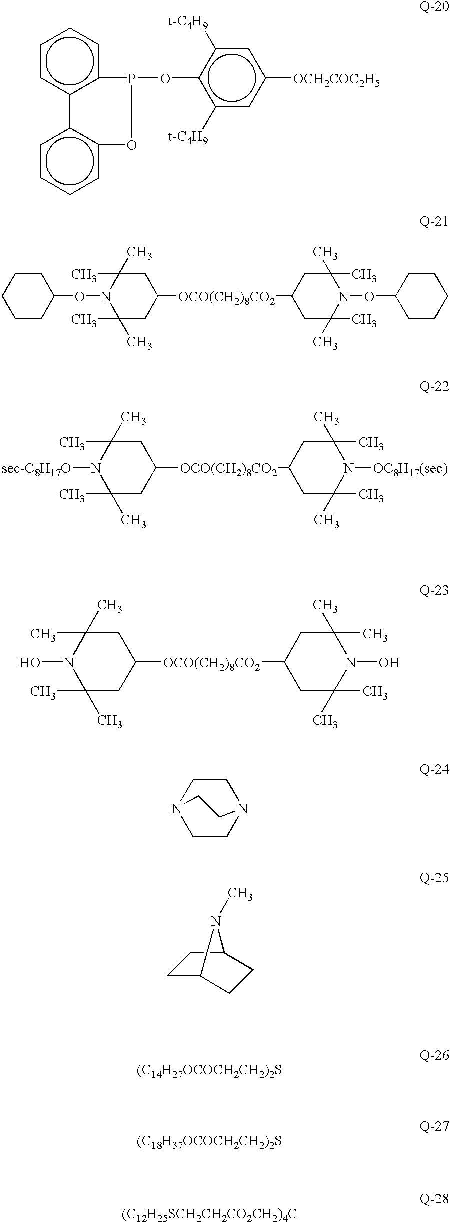

Furthermore, it is effective to use various additives known for heat-sensitive recording materials and pressure-sensitive recording materials. Examples of antioxidant among these additives include compounds described in JP-A Nos. 60-125470, 60-125471, 60-125472, 60-287485, 60-287486, 60-287487, 62-146680, 60-287488, 62-282885, 63-89877, 63-88380, 63-088381, 01-239282, 04-291685, 04-291684, 05-188687, 05-188686, 05-110490, 05-1108437, 05-170361, 63-203372, 63-224989, 63-267594, 63-182484, 60-107384, 60-107383, 61-160287, 61-185483, 61-211079, 63-251282, 63-051174, Japanese Patent Application Publication (JP-B) Nos. 48-043294, and 48-033212.

Specific examples thereof include 6-ethoxy-1-phenyl-2,2,4-trimethyl-1,2-dihydroquinoline, 6-ethoxy-1-octyl-2,2,4-trimethyl-1,2-dihydroquinoline, 6-ethoxy-1-phenyl-2,2,4-trimethyl-1,2,3,4-tetrahydroquinoline, 6-ethoxy-1-octyl-2,2,4-trimethyl-1,2,3,4-tetrahydroquinoline, nickel cyclohexanoate, 2,2-bis-4-hydroxyphenylpropane, 1,1-bis-4-hydroxyphenyl-2-ethylhexane, 2-methyl-4-methoxy-2-diphenylamine, 1-methyl-2-phenylindole and the following compounds.

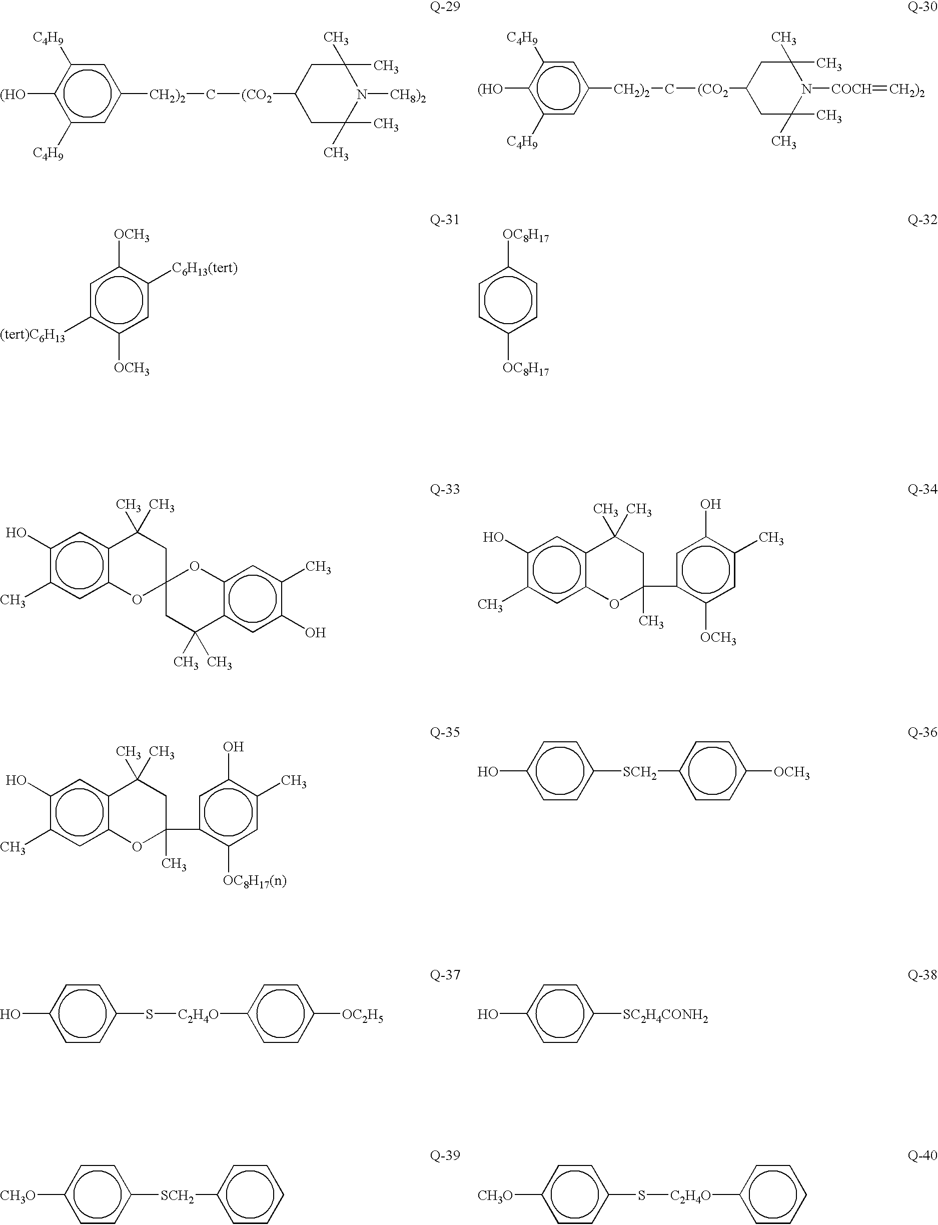

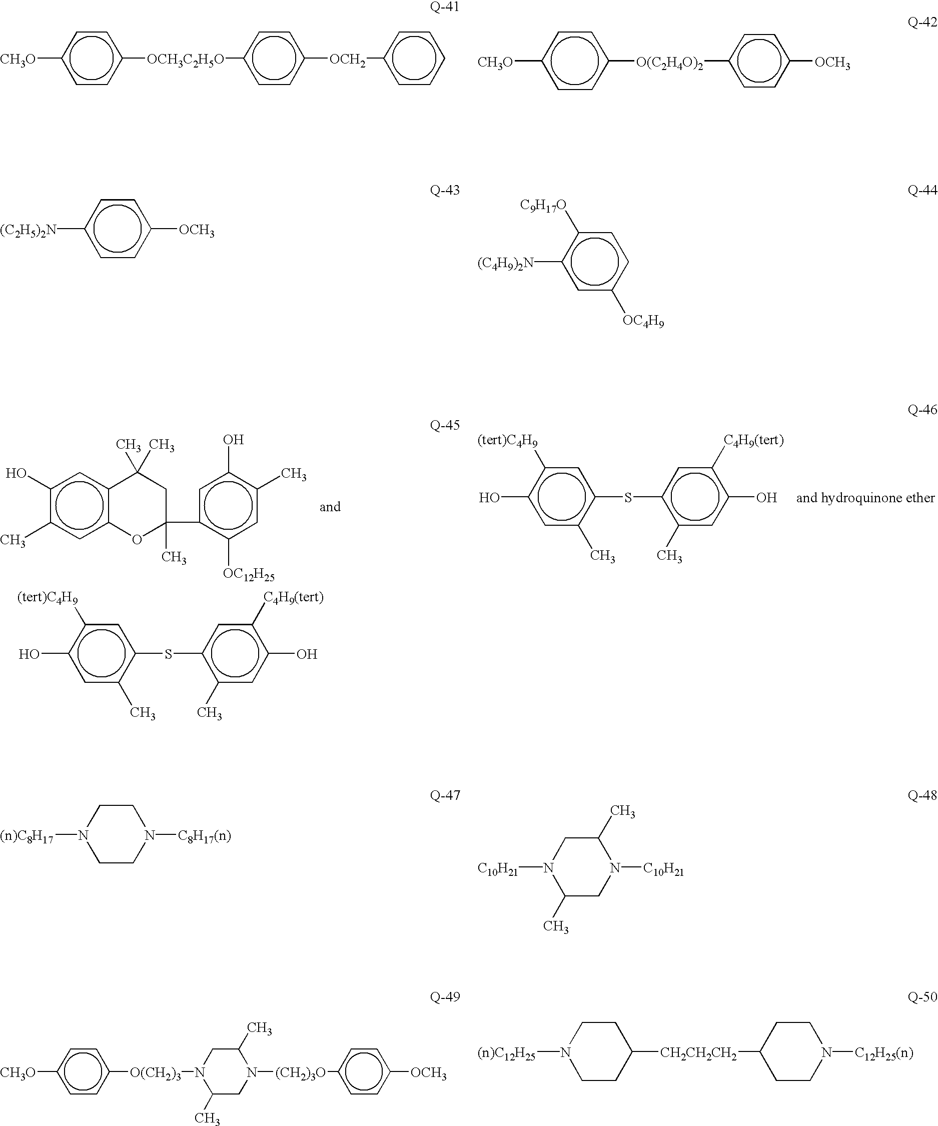

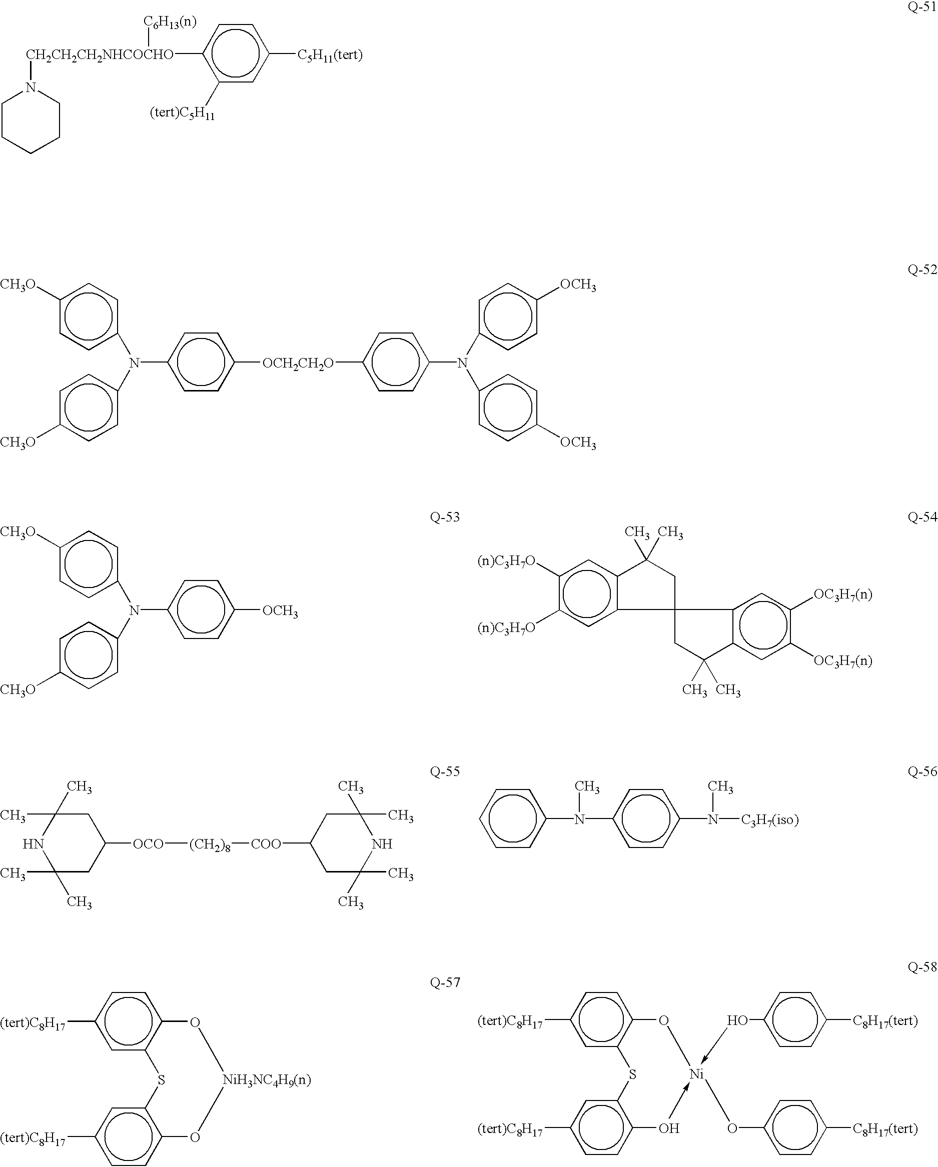

These antioxidants may be added to the heat-sensitive recording layer, the intermediate layer, the light-transmittance adjusting layer, or the protective layer. When these antioxidants are used in combination, combinations of the compounds (Q-7), (Q-45) and (Q-46), or a combination of the compounds (Q-10) and (Q-13) may be used.

### EXAMPLES

The invention will be specifically described by way of examples hereinafter. However, the invention is not limited to these examples.

### Example 1

### Support with an Undercoat Layer

Forty parts by mass of enzymolized gelatin (average molecular weight: 10,000, PAGI-method viscosity: 1.5 mPas (15 mP), and PAGI-method jelly strength: 20 g) was added to 60 parts by mass of ion-exchanged water, and the solution was stirred at 40° C. to dissolve the gelatin. In this way, an aqueous solution of gelatin for an undercoat layer was prepared.

8 parts by mass of water-swelling synthetic mica (aspect ratio: 1000; trade name: Somashif ME100, made by Co-op Chemical Co., Ltd.) and 92 parts by mass of water were separately mixed with each other, and then the mica was dispersed in water with a visco mill, to yield a mica-dispersed solution having a volume-average particle size of 2.0 μm. To this mica-dispersed solution was added water so that the concentration of the mica would be 5% by mass. The resultant solution was homogeneously mixed to prepare a mica-dispersed solution.

Next, 120 parts by mass of water and 556 parts by mass of methanol were added to 100 parts by mass of the aqueous solution of 40% by mass gelatin for an undercoat layer, which had a temperature of 40° C., and then the resultant solution was sufficiently stirred and mixed. Thereafter, 208 parts by mass of the 5% by mass mica-dispersed solution was added, and then the resultant solution was sufficiently stirred and mixed. 9.8 parts by mass of a 1.66% by mass polyethylene oxide surfactant was added to the solution. The temperature of the solution was kept at 35 to 40° C., and 7.3 parts by mass of ethylenediglycidyl ether as a gelatin hardener was added to the solution, so as to prepare a coating solution (5.7% by mass) for an undercoat layer.

The coating solution was coated onto one surface of a support, wherein polyethylene films were laminated on both surfaces of fine paper in the manner that the coated amount of the mica would be 0.2 g/m². In this way, an undercoat layer was formed.

### Preparation of Phthalated Gelatin Solution

32 parts by mass of phthalated gelatin (trade name: MGP gelatin, made by Nippi Collagen Co., Ltd.); 0.9143 parts by mass of 1,2-benzothiazoline-3-one (3.5% solution in methanol, made by Daito Chemical Industries, Ltd.), and 367.1 parts by mass of ion-exchanged water were mixed. The mixture was dissolved in the water at 40° C. to yield an aqueous solution of phthalated gelatin.

### Preparation of Gelatin Solution for Producing an Emulsion

25.5 parts by mass of alkali-treated, low-ion gelatin (trade name: #750 gelatin, made by Nitta Gelatin Co., Ltd.); 0.7286 parts by mass of 1,2-benzothiazoline-3-one (3.5% solution in methanol, made by Daito Chemical Industries, Ltd.), 0.153 parts by mass of calcium hydroxide, and 143.6 parts by mass of ion-exchanged water were mixed. The mixture was dissolved in the water at 50° C. to yield an aqueous solution of gelatin for producing an emulsion.

### Preparation of Diazonium Salt Compound-Encapsulated Microcapsule Solutions

### Preparation of Diazonium Salt-Encapsulated Microcapsule Solution (a)

To 15.0 parts by mass of ethyl acetate were added 3.2 parts by mass of the following diazonium salt (A) (maximum absorbency wavelength: 420 nm) and 10.7 parts by mass of diphenyl phthalate, and then the mixture was heated to produce a homogeneous solution. To this mixed solution was added 9.7 parts by mass of a mixture of xylylenediisocyanate/ trimethylolpropane adduct and xylylenedisocyanate/bisphenol A adduct (trade name: Takenate D1 19N (50% by mass solution in ethyl acetate, made by Takeda Chemical Industries, Ltd.)) as a capsule-wall material. The solution was homogeneously stirred to yield a mixed solution (I).

18.1 parts by mass of ion-exchanged water and 0.38 part by mass of Scraph AG-8 (50% by mass, made by Nippon Fine Chemical Co., Ltd.) were separately added to 65 parts by mass of the 8% by mass phthalated gelatin solution, and the mixed solution (I) of the diazonium salt (A) obtained in the above-mentioned step was added thereto. A homogenizer (made by Nippon Seiki Seisakusho Co., Ltd.) was used to emulsify and disperse the salt at 40° C. To the resultant emulsion was added 10 parts by mass of water to make the emulsion homogeneous. Thereafter, the emulsion was subjected to a microcapsule reaction for 3 hours while the emulsion was stirred at 40° C. Thereafter, to the emulsion were added 4.6 parts by mass of ion exchange resin Amberlite IRA68 (made by Organo Corporation) and 9.2 parts by mass of Amberlite IRC50 (made by Organo Corporation), and the mixture was stirred for 1 hour. Thereafter, the ion exchange resin was removed by filtration, and 0.7 part by mass of an aqueous solution of 5% hydroquinone was added thereto. The solution was stirred and the solid content concentration in the capsule solution was adjusted into 24.5% to yield a diazonium salt capsulated microcapsule solution (a).

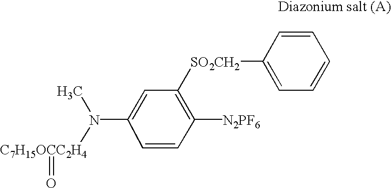

### Preparation of Diazonium Salt-Encapsulated Microcapsule Solution (b)

To 15.1 parts by mass of ethyl acetate were added 3.4 parts by mass of the following diazonium salt (B) (maximum absorbency wavelength: 365 nm), 5.7 parts by mass of tricresyl phosphate, 5.7 parts by mass of isopropylbiphenyl, 0.2 parts by mass of 2,2-dimethoxy-1,2-diphenylethane-1-one (trade name: Irgacure 651; made by Chiba Speciality Chemicals Co., Ltd.), and 0.5 parts by mass of diphenyl-(2,4,6-trimethylbenzoyl)phosphine oxide (trade name: Luciline TPO; made by BASF Japan Ltd.). The mixture was heated to yield a homogeneous mixed solution. To this mixed solution were added 14.1 parts by mass of a mixture of xylylenediisocyanate/trimethylolpropane adduct and xylylenedisocyanate/bisphenol A adduct (trade name: Takenate D119N (50% by mass solution in ethyl acetate, made by Takeda Chemical Industries, Ltd.) and 0.4 parts by mass of polymethylenepolyphenylpolyisocyanate (trade name: Milionate MR-200; made by Nippon Polyurethane Industry Co., Ltd.) as capsule-wall materials. The solution was homogeneously stirred to yield a mixed solution (II).

25.2 parts by mass of ion-exchanged water and 0.4 parts by mass of Scraph AG-8 (50% by mass, made by Nippon Fine Chemical Co., Ltd.) were separately added to 66.1 parts by mass of the 8% by mass phthalated gelatin solution, and the mixed solution (II) of the diazonium salt (B) obtained in the above-mentioned step was added thereto. A homogenizer (made by Nippon Seiki Seisakusho Co., Ltd.) was used to emulsify and disperse the salt at 40° C. To the resultant emulsion was added 10 parts by mass of water to make the emulsion homogeneous. Thereafter, the emulsion was subjected to a microcapsule reaction for 0.5 hours while the emulsion was stirred at 40° C. Thereafter, the temperature was raised to 50° C., and a microcapsule reaction was conducted for 2.5 hours. To the emulsion were then added 15 parts by mass of ion exchange resin Amberlite IRA 68 (made by Organo Corporation) and 30 parts by mass of Amberlite IRC 50 (made by Organo Corporation), and the mixture was stirred for 1 hour. Thereafter, the ion exchange resin was removed by filtration, and then the solid content concentration in the capsule solution was adjusted into 23% to yield a diazonium salt encapsulated microcapsule solution (b).

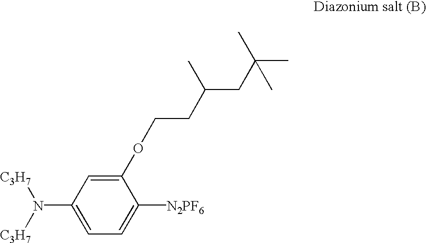

### Preparation of Diazonium Compound-Encapsulated Microcapsule Solution (c)

To 15.1 parts by mass of ethyl acetate were added 4.6 parts by mass of the following diazo compound (C) (maximum absorbency wavelength: 350 nm or less) and 10.4 parts by mass of diphenyl phthalate. The mixture was heated to yield a homogeneous solution. To the mixture were added 6.1 parts by mass of xylylenediisocyanate/trimethylolpropane adduct (trade name: Takenate D110N (75% by mass solution in ethyl acetate, made by Takeda Chemical Industries, Ltd.) and 2.4 parts by mass of polymethylenepolyphenylpolyisocyanate (trade name: Milionate MR-200; made by Nippon Polyurethane Industry Co., Ltd.) as capsule-wall materials. The solution was homogeneously stirred to yield a mixed solution (III).

13.8 parts by mass of ion-exchanged water and 0.41 part by mass of Scraph AG-8 (50% by mass, made by Nippon Fine Chemical Co., Ltd.) were separately added to 62.7 parts by mass of the 8% by mass phthalated gelatin solution, and the mixed solution (III) of the diazonium compound (C) obtained in the above-mentioned step was added thereto. A homogenizer (made by Nippon Seiki Seisakusho Co., Ltd.) was used to emulsify and disperse the compound at 40° C. To the resultant emulsion were added 70 parts by mass of water to make the emulsion homogeneous. Thereafter, the emulsion was subjected to a microcapsule reaction for 1 hour while the emulsion was stirred at 40° C. Thereafter, the temperature was raised to 60° C., and a microcapsule reaction was conducted for 2.0 hours. Thereafter, the temperature of the emulsion solution was lowered to 40° C., and then to the emulsion were added 7.5 parts by mass of ion exchange resin Amberlite IRA 68 (made by Organo Corporation) and 15 parts by mass of Amberlite IRC 50 (made by Organo Corporation), and further the mixture was stirred for 1 hour. Thereafter, the ion exchange resin was removed by filtration, and then the solid content concentration in the capsule solution was adjusted into 20% to yield a diazonium compound encapsulated microcapsule solution (c).

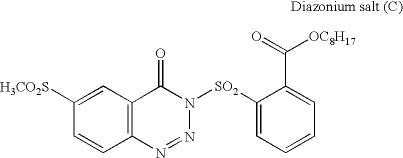

### Preparation of Coupler-Dispersed Emulsions

### Preparation of Coupler-Dispersed Emulsions (d)

Into 31.9 parts by mass of ethyl acetate were dissolved 5.2 parts by mass of the following coupler (D), 3.3 parts by mass of triphenylguanidine (made by Hodogaya Chemical Co., Ltd.), 20 parts by mass of 4,4′-(m-phenylenediisopropylidene)diphenol (trade name: Bisphenol M (Mitsui Petrochemical Industries, Co., Ltd.), 13.3 parts by mass of 4-(2-ethyl-1-hexyloxy)benzenesulfonic amide (made by Manac Co., Ltd.), 6.8 parts by mass of 4-n-pentyloxybenzenesulfonic amide (made by Manac Co., Ltd.), 1.6 parts by mass of 3,3,3′,3′-tetramethyl-5,5′,6,6′-tetra(1-propyloxy)-1,1′-spirobisindane (made by Sankyo Chemical Industries, Co., Ltd.), 6.8 parts by mass of tricresyl phospahte, and 4.2 parts by mass of calcium dodecylbenzenesulfonate (trade name: Pionin A-41-C, 70% solution in methanol; made by Takemoto Oil & Fat Co., Ltd.). In this way, a mixed solution (IV) was yielded.

137.5 parts by mass of ion-exchanged water was separately mixed with 158.1 parts by mass of the aqueous solution of gelatin for producing an emulsion, and further thereto was added the coupler mixed solution (IV) yielded in the above-mentioned step. A homogenizer (made by Nippon Seiki Seiakusho Co., Ltd.) was used to emulsify and disperse the coupler. The resultant coupler-dispersed emulsion was heated under reduced pressure to remove ethyl acetate. Thereafter, the solid content concentration in the capsule solution was adjusted to 20% to yield a coupler-dispersed emulsion (d).

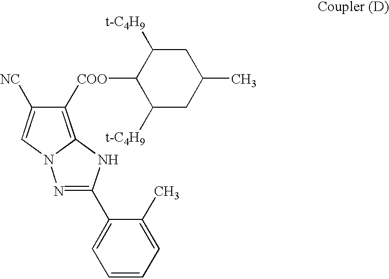

### Preparation of Coupler-Dispersed Emulsions (e)

Into 37.3 parts by mass of ethyl acetate were dissolved 4.47 parts by mass of the following coupler (E), 1.87 parts by mass of triphenylguanidine (made by Hodogaya Chemical Co., Ltd.), 4.39 parts by mass of 4,4′-(m-phenylenediisopropylidene)diphenol (trade name: Bisphenol M (Mitsui Petrochemical Industries, Ltd.), 1.4 parts by mass of α-tocopherol, 5.84 parts by mass of tricresyl phospahte, and 1.63 parts by mass of calcium dodecylbenzenesulfonate (trade name: Pionin A-41-C, 70% solution in methanol; made by Takemoto Oil & Fat Co., Ltd.). In this way, a mixed solution (V) was yielded.

45.5 parts by mass of ion-exchanged water was separately mixed with 49.3 parts by mass of the aqueous solution of gelatin for producing an emulsion, and further thereto was added the coupler mixed solution (V) yielded in the above-mentioned step. A homogenizer (made by Nippon Seiki Seisakusho Co., Ltd.) was used to emulsify and disperse the coupler. The resultant coupler compound-dispersed emulsion was heated under reduced pressure to remove ethyl acetate. Thereafter, the solid content concentration in the capsule solution was adjusted into 20% by mass to yield a coupler-dispersed emulsion (e).

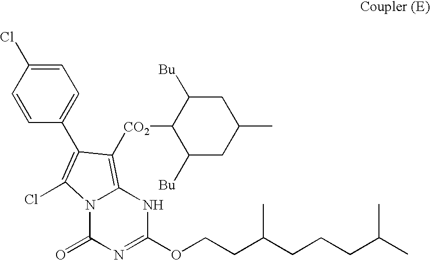

### Preparation of Coupler-Dispersed Emulsions (f)

Into 49 parts by mass of ethyl acetate were dissolved 6.0 parts by mass of the following coupler (F), 1.9 parts by mass of triphenylguanidine (made by Hodogaya Chemical Co., Ltd.), 11.5 parts by mass of tricresylphospahte, and 0.8 parts by mass of calcium dodecylbenzenesulfonate (trade name: Pionin A-41-C, 70% solution in methanol; made by Takemoto Oil & Fat Co., Ltd.). In this way, a mixed solution (VI) was yielded.

104 parts by mass of ion-exchanged water was separately mixed with 77 parts by mass of the aqueous solution of gelatin for producing an emulsion, and further thereto was added the coupler mixed solution (VI) yielded in the above-mentioned step. A homogenizer (made by Nippon Seiki Seisakusho Co., Ltd.) was used to emulsify and disperse the coupler. The resultant coupler-dispersed emulsion was heated under reduced pressure to remove ethyl acetate. Thereafter, the solid content concentration in the capsule solution was adjusted to 17.5% to yield a coupler-dispersed emulsion (f).

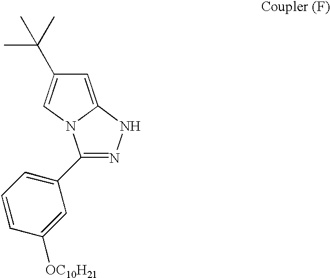

### Preparation of Coating Solutions for Heat-Sensitive Recording Layers

### Preparation of Coating Solution (G) for Magenta Heat-Sensitive Recording Layer

The diazonium salt-encapsulated microcapsule solution (a) and the coupler dispersed emulsion (d) were mixed in such a manner that the molar ratio of the encapsulated coupler compound to the encapsulated diazo compound was 2/1. Furthermore, an aqueous solution of polystyrenesulfonic acid (of a type partially-neutralized with potassium hydroxide) (5% by mass) was mixed with the diazonium salt encapsulated microcapsule solution (a) in such a manner that 0.2 parts by mass of the aqueous solution of polystyrenesulfonic acid was used for 10 parts by mass of the diazonium salt encapsulated microcapsule solution (a), so as to yield a coating solution (G) for a magenta heat-sensitive recording layer.

### Preparation of Coating Solution (H) for Cyan Heat-Sensitive Recording Layer

The diazonium salt-encapsulated microcapsule solution (b) and the coupler dispersed emulsion (e) were mixed in such a manner that the molar ratio of the encapsulated coupler compound to the encapsulated diazo compound was 3/1. Furthermore, an aqueous solution of polystyrenesulfonic acid (of a type partially-neutralized with potassium hydroxide) (5% by mass) and water were mixed with the diazonium salt encapsulated microcapsule solution (b) in such a manner that 0.1385 parts by mass of the aqueous solution polystyrenesulfonic acid and 3.65 parts by mass of the water was used for 10 parts by mass of the diazonium salt encapsulated microcapsule solution (b), so as to yield a coating solution (H) for a cyan heat-sensitive recording layer.

### Preparation of Coating Solution (I) for Yellow Heat-Sensitive Recording Layer

The diazonium salt-encapsulated microcapsule solution (c) and the coupler dispersed emulsion (f) were mixed in such a manner that the molar ratio of the encapsulated coupler compound to the encapsulated diazo compound was 3/1. Furthermore, water and fluorescent bleaching agent containing a 4,4′-bistriazinylaminostylbene-2,2′-disulfonic acid derivative (trade name: Keikol BXNL (28% by mass), made by Nippon Soda Co., Ltd.) were mixed with the diazonium salt encapsulated microcapsule solution (c) in such a manner that 0.86 parts by mass of the water and 0.166 parts by mass of the fluorescent bleaching agent was used for 10 parts by mass of the diazonium salt encapsulated microcapsule solution (c), so as to yield a coating solution (I) for a yellow heat-sensitive recording layer.

### Preparation of Coating Solution for Intermediate Layer

Mixed were 10 parts by mass of an aqueous solution of 15% by mass alkali-treated, low-ion gelatin (trade name: #750 gelatin, made by Nitta Gelatin Co., Ltd.), 0.05 parts by mass of an aqueous solution of sodium 4-[(4-nonylphenoxy)-tri(oxyethylene)]butylsulfonate (20% by mass, made by Sankyo Chemical Industries, Co., Ltd.), 1.5 parts by mass of boric acid (4.0% by mass solution in water), 0.19 parts by mass of an aqueous solution of polystyrenesulfonic acid (of a type partially-neutralized with potassium hydroxide) (5% by mass), 4.53 parts by mass of a mixed aqueous solution (4% by mass) of N,N′-ethylene-bis(vinylsulfonylacetoamide), N,N′-trimethylene-bis(vinylsulfonylacetoamide), and sodium citrate (made by Wako Pure Chemical Industries, Co., Ltd.) and 0.67 parts by mass of ion-exchanged water, to prepare a coating solution for an intermediate layer.

### Preparation of Coating Solution for Light-Transmittance Adjusting Layer

### Preparation of Ultraviolet Absorbent Precursor Microcapsule Solution

Into 71 parts by mass of ethyl acetate were dissolved 14.5 parts by mass of [2-allyl-6-(2H-benzotriazole-2-yl)-4-t-octylphenyl]benzenesulfonate as an ultraviolet absorbent precursor, 5.0 parts by mass of 2,5-bis(t-octyl)hydroquinone, 1.9 parts by mass of tricresyl phosphate, 5.7 parts by mass of α-methylstyrenedimer (trade name: MSD-100; made by Mitsui Chemicals, Co., Ltd.), and 0.45 parts by mass of calcium dodecylbenzenesulfonate (trade name: Pionin A-41-C (70% solution in methanol); made by Takemoto Oil & Fat Co., Ltd.), so as to produce a homogeneous solution. To this mixed solution were added 54.7 parts by mass of xylylenediisocyanate/trimethylolpropane adduct (trade name: Takenate D110N (75% by mass solution in ethyl acetate); made by Takeda Chemical Industries, Co., Ltd.) as a capsule-wall material. The solution was homogeneously stirred to yield an ultraviolet absorbent precursor mixed solution (VII).

8.9 parts by mass of an aqueous solution of a 30% by mass phosphoric acid and 532.6 parts by mass of ion-exchanged water were separately mixed with 52 parts by mass of itaconic acid-modified polyvinyl alcohol (trade name: KL-318; Kuraray Co., Ltd.), so as to prepare an aqueous solution of PVA for an ultraviolet absorbent precursor microcapsule solution.

The ultraviolet absorbent precursor mixed solution (VII) was added to 516.06 parts by mass of the aqueous solution of PVA for an ultraviolet absorbent precursor microcapsule solution. A homogenizer (made by Nippon Seiki Seisakusho Co., Ltd.) was used to emulsify and disperse the precursor at 20° C. To the resultant emulsion were added 254.1 parts by mass of ion-exchanged water to make the emulsion homogeneous. Thereafter, the emulsion was subjected to a microcapsule reaction for 3.0 hours while the emulsion was stirred at 40° C. Subsequently, thereto were added 94.3 parts by mass of ion exchange resin Amberlite MB-3 (made by Organo Corporation), and then the emulsion was further stirred for 1 hour. Thereafter, the ion exchange resin was removed by filtration, and then the solid content concentration in the capsule solution was adjusted to 13.5%. The particle size of the resultant microcapsules was 0.30 μm. Into 859.1 parts by mass of this capsule solution were incorporated 2.416 parts by mass of carboxy-modified styrene butadiene latex (trade name: SN-307 (48% by mass solution in water); made by Sumitomo Norgatack Co., Ltd.) and 39.5 parts by mass of ion-exchanged water, so as to yield an ultraviolet absorbent precursor microcapsule solution.

### Preparation of Coating Solution for Light-Transmittance Adjusting Layer

Mixed were 1000 parts by mass of the ultraviolet absorbent precursor microcapsule solution, 5.2 parts by mass of potassium N-(perfluoro-1-octanesulfonyl)-N-propylaminoacetate (trade name: Megafack, made by Dainippon Ink and Chemicals, Co., Ltd.) (5% by mass solution in water), 7.75 parts by mass of an aqueous solution of 4% by mass sodium hydroxide, 73.39 parts by mass of sodium (4-nonylphenoxytrioxyethylene)butylsulfonate (2.0% by mass solution in water, made by Sankyo Chemical Industries, Co., Ltd.), so as to yield a coating solution for a light-transmittance adjusting layer.

### Preparation of Coating Solution for Protective Layer

### Preparation of Polyvinyl Alcohol Solution for Protective Layer

Mixed were 160 parts by mass of vinylalcohol-alkyl vinyl ether copolymer (trade name: EP-130; made by Denki Kagaku Kogyo Kabushiki Kaisha), 8.74 parts by mass of a mixed solution of sodium alkylsulfonate and polyoxyethylene alkyl ether phosphate (trade name: Neoscore CM-57 (54% by mass solution in water); made by Toho Chemical Industry Co., Ltd.), and 3832 parts by mass of ion-exchanged water. The mixed solution was stirred at 90° C. for 1 hour to yield a homogenous polyvinyl alcohol solution for a protective layer.

### Preparation of Pigment-Dispersed Solution for Protective Layer

Mixed were 8 parts by mass of barium sulfate (trade name BF-21F, the content of barium sulfate: 93% or more; made by Sakai Chemical Industry Co., Ltd.), 0.2 parts by mass of anionic special polycarboxylic acid type polymer activating agent (trade name: Poise 532A (40% by mass solution in water); made by Kao Corp.), and 11.8 parts by mass of ion-exchanged water. The dispersant components were dispersed in the water with a dyno mill to prepare a pigment-dispersed solution for the protective layer. The pigment-dispersed solution was subjected to a particle-size measurement (carried out with LA-910 made by Horiba, Ltd.). The median particle size thereof was 0.30 μm or less.

### Preparation of Mat Agent Dispersed Solution for Protective Layer

Mixed were 220 parts by mass of wheat starch (trade name: wheat starch S; made by Shinshin Shokuryo Kogyo), 3.81 parts by mass of 1-2-benzisothiazoline-3-one dispersed in water (trade name: PROXE1. B.D, I.C.I.) and 1976.19 parts by mass of ion-exchanged water, and the dispersed product was made homogeneous to yield a mat agent dispersed solution for the protective layer.

### Preparation of Coating Blend Solution for Protective Layer

The following were homogeneously mixed with 1000 parts by mass of the polyvinyl alcohol solution for the protective layer: 40 parts by mass of potassium N-(perfluoro-1-octanesulfonyl)-N-propylaminoacetate (trade name: Megafack F-120; made by Dainippon Ink and Chemicals, Co., Ltd.) (5% by mass solution in water), 50 parts by mass of sodium (4-nonylphenoxytrioxyethylene)butylsulfonate (2.0% by mass solution in water, made by Sankyo Chemical Industries, Ltd.), 49.87 parts by mass of the pigment dispersed solution for the protective layer, 16.65 parts by mass of the mat agent dispersed solution for the protective layer and 48.7 parts by mass of zinc stearate dispersed solution (trade name: Hydrin F115, and 20.5% by mass solution in water; made by Chukyo Oil & Fat Co., Ltd.), so as to yield a coating blend solution for the protective layer.

### Coating of Coating Solutions for Respective Heat-Sensitive Recording Layers

The following solutions were continuously coated onto the surface of the undercoat layer of the support: the coating solution (I) for the yellow heat-sensitive recording layer, the coating solution for the intermediate layer, the coating solution (H) for the cyan heat-sensitive recording layer, the coating solution for the intermediate layer, the coating solution (G) for the magenta heat-sensitive recording layer, the coating solution for the light-transmittance adjusting layer, and the coating solution for the protective layer. The resultant lamination was continuously dried under at a temperature of 30° C. and a relative moisture degree of 30% and at a temperature of 40° C. and a relative moisture degree of 30%. In this way, a multicolor heat-sensitive recording layer of Example 1 was yielded.

At this time, the coated amount of the solid content in the coating solution (I) for the yellow heat-sensitive recording layer, that of the applied solid content in the coating solution (H) for the cyan heat-sensitive recording layer, and that of the applied solid content in the coating solution (G) for the magenta heat-sensitive recording layer were 4.5 m/g², 6.7 g/m² and 4.71 m/g², respectively.

The coated amount of the solid content in each of the coating solutions for the intermediate layers was 3.25 g/m², the coated amount of the solid content in the coating solution for the light-transmittance adjusting layer was 2.35 m/g², and the coated amount of the solid content in the protective layer was 1.39 m/g².

### Example 2

The same manner as in Example 1 was carried out except that the coated amount of the coating solution (I) for the yellow heat-sensitive recording layer would be 5.40 g/m², that of the coating solution (H) for the cyan heat-sensitive recording layer would be 8.04 g/m² and that of the coating solution (G) for the magenta heat-sensitive recording layer would be 5.65 g/m². In this way, a heat-sensitive recording material of Example 2 was yielded.

### Comparative Example 1

### Support with Undercoat Layer

A wood pulp made of 100 parts by mass of LBKP was beaten and decomposed with a double discrefiner to have a Canadian freeness of 300 ml, and then 0.5 parts by mass of epoxylated behenic amide, 1 part by mass of anion polyacrylamide, 0.1 parts by mass of polyamide polyamine epichlorhydrin, and 0.5 parts by mass of cation polyacrylamide were added to the pulp. The amounts of the respective components are represented by bone-dry mass on the basis of the pulp. Base paper weighing 100 g/m² was produced with a Fourdrinier paper machine. The paper was surface-sized with polyvinyl alcohol at a bone-dry mass of 1.0 g/m². The paper was then subjected to calendar treatment to adjust the density thereof to 1.0.

The wire face (back face) of the base paper was subjected to corona discharge, and subsequently a melting extruder was used to coat the back face with high-density polyethylene in such a manner that the polyethylene resin would have a thickness of 30 μm. In this way, a resin layer having a mat surface was formed (this face is called a “back face”). The polyethylene-coated surface of this back face was subjected to corona discharge treatment. Thereafter, aluminum oxide (“Alumina sol 100” made by Nissan Chemical industries, Ltd.)/silicon dioxide (“Snowtex O” made by Nissan Chemical Industries, Ltd.)=1/2 (mass ratio) as an antistatic agent was dispersed into water, and this agent was applied in such a manner that the mass after drying would be 0.2 g/m² (This is called “back PE-laminated product”.).

The felt face (front face) of the base paper was subjected to corona discharge. A melting extruder was used to form a coat of low density polyethylene containing 10% by mass of titanium dioxide and a very small amount of ultramarine by melting extrusion, so as to have a resin thickness of 40 μm. In this way, a resin layer having a gloss face was formed (this face is called a “front face”). The polyethylene-coated surface of the front face was subjected to corona treatment, and then the following gelatin undercoat layer was applied in such a manner that the weight after drying would be 0.2 g/m².

### Preparation of Gelatin Undercoat Layer Solution

Forty parts by mass of enzymolized gelatin (average molecular weight: 10,000, PAGI-method viscosity: 1.5 mPa·s (15 mP), and PAGI-method jelly strength: 20 g) was added to 60 parts by mass of ion-exchanged water, and the solution was stirred at 40° C. to dissolve the gelatin in the water. In this way, an aqueous solution of gelatin for an undercoat layer was prepared.

8 parts by mass of water-swelling synthetic mica (aspect ratio: 1000, and trade name: Somashif ME100; made by Co-op Chemical Co., Ltd.) and 92 parts by mass of water were separately mixed with each other, and then the mica was wet-dispersed in water with a visco mill, to yield a mica-dispersed solution having an average particle size of 2.0 μm. To this mica-dispersed solution was added water in the manner that the concentration of the mica would be 5% by mass. The resultant was homogeneously mixed to prepare a desired mica-dispersed solution.

Next, 120 parts by mass of water and 556 parts by mass of methanol were added to 100 parts by mass of the aqueous solution of 40% by mass gelatin, which had a temperature of 40° C., and then the resultant solution was sufficiently stirred and mixed. Thereafter, 208 parts by mass of the 5% by mass mica-dispersed solution was added, and then the resultant solution was sufficiently stirred and mixed. To the solution was added 9.8 parts by mass of a 1.66% by mass polyethylene oxide-based surfactant. The temperature of the solution was kept at 35 to 40° C., and 7.3 parts by mass of ethylenediglycidyl ether was added thereto as a gelatin hardener, so as to prepare a coating solution (5.7% by mass) for an undercoat layer.

This coating solution was coated onto the front face of the support, wherein the polyethylene films were laminated on both surfaces of the fine paper in the manner that the coated amount of the mica would be 0.2 g/m². In this way, an undercoat layer was formed.

### Preparation of Cyan Heat-Sensitive Recording Layer Solution

### Preparation of Electron-Donating Dye Precursor-Containing Capsule Solution (j)

Five parts by mass of 3-(o-methyl-p-dimethylaminophenyl)-3-(1′-ethyl-2′-methylindole-3-yl)phthalide (electron-donating dye precursor) was dissolved into 20 parts by mass of ethyl acetate, and then 20 parts by mass of isopropylbiophenyl (high boiling point solvent) was added. The solution was heated and uniformly mixed.

To the resultant solution was added 20 parts by mass of adduct of xylidenediisocyanate/trimethylolpropane (1/3), and then the solution was uniformly stirred. This was used as an electron-donating colorless dye precursor solution.

A solution was separately prepared, wherein 2 parts by mass of an aqueous solution of 2% by mass sodium dodecylsulfonate was added to 54 parts by mass of an aqueous solution of 6% by mass phthalated gelatin. To this solution was added the above-mentioned electron-donating colorless dye precursor solution. A homogenizer was used to emulsify and disperse the precursor. In this way, an emulsified/dispersed solution was yielded. To the resultant emulsified/dispersed solution was added 68 parts by mass of water, and the resultant solution was mixed and made homogeneous. Thereafter, the mixture was heated to 50° C. while being stirred, and was subjected to a microcapsule reaction for 3 hours, so as to prepare an electron-donating colorless dye precursor-containing microcapsule solution (j). The average particle size of the microcapsules was 1.6 μm.

### Preparation of Electron-Accepting Compound Dispersed Solution (k)

Thirty parts by mass of 4,4′-(p-phenylenediisopropylidene)diphenol (trade name: Bisphenol P; made by Mitsui Petrochemical Industries, Ltd.) as an electron-accepting compound was added to 150 parts by mass of an aqueous solution of 4% by mass gelatin, and dispersed with a ball mill for 24 hours to yield an electron-accepting compound dispersed solution (k). The average particle size of the electron-accepting compound in the electron-accepting compound dispersed solution (k) was 1.2 μm.

### Preparation of Coating Solution for Cyan Heat-Sensitive Recording Layer

The electron-donating colorless dye precursor-containing microcapsule solution (j) and the electron-accepting compound dispersed solution (k) were mixed in such a manner that the ratio of the precursor/the electron-accepting compound dispersed solution was 1/10. Thereto was added sodium dodecylbenzenesulfonate in such a manner that the amount to be applied to a cyan heat-sensitive recording layer formed by application of the cyan heat-sensitive recording layer coating solution was 0.1 g/m².

### Preparation of Magenta Heat-Sensitive Recording Layer

### Preparation of Diazonium Salt Microcapsule Solution (l)

Two parts by mass of a diazonium salt (L) represented by the structural formula described below, which is decomposed by light having a wavelength of 365 nm, was dissolved into 20 parts by ethyl acetate, and subsequently thereto were added 20 parts by mass of isopropylbiphenyl and 0.4 parts by mass of diphenyl-(2,4,6-trimethylbenzoyl)phosphine oxide (trade name: Luciline TPO; made by BASF Japan Ltd.). These components were heated and uniformly mixed. To the resultant solution was added 15 parts by mass of an adduct (capsule-wall agent) of xylidenediisocyanate/trimethylolpropane (1/3), and these components were uniformly mixed to yield a solution of the diazonium salt.

The resultant solution of the diazonium salt was added to a solution, wherein 54 parts by mass of an aqueous solution of 6% by mass phthalated gelatin and 2 parts by mass of an aqueous solution of 2% by mass sodium dodecylsulfonate was mixed. A homogenizer was used to emulsify and disperse the salt. To the resultant emulsified/dispersed solution was added 68 parts by water, and the solution was uniformly mixed. The solution was heated to 40° C. while being stirred, and was subjected to a microcapsule reaction for 3 hours in such a manner that the average particle size of the capsules was 1.2 μm. In this way, a capsule solution was obtained. Thereafter, the temperature of the solution was lowered to 35° C., and 6.5 parts by mass of ion exchange resin Amberlite IRA 68 (made by Organo Corporation) and 13 parts by mass of Amberlite IRC 50 (made by Organo Corporation) were added, and the mixture was stirred for 1 hour. Thereafter, the ion exchange resin was removed by filtration, to yield a target diazonium salt encapsulated microcapsule solution (l).

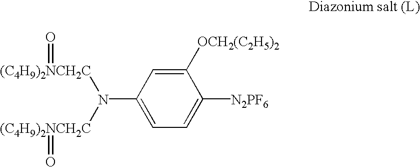

### Preparation of a Coupler Emulsion (m)

Into 10 parts by mass of ethyl acetate were dissolved 2.0 parts by mass of a coupler (M) represented by the following structural formula (M), 2.0 parts by mass of 1,2,3-triphenylguanidine, 2.0 parts by mass of 1,1-(p-hydroxyphenyl)-2-ethylhexane, 4.0 parts by mass of 4,4′-(m-phenylenediisopropylidene)diphenol, and 0.6 parts by mass of 3,3,3′,3′-tetramethyl-5,5′,6,6′-tetra(1-propyloxy)-1,1′-spirobisindane. The resultant solution was poured into an aqueous solution, wherein 20 parts by mass of an aqueous solution of 6% by mass gelatin and 2 parts by mass of an aqueous solution of 2% by mass sodium dodecylsulfonate were mixed. Thereafter, a homogenizer was used to perform emulsion for 10 minutes, to yield a coupler emulsion (m).

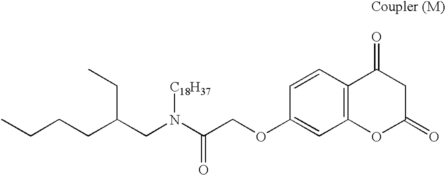

### Preparation of Coating Solution for Magenta Heat-Sensitive Recording Layer

An SBR latex (trade name: “SN-307”; made by Sumitomo Norgatack Co.) was added to the previously-prepared diazonium salt-containing capsule solution (l) in such a manner that the amount of the latex was 40% by mass of the solid content in the capsules. Thereafter, the coupler emulsion (m) was mixed with the diazonium salt-containing capsule solution (l) in such a manner that the mass ratio of the emulsion (m) to the capsule solution (l) was 3/2. In this way, a coating solution for a magenta layer was prepared.

### Preparation of Yellow Heat-Sensitive Recording Layer Solution

### Preparation of Diazonium Salt Microcapsule Solution (n)

Into 16.4 parts by mass of ethyl acetate were dissolved 3.5 parts by mass of a diazonium salt (N1) illustrated below, which had a maximum absorbency wavelength for decomposition of 420 nm, and 0.9 parts by mass of a diazonium salt (N2) illustrated below, as diazonium salts, and further thereto were added 9.8 parts by mass of isopropylbiphenyl as a high boiling point solvent and 0.4 parts by mass of diphenyl-(2,4,6-trimethylbenzoyl)phosphine oxide (trade name: Luciline TPO; made by BASF Japan Ltd.). The solution was heated and homogeneously mixed. To this solution were added 4.5 parts by mass of xylylenediisocyanate/trimethylolpropane adduct (trade name: Takenate D110N (75% by mass solution in ethyl acetate), made by Takeda Chemical Industries, Ltd.) and 4.2 parts by mass of a 30% by mass xylylenediisocyanate/bisphenol A adduct solution in ethyl acetate as capsule-wall materials. The solution was homogeneously stirred.

77 parts by mass of an aqueous solution of 6% by mass gelatin, to which 0.36 parts by mass of Scraph AG-8 (made by Nippon Fine Chemical Co., Ltd.) was added, was separately prepared. The above-mentioned diazonium salt solution was added thereto, and then the salt was emulsified and dispersed with a homogenizer. To the resultant aqueous solution was added 20 parts by water, and the solution was made homogeneous. Thereafter, the solution was subjected to a microcapsule reaction for 3 hours while the solution was stirred at 40° C. Thereafter, the temperature of the solution was lowered to 35° C., and 6.5 parts by mass of ion exchange resin Amberlite IRA68 (made by Organo Corporation) and 13 parts by mass of Amberlite IRC50 (made by Organo Corporation) were added to the solution, and the mixture was stirred for 1 hour. Thereafter, the ion exchange resin was removed by filtration, and then a 1% by mass hydroquinone solution in water was added to the solution in such a manner that 0.4 parts by mass of the hydroquinone solution was used per 10 parts by mass of the capsules. The mixture was stirred to yield a target diazonium salt microcapsule solution (n). The average particle size of the capsules was 0.91 μm.

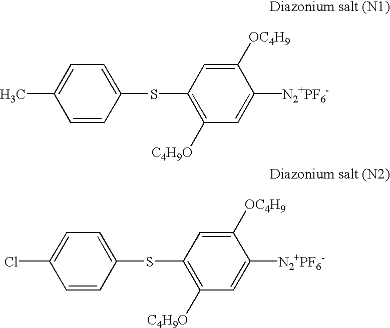

### Preparation of Coupler Emulsion (o)

Into 8.0 parts by mass of ethyl acetate were dissolved 2.4 parts by mass of the following coupler (O), 2.5 parts by mass of triphenylguanidine, 2.5 parts by mass of 1-1-(p-hydroxyphenyl)-2-ethylhexane, 3.6 parts by mass of 4,4′-(m-phenylenediisopropylidene)diphenol, 3.2 parts by mass of 2-ethylhexyl-4-hydroxybenzoate, and 0.8 parts by mass of 3,3,3′,3′-tetramethyl-5,5′,6,6′-tetra(1-propyloxy)-1,1′-spirobisindane. 1 part by mass of Pionin A41C made by Takemoto Oil & Fat Co., Ltd. was added, and then the solution was heated and homogeneously mixed. The solution was added to 75 parts by mass of an aqueous solution of 10% by mass gelatin (trade name: #750 gelatin; made by Nitta Gelatin Co., Ltd.). The coupler was then emulsified or dispersed with a homogenizer. Ethyl acetate remaining in this emulsion was evaporated to yield a coupler emulsion (o).

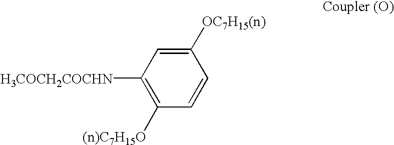

### Preparation of Coating Solution for Yellow Heat-Sensitive Recording Layer

The above-mentioned diazonium salt capsule solution (n), the coupler emulsion (o), and styrene-butadiene rubber (SN-307, made by Sumitomo Norgatack Co.) were mixed in such a manner that the ratio of the diazonium salt to the coupler would be 1/3.2 and the mass of the styrene-butadiene would be equal to that of the gelatin. In this way, a target coating solution was prepared.

### Preparation of Intermediate Coating Solution

To 100 parts by mass of an aqueous solution of 10% by mass gelatin (trade name: #750 gelatin; made by Nitta Gelatin Co., Ltd.) was added 2 parts by mass of 2% sodium (4-nonylphenoxytrioxyethylene)butylsulfonate, so as to prepare a coating solution for an intermediate layer.

### Preparation of Light-Transmittance Adjusting Layer Solution

### Preparation of Ultraviolet Absorbent Precursor Microcapsule Solution

Into 30 parts by mass of ethyl acetate were dissolved 10 parts by mass of [2-allyl-6-(2H-benzotriazole-2-yl)-4-t-octylphenyl]benzenesulfonate, 3 parts by mass of 2,5-di-t-octyl-hydroquinone, 2 parts by mass of tricresylphosphate, and 4 parts by mass of α-methylstyrenedimer as an ultraviolet absorbent precursor. To this solution were further added 20 parts by mass of xylylenediisocyanate/trimethylolpropane adduct (trade name: Takenate D110N (75% by mass solution in ethyl acetate); made by Takeda Chemical Industries, Ltd.), and the solution was homogeneously stirred as a capsule-wall material.

200 parts by mass of an aqueous solution of 8% itaconic acid-modified polyvinyl alcohol (trade name: KL-318, made by Kuraray Co., Ltd.) was separately prepared. The above-mentioned ultraviolet absorbent precursor solution was added thereto, and the precursor was emulsified and dispersed with a homogenizer. To the resultant emulsion was added 120 parts by mass of water, and the emulsion was made homogeneous. Thereafter, the temperature of the emulsion was raised to 40° C. while the emulsion was stirred. The emulsion was subjected to a microcapsule reaction for 3 hours, and subsequently thereto were added 7.0 parts by mass of ion exchange resin Amberlite MB-3 (Organo Corporation). The emulsion was further stirred for 1 hour, to prepare a target ultraviolet absorbent precursor microcapsule solution. The average particle size of the microcapsules was 0.3 μm.

### Preparation of Coating Solution for Light-Transmittance Adjusting Layer

To 100 parts by mass of the above-mentioned ultraviolet absorbent precursor microcapsule solution were added 10 parts by mass of an aqueous solution of 2% sodium (4-nonylphenoxytrioxyethylene)butylsulfonate, so as to prepare a coating solution for an light-transmittance adjusting layer.

### Preparation of Coating Solution for Protective Layer

Mixed were 100 parts by mass of an aqueous solution of 7% by mass vinylalcohol-alkyl vinyl ether copolymer (trade name: EP-130; made by Denki Kagaku Kogyo Kabushiki Kaisha), 50 parts by mass of water, 10 parts by mass of a dispersed solution of 20% by mass barium sulfate (trade name: BF-21F; made by Sakai Chemical Industry Co., Ltd.), 5 parts by mass of an aqueous solution of 2.0% by mass sodium (4-nonylphenoxytrioxyethylene)butylsulfonate, and 5.0 parts by mass of an aqueous solution of 50% by mass potassium N-(perfluoro-1-octanesulfonyl)-N-propylaminoacetate, so as to prepare a coating solution for a protective layer.

### Production of Heat-Sensitive Recording Layer for Comparison

The following were successively coated on the surface of the undercoat layer disposed on the support with the undercoat layer: a cyan heat-sensitive recording layer solution, an intermediate layer solution, a magenta heat-sensitive recording layer solution, an intermediate layer solution, a yellow heat-sensitive recording layer solution, a light-transmittance adjusting layer solution and a protective layer solution. The solution was dried to yield a multicolor heat-sensitive recording layer of Comparative Example 1. The coated amounts of the respective solutions from the cyan heat-sensitive recording layer solution to the protective layer solution were 8.12 g, 3.28 g, 9.05 g, 3.13 g, 8.51 g, 2.50 g, and 1.23 g, respectively, per 1 m².

### Comparative Example 2

A heat-sensitive recording material of Comparative Example 2 was obtained in the same way as in Comparative Example 1 except that the coated amounts of the respective solutions from the cyan heat-sensitive recording layer solution to the protective layer solution were 9.74 g, 3.94 g, 10.86 g, 3.76 g, 10.21 g, 3.0g, and 1.48 g, respectively, per 1 m².

### Evaluation

The multicolor heat-sensitive recording materials of Examples 1 and 2 and Comparative Examples 1 and 2 were evaluated by the following methods. The results are shown in Table 1. The heat-sensitive recording layers were, in order from the protective layer side, the first heat-sensitive recording layer, the second heat-sensitive recording layer, and the third heat-sensitive recording layer, respectively.

### Water Content

The water contents in the multicolor heat-sensitive recording materials of Examples 1 and 2 and Comparative Examples 1 and 2 were measured in accordance with the method of JIS P 8127 (method of testing the water content in paper and plate paper).

### Curl Balance

Curls were measured in accordance with “J. TAPPI Paper Pulp Test Method, No. 17-77, Test Method of Paper Curl III”. Cases in which the curl angle measured in the state that back faces were put on each other was 120° or less were regarded as good (◯), and cases in which the curl angel was 120° or more was regarded as bad (X).

### Shelf Life

Twenty sheets of recording paper having a size of 10 cm and 15 cm were stacked and then airtightly wrapped. The stack was preserved at 50° C. for 7 hours. Thereafter, the stack was sufficiently irradiated with ultraviolet rays having wavelengths of 425 nm and 365 nm to fix the diazo. An X-Rite 310TR made by Nippon Lithograph, Co., Ltd. was used to measure the background densities of the samples. Cases in which both of O.D.(Y) and O.D.(M) were 0.10 or less were regarded as good (◯), and cases in which either thereof was 0.10 or more were regarded as bad (X).

TABLE 1

| | Water | Wet coated | Solid content | | |
|---|---|---|---|---|---|
| | content | amount | coated amount | | |
| | (%) | (g/m²) | (g/m²) | Curls | Shelf life |
| Example 1 | 4.5 | 192.1 | 26.15 | ◯ | ◯ |
| Example 2 | 5.2 | 208.9 | 29.33 | ◯ | ◯ |
| Comparative | 6.0 | 259.8 | 35.37 | X | X |
| Example 1 | | | | | |
| Comparative | 6.5 | 315.8 | 42.99 | X | X |
| Example 2 | | | | | |

As is apparent from Table 1, the multicolor heat-sensitive recording materials of Examples 1 and 2 had superior curl balance and shelf life.

On the other hand, the multicolor heat-sensitive recording materials of Comparative Examples 1 and 2 had bad curl balance and were not easily passed through a printer. When they were preserved for a given time, fog was generated and poor shelf life was exhibited.

As described above, according to the invention, a multicolor heat-sensitive recording material that has superior curl balance and shelf life can be provided.

What is claimed is:

1. A multicolor heat-sensitive recording material comprising a support having disposed thereon at least a heat-sensitive recording layer that develops yellow, a heat-sensitive recording layer that develops cyan, and a heat-sensitive recording layer that develops magenta, wherein
water content by percentage of the multicolor heat-sensitive recording material including the support is 5.5% or less.

2. The multicolor heat-sensitive recording material of claim 1, wherein the wet coated amount of all layers formed on the side of the support disposed with the heat-sensitive recording layers is 250 g/m² or less.

3. The multicolor heat-sensitive recording material of claim 1, wherein the solid content coated amount of all layers formed on the side of the support disposed with the heat-sensitive recording layers is 40 g/m² or less.

4. The multicolor heat-sensitive recording material of claim 1, wherein the heat-sensitive recording layers are successively disposed on the support in the order of the heat-sensitive recording layer that develops yellow, the heat-sensitive recording layer that develops cyan, and the heat-sensitive recording layer that develops magenta.

5. The multicolor heat-sensitive recording material of claim 1, wherein the heat-sensitive recording layer that develops cyan and the heat-sensitive recording layer that develops magenta are light-fixing, heat-sensitive recording layers.

6. The multicolor heat-sensitive recording material of claim 1, further comprising a light-transmittance adjusting layer, an intermediate layer and a protective layer.

7. The multicolor heat-sensitive recording material of claim 1, wherein each of the heat-sensitive recording layers comprises: at least one of a diazo compound and at least one of a diazonium salt; and a coupler compound that reacts with the diazo compound and the diazonium salt to develop the corresponding color.

8. The multicolor heat-sensitive recording material of claim 7, wherein the heat-sensitive layers further comprise a basic material and a sensitizer.

9. The multicolor heat-sensitive recording material of claim 7, wherein the maximum absorbency wavelength of at least one of the diazo compound and the diazonium salt in the heat-sensitive recording layer that develops yellow is 350 nm or less, the maximum absorbency wavelength of at least one of the diazo compound and the diazonium salt in the heat-sensitive recording layer that develops cyan is 370±30 nm, and the maximum absorbency wavelength of at least one of the diazo compound and the diazonium salt in the heat-sensitive recording layer that develops magenta is 430±30 nm.

10. The multicolor heat-sensitive recording material of claim 7, wherein at least one of the diazo compound and the diazonium salt is encapsulated in microcapsules.
